(19) United States
(12) Patent Application Publication
(10) Pub. No.: US 2006/0289882 A1
(43) Pub. Date: Dec. 28, 2006

(54) Organic electroluminescent element and organic electroluminescent display device

(76) Inventors: Kazuki Nishimura, Hirakata-city (JP); Yuji Hamada, Ikoma-gun (JP); Masahiro Iyori, Hirakata city (JP); Haruhisa Hashimoto, Toyonaka-city (JP); Masakazu Sakata, Hirakata-city (JP); Hiroaki Izumi, Kirakata-city (JP); Kaname Ito, Moriguchi-city (JP); Kaori Ishikawa, Nishinomiya-city (JP); Hiroki Ishida, Anpachi-gun (JP)

Correspondence Address: MCDERMOTT WILL & EMERY LLP, 600 13TH STREET, N.W., WASHINGTON, DC, 20005-3096, US

(21) Appl. No.: 11/192,405

(22) Filed: Jul. 29, 2005

(30) Foreign Application Priority Data
Jul. 30, 2004 (JP) 2004-224905
Jul. 30, 2004 (JP) 2004-224906
Jul. 30, 2004 (JP) 2004-224907
Jul. 30, 2004 (JP) 2004-224908
Jul. 30, 2004 (JP) 2004-224909
Jul. 30, 2004 (JP) 2005-224910
Nov. 30, 2004 (JP) 2004-347296
Jan. 31, 2005 (JP) 2005-024212
Feb. 25, 2005 (JP) 2005-050034
Feb. 25, 2005 (JP) 2005-050035

(51) Int. Cl. H01L 51/54; H05B 33/00

(52) U.S. Cl. 257/94; 257/40; 257/98; 257/E51.05; 313/504; 313/506; 313/112; 428/690; 428/917; 428/112

(57) ABSTRACT

An organic electroluminescent element comprising a cathode, an anode, an intermediate unit arranged between a cathode and an anode, a first light emitting unit arranged between a cathode and an intermediate unit, and a second light emitting unit arranged between an anode and an intermediate unit, wherein an electron extracting layer for extracting an electron from an adjacent layer adjoining a cathode side is provided in an intermediate unit, an absolute value of an energy level of a lowest unoccupied molecular orbital (LUMO) of an electron extracting layer |LUMO(A)|, and an absolute value of an energy level of a highest occupied molecular orbital (HOMO) of the adjacent layer |HOMO(B)| are in the relationship of |HOMO(B)|−|LUMO(A)|≦1.5 eV, and an intermediate unit supplies a hole generated by extraction of an electron from an adjacent layer by an electron extracting layer and, at the same time, supplies the extracted electron to a second light emitting unit.

The priority Japanese Patent Application Numbers 2004-224905, 2004-224906, 2004-224907, 2004-224908, 2004-224909, 2004-224910, 2004-347296, 2005-024212, 2005-050034 and 2005-050035 upon which this patent application is based is hereby incorporated by reference.

### BACKGROUND OF THE INVENTION

1. Field of the Invention

The present invention relates to an organic electroluminescent element and an organic electroluminescent display device.

2. Description of the Related Art

An organic electroluminescent element (organic EL element) has been actively developed from a viewpoint of application to display and illumination. Principle for driving an organic EL element is as follows; That is, a hole and an electron are injected through an anode and a cathode, respectively, these are transported in an organic thin film, and recombined in a light emitting layer to generate the excited state, and light emitting is obtained from this excited state. In order to enhance a light emitting efficiency, it is necessary to inject a hole and an electron effectively, and transport them in an organic thin film. However, since movement of a carrier in an organic EL element undergoes restriction due to an energy barrier between an electrode and an organic thin film, and low carrier mobility in an organic thin film, improvement in a light emitting efficiency is limited.

On the other hand, as other method of improving a light emitting efficiency, there is a method of laminating a plurality of light emitting layers. For example, by laminating an orange light emitting layer and a blue light emitting layer in a complementary relationship so that they are directly contacted, a higher light emitting efficiency than that of the case of a monolayer can be obtained in some cases. For example, in the case where a light emitting efficiency of a blue light emitting layer is 10 cd/A, and a light emitting efficiency of an orange light emitting layers is 8 cd/A, when these are laminated to form a white light emitting element, a light emitting efficiency of 15 cd/A is obtained.

However, when 3 or more of light emitting layers are laminated so that they are directly contacted, improvement in a light emitting efficiency is not obtained. This is because there is a limitation on expansion of a region for recombining an electron and a hole, and a recombination region does not span 3 or more layers.

In 2004 spring 51^{st} Applied Physics Association Coupled Lecture, Lecture Abstract, No. 3, pp 1464, Lecture No. 28p-ZQ-14 “Carrier Recombination-Type Organic EL Element”, there is reported a method of laminating two light emitting units via an inorganic semiconductor layer such as V₂O₅ and ITO, generating a carrier in the interior of an inorganic semiconductor layer, and supplying a carrier to two light emitting layers. This method is a method of utilizing a carrier contained in an inorganic semiconductor layer and, in order to generate a carrier, a high voltage must be applied. For this reason, a driving voltage becomes high and this cannot be applied to low voltage driving of a portable equipment.

In Japanese Patent Application Laid-Open (JP-A) No.2003-272860, JP-A No.2003-264085, JP-A No.11-329748 and JP-A No.2004-39617, an organic EL element in which a plurality of light emitting units are laminated via a charge generating layer is proposed, but it is necessary to drive that element at a high voltage, and a high light emitting efficiency is not obtained.

### SUMMARY OF THE INVENTION

An object of the present invention is to provide, in an organic EL element provided with at least two light emitting units, an organic EL element which can be driven at a low voltage, has a high light emitting efficiency, and can exhibit a desired emitting color, and an organic EL display device.

<First Aspect>

An organic EL element in accordance with a first aspect of the present invention is provided with a cathode, an anode, an intermediate unit arranged between a cathode and an anode, a first light emitting unit arranged between a cathode and an intermediate unit, and a second light emitting unit arranged between an anode and an intermediate unit, and is characterized in that an electron extracting layer for extracting an electron from an adjacent layer adjoining a cathode side is provided in an intermediate unit, an absolute value of an energy level of a lowest unoccupied molecular orbital (LUMO) of an electron extracting layer |LUMO (A)|, and an absolute value of an energy level of a highest occupied molecular orbital (HOMO) of an adjacent layer |HOMO (B)| are in the relationship of |HOMO (B)|−|LUMO (A)|≦1.5 eV, and an intermediate unit supplies a hole generated by extraction of an electron from an adjacent layer by an electron extracting layer to a first light emitting unit and, at the same time, supplies the extracted electron to a second light emitting unit. Hereinafter, regarding matters common to each aspect of the present invention, they are explained as the “present invention” in some cases.

According to the present invention, an intermediate unit is provided between a first light emitting unit and a second light emitting unit, and an electron extracting layer is provided in an intermediate unit. An adjacent layer is provided on a cathode side of an electron extracting layer. An absolute value of an energy level of HOMO of an adjacent layer |HOMO (B)|, and an absolute value of an energy level of LUMO of an electron extracting layer |LUMO (A)| are in the relationship of |HOMO (B)|−|LUMO (A)|≦1.5 eV. That is, an energy level of LUMO of an electron extracting layer is a value close to an energy level of HOMO of an adjacent layer. For this reason, an electron extracting layer can extract an electron from an adjacent layer. By this extraction of an electron from an adjacent layer, a hole is generated in an adjacent layer. When an adjacent layer is provided in a first light emitting unit, a hole is generated in a first light emitting unit. On the other hand, when an adjacent layer is provided between an electron extracting layer and a first light emitting unit, that is, when it is provided in an intermediate unit, a hole generated in an adjacent layer is supplied to a first light emitting unit. A hole supplied to a first light emitting unit is recombined with an electron from a cathode, thereby, a first light emitting unit emits light.

On the other hand, an electron extracted by an electron extracting layer is supplied to a second light emitting unit, and recombined with a hole supplied from an anode, thereby, a second light emitting unit emits light.

Therefore, according to the present invention, a recombination region can be formed in a first light emitting unit and a second light emitting unit, respectively, thereby, a first light emitting unit and a second light emitting unit can emit light separately.

In the present invention, in order that an electron extracting layer extracts an electron from an adjacent layer, it is preferable that an energy level of LUMO of an electron extracting layer is closer to an energy level of HOMO of an adjacent layer than an energy level of LUMO of an adjacent layer. That is, it is preferable that an absolute value of an energy level of LUMO of an adjacent layer |HOMO (B)| satisfies the following relationship;
|HOMO(B)|−LUMO(A)|<|LUMO(A)|−LUMO(B)|

In addition, since an absolute value of an energy level of LUMO of a material used as an electron extracting layer is generally smaller than an absolute value of an energy level of HOMO of an adjacent layer, in such the case, absolute values of respective energy levels are shown by the following relation equation.
0 eV<|HOMO(B)|−LUMO(A)|≦1.5 eV

A first light emitting unit and a second light emitting unit in the present invention may be formed of a single light emitting layer, or may be constructed by laminating a plurality of light emitting layers so that they are directly contacted, respectively. However, the present invention is particularly useful when the present invention has a structure in which a first light emitting layer and a second light emitting layer are laminated so that they are directly contacted with two light emitting layers, respectively. That is, in such the case, when a first light emitting unit and a second light emitting unit are directly laminated, a structure in which four light emitting layers are directly laminated is obtained and, as described above, since there is a limitation on expansion of a region for recombining an electron and a hole, a recombination region does not span four light emitting layers. For this reason, recombination is generated at one place in a thickness direction of four light emitting layers, and a high light emitting efficiency cannot be obtained. In addition, since recombination is generated at a different region from a recombination region when a first light emitting unit and a second light emitting unit emit light separately, respectively, a color different from an emitting color of a first light emitting unit and that of a second light emitting unit is emitted.

In accordance with the present invention, by providing an intermediate unit between a first light emitting unit and a second light emitting unit, recombination can be generated in each of a first light emitting unit and a second light emitting unit. That is, a recombination region can be formed in a first light emitting unit and a second light emitting unit, respectively, and a first light emitting unit and a second light emitting unit can independently emit light, respectively. For this reason, a high light emitting efficiently can be obtained and, at the same time, the same color as that of a light emitting color of a first light emitting unit and a second light emitting unit can be emitted.

In the present invention, it is preferable that an adjacent layer is formed of a hole transporting material, and it is particularly preferable that the layer is formed of an arylamine-based hole transporting material.

In the present invention, an adjacent layer may be provided in a light emitting unit. In particular, when a host material for a light emitting layer situated on an intermediate unit side in a first light emitting unit is a hole transporting material suitable as an adjacent layer, a light emitting layer on an intermediate unit side in a first light emitting unit may be an adjacent layer.

Alternatively, in the present invention, an adjacent layer may be provided in an intermediate unit. When a host material for a light emitting layer on an intermediate unit side in a first light emitting unit is not a hole transporting material suitable as an adjacent layer, since it cannot function as an adjacent layer in some cases, in such the case, an adjacent layer may be provided in an intermediate unit. In such the case, an adjacent layer is arranged between an electron extracting layer and a first light emitting unit.

In the present invention, an electron extracting layer can be used without any limitation as far as an absolute value of an energy level of LUMO is smaller than an absolute value of an energy level of HOMO of an adjacent layer by 1.5 eV. As an embodiment, for example, the layer can be formed of a pyrazine derivative represented by the following structural formula. 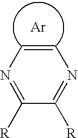
(wherein Ar represents an aryl group, and R represents an alkyl group having a carbon number of 1 to 10, an alkyloxy group having a carbon number of 1 to 10 having a carbon number of 1 to 10, a dialkylamine group having a carbon number of 1 to 10, F, Cl, Br, I or CN)

In the present invention, further preferably, an electron extracting layer can be formed of a hexaazatriphenylene derivative represented by the following structural formula. 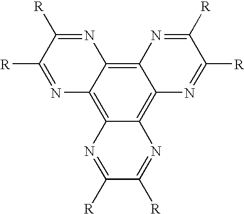
(wherein R represents hydrogen, an alkyl group having a carbon number of 1 to 10, an alkyloxy group having a carbon number of 1 to 10, a dialkylamine group having a carbon number of 1 to 10, F, Cl, Br, I or CN)

In a preferable embodiment in accordance with the present invention, a first light emitting unit and a second light emitting unit are units which emit substantially the same color. In this case, it is preferable that those units are formed by using substantially the same material so that they have the same structure.

It is preferable that a light emitting layer constituting a first light emitting unit and a second light emitting unit in the present invention is formed of a host material and a dopant material. If necessary, a carrier transporting second dopant material may be contained. A dopant material may be a singlet light emitting material, or a triplet light emitting material (phosphorescent emitting material).

In the present invention, it is preferable that an electron injecting layer is provided between an electron extracting layer and a second light emitting unit. When an electron injecting layer is formed of a metal lithium, a thickness thereof is preferably in a range of 0.3 to 0.9 nm. By making a thickness of an electron injecting layer comprising of a metal lithium in such a range, an element life can be prolonged, and a driving voltage can be reduced. A further preferable thickness of an electron injecting layer is in a range of 0.6 to 0.9 nm.

In addition, it is preferable that an electron transporting layer is provided between an electron injecting layer and a second light emitting unit. An electron transporting layer can be formed of a material which is generally used as an electron transporting material in an organic EL element.

A bottom emission-type organic electroluminescent display device in accordance with a first aspect of the present invention comprises an organic electroluminescent element having an element structure sandwiched between an anode and a cathode, and an active matrix driving substrate having each active element for supplying a display signal for each display pixel to the organic electroluminescent element, in which the organic electroluminescent element is provided on the active matrix driving substrate and, among the cathode and the anode, an electrode provided on the substrate side is a transparent electrode, and is characterized in that an organic electroluminescent element is provided with a cathode, an anode, an intermediate unit arranged between a cathode and an anode, a first light emitting unit arranged between a cathode and an intermediate unit, and a second light emitting unit arranged between an anode and an intermediate unit, an electron extracting layer for extracting an electron from an adjacent layer adjoining a cathode side is provided in an intermediate unit, an absolute value of an energy level of a lowest unoccupied molecular orbital (LUMO) of an electron extracting layer |LUMO (A)|, and an absolute value of an energy level of a highest occupied molecular orbital (HOMO) of an adjacent layer |HOMO (B)| are in the relationship of |HOMO (B)|−|LUMO (A)|≦1.5 eV, and an intermediate unit supplies a hole generated by extraction of an electron from an adjacent layer by an electron extracting layer to a first light emitting unit and, at the same time, supplies the extracted electron to a second light emitting unit.

When an organic electroluminescent element is a white emitting element, it is preferable that a color filter is arranged between an active matrix driving substrate and an organic electroluminescent element.

A top emission-type organic electroluminescent display device in accordance with a first aspect of the present invention comprises an organic electroluminescent element having an element structure sandwiched between an anode and a cathode, an active matrix driving substrate having each active element for supplying a display signal for each display pixel to the organic electroluminescent element, and a transparent sealing substrate provided opposite to the active matrix driving substrate, in which an organic electroluminescent element is arranged between an active matrix driving substrate and a sealing substrate and, among a cathode and an anode, an electrode provided on a sealing substrate side is a transparent electrode, and is characterized in that an organic electroluminescent element is provided with a cathode, an anode, an intermediate unit arranged between a cathode and an anode, a first light emitting unit arranged between a cathode and an intermediate unit, and a second light emitting unit arranged between an anode and an intermediate unit, an electron extracting layer for extracting an electron from an adjacent layer adjoining a cathode side is provided in an intermediate unit, an absolute value of an energy level of a lowest unoccupied molecular orbital (LUMO) of an electron extracting layer |LUMO (A)|, and an absolute value of an energy level of a highest occupied molecular orbital (HOMO) of an adjacent layer |HOMO (B)| are in the relationship of |HOMO (B)|−|LUMO (A)|≦1.5 eV, and an intermediate unit supplies a hole generated by extraction of an electron from an adjacent layer by an electron extracting layer to a first light emitting unit and, at the same time, supplies the extracted electron to a second light emitting unit.

When an organic electroluminescent element is a white emitting element, it is preferable that a color filter is arranged between a sealing substrate and an organic electroluminescent element.

In a top emission-type organic electroluminescent display device of the present invention, light emitted in an organic electroluminescent element is radiated from a sealing substrate on a side opposite to a side on which an active matrix is provided. Generally, an active matrix driving substrate is formed by laminating many layers, and an active element such as a thin film transistor provided for each pixel is not translucent. Therefore, in the case of a bottom emission-type, emitted light is attenuated due to the presence of such many layers and the active element such as a thin film transistor. In the case of a top emission-type, the device can emit light without undergoing influence of such the active matrix circuit. In particular, since an organic electroluminescent element of the present invention has a plurality of light emitting units, in the case of a top emission-type, a smaller number of films through which emitted light passes may be used as compared with a bottom emission type, a freedom degree of design for controlling attenuation of emitted light due to interference of light or attenuation of a visual field angle of emitted light can be enhanced.

The organic EL element and the organic EL display device of the present invention are an organic EL element provided with at least two light emitting units, and are an organic EL element and an organic EL display device which can be driven at a low voltage, and have a high light emitting efficiency.

<Second Aspect>

An organic EL element in accordance with a second aspect of the present invention is provided with a cathode, an anode, an intermediate unit arranged between a cathode and an anode, a first light emitting unit arranged between a cathode and an intermediate unit, and a second light emitting unit which is arranged between an anode and an intermediate unit, and emits a color substantially different from that of a first light emitting unit, and characterized in that an electron extracting layer for extracting an electron from an adjacent layer adjoining a cathode side is provided in an intermediate unit, an absolute value of an energy level of a lowest unoccupied molecular orbital (LUMO) of an electron extracting layer |LUMO (A)|, and an absolute value of an energy level of a highest occupied molecular orbital (HOMO) of an adjacent layer |HOMO (B)| are in the relationship of |HOMO (B)|−|LUMO (A)|≦1.5 eV, and an intermediate unit supplies a hole generated by extraction of an electron from an adjacent layer by an electron extracting layer to a first light emitting unit and, at the same time, supplies the extracted electron to a second light unit.

In accordance with a second aspect of the present invention, by providing an intermediate unit between a first light emitting unit and a second light emitting unit, recombination can be generated in a first light emitting unit and a second light emitting unit, respectively. That is, a recombination region can be formed in each of a first light emitting unit and a second light emitting unit, and a first light emitting unit and a second light emitting unit can independently emit light, respectively. For this reason, a high light emitting efficiency can be obtained and, at the same time, the color combined with each color of a first light emitting unit and a second light emitting unit can be emitted.

In the present invention, it is preferable that an electron injecting layer in an intermediate unit can be formed of an alkali metal such as Li and Cs, an alkali metal oxide such as Li₂O, an alkaline earth metal, or an alkali earth metal oxide.

A bottom emission-type organic electroluminescent display device in accordance with a second aspect of the present invention comprises an organic electroluminescent element having an element structure sandwiched between an anode and a cathode, and an active matrix driving substrate having each active element for supplying a display signal for each display pixel to the organic electroluminescent element, in which the organic electroluminescent element is provided on the active matrix driving substrate and, among the cathode and the anode, an electrode provided on the substrate side is a transparent electrode, and is characterized in that an organic electroluminescent element is provided with a cathode, an anode, an intermediate unit arranged between a cathode and an anode, a first light emitting unit arranged between a cathode and an intermediate unit, and a second light emitting unit which is arranged between an anode and an intermediate unit, and emit color substantially different from that of a first light emitting unit, an electron extracting layer for extracting an electron from an adjacent layer adjoining a cathode side is provided in an intermediate unit, an absolute value of an energy level of a lowest unoccupied molecular orbital (LUMO) of an electron extracting layer |LUMO (A)|, and an absolute value of an energy level of a highest occupied molecular orbital (HOMO) of an adjacent layer |HOMO (B)| are in the relationship of |HOMO (B)|−|LUMO (A)|≦1.5 eV, and an intermediate unit supplies a hole generated by extraction of an electron from an adjacent layer by an electron extracting layer to a first light emitting unit and, at the same time, supplies the extracted electron to a second light emitting unit.

A top emission-type organic electroluminescent display device in accordance with a second aspect of the present invention comprises an organic electroluminescent element having an element structure sandwiched between an anode and a cathode, an active matrix driving substrate having each active element for supplying a display signal for each display pixel to the organic electroluminescent element, and a transparent sealing substrate provided opposite to the active matrix driving substrate, in which an organic electroluminescent element is arranged between an active matrix driving substrate and a sealing substrate and, among a cathode and an anode, an electrode provided on a sealing substrate side is a transparent electrode, and is characterized in that an organic electroluminescent element is provided with a cathode, an anode, an intermediate unit arranged between a cathode and an anode, a first light emitting unit arranged between a cathode and an intermediate unit, and a second light emitting unit which is arranged between an anode and an intermediate unit, and emit color substantially different from that of a first light emitting unit, an electron extracting layer for extracting an electron from an adjacent layer adjoining a cathode side is provided in an intermediate unit, an absolute value of an energy level of a lowest unoccupied molecular orbital (LUMO) of an electron extracting layer |LUMO (A)|, and an absolute value of an energy level of a highest occupied molecular orbital (HOMO) of an adjacent layer |HOMO (B)| are in the relationship of |HOMO (B)|−|LUMO (A)|≦1.5 eV, and an intermediate unit supplies a hole generated by extraction of an electron from an adjacent layer by an electron extracting layer to a first light emitting unit and, at the same time, supplies the extracted electron to a second light emitting unit.

The organic EL element and the organic EL display device in accordance with a second aspect of the present invention are an organic EL element provided with at least two light emitting units which emit substantially difference colors, and are an organic EL element and an organic EL display device which can be driven at a low voltage, have a high light emitting efficiency, and exhibit a desired emitted color.

<Third Aspect>

An organic EL element in accordance with a third aspect of the present invention is provided with a cathode, an anode, an intermediate unit arranged between a cathode and an anode, a first light emitting unit arranged between a cathode and an intermediate unit, and a second light emitting unit emitting a color arranged between an anode and an intermediate unit, and is characterized in that an electron extracting layer for extracting an electron from an adjacent layer adjoining a cathode side is provided in an intermediate unit, an absolute value of an energy level of a lowest unoccupied molecular orbital (LUMO) of an electron extracting layer |LUMO (A)|, and an absolute value of an energy level of a highest occupied molecular orbital (HOMO) of an adjacent layer are in the relationship of |HOMO (B)|−|LUMO (A)|≦1.5 eV, a light emitting layer situated on an intermediate unit of a first light emitting unit contains an arylamine-based hole transporting material, the light emitting layer is provided adjoining an electron extracting layer so as to function as an adjacent layer, and an intermediate unit supplies a hole generated by extraction of an electron from the light emitting layer by an electron extracting layer to a first light emitting unit and, at the same time, supplies the extracted electron to a second light emitting unit.

According to a third aspect of the present invention, an intermediate unit is provided between a first light emitting unit, and a second light emitting unit, and an electron extracting layer is provided in an intermediate unit. In addition, a light emitting layer situated on an intermediate unit side of a first light emitting unit contains an arylamine-based hole transporting material, and the light emitting layer is provided adjoining an electron extracting layer. Therefore, in a third aspect, the light emitting layer functions as an adjacent layer. In accordance with a third aspect of the present invention, by making a light emitting layer situated on an intermediate unit side of a first light emitting unit function as an adjacent layer, a driving voltage can be lowered, and a light emitting efficiency can be enhanced as compared with the case where an adjacent layer is provided in an intermediate unit.

In a third aspect of the present invention, an arylamine-based hole transporting material is contained in a light emitting layer situated on an intermediate unit side of a first light emitting unit. An arylamine-based hole transporting material is contained in the light emitting layer preferably at 50% by weight or more, further preferably at 70% by weight or more. It is preferable that the arylamine-based hole transporting material is contained as a host material in the light emitting layer.

A bottom emission-type organic electroluminescent display device in accordance with a third aspect of the present invention comprises an organic electroluminescent element having an element structure sandwiched between an anode and a cathode, and an active matrix driving substrate having each active element for supplying a display signal for each display pixel to the organic electroluminescent element, in which the organic electroluminescent element is provided on the active matrix driving substrate and, among the cathode and the anode, an electrode provided on the substrate side is a transparent electrode, and is characterized in that an organic electroluminescent element is provided with a cathode, an anode, an intermediate unit arranged between a cathode and an anode, a first light emitting unit arranged between a cathode and the intermediate unit, and a second light emitting unit arranged between an anode and the intermediate unit, an electron extracting layer for extracting an electron from an adjacent layer adjoining a cathode side is provided in an intermediate unit, an absolute value of an energy level of a lowest unoccupied molecular orbital (LUMO) of an electron extracting layer |LUMO (A)|, and an absolute value of an energy level of a highest occupied molecular orbital (HOMO) of an adjacent layer |HOMO (B)| are in the relationship of |HOMO (B)|−|LUMO (A)|≦1.5 eV, a light emitting layer situated on an intermediate unit of a first light emitting unit contains an arylamine-based hole transporting material, the light emitting layer is provided adjoining an electron extracting layer so as to function as the adjacent layer, and an intermediate unit supplies a hole generated by extraction of an electron from a light emitting layer by an electron extracting layer to a first light emitting unit, and supplies the extracted electron to a second light emitting unit.

A top emission-type organic electroluminescent display device in accordance with a third aspect of the present invention comprises an organic electroluminescent element having an element structure sandwiched between an anode and a cathode, an active matrix driving substrate having each active element for supplying a display signal for each display pixel to the organic electroluminescent element, and a transparent sealing substrate provided opposite to the active matrix driving substrate, in which an organic electroluminescent element is arranged between an active matrix driving substrate and a sealing substrate and, among a cathode and an anode, an electrode provided on a sealing substrate side is a transparent electrode, and is characterized in that an organic electroluminescent element is provided with a cathode, an anode, an intermediate unit arranged between a cathode and an anode, a first light emitting unit arranged between a cathode and the intermediate unit, and a second light emitting unit arranged between an anode and the intermediate unit, an electron extracting layer for extracting an electron from an adjacent layer adjoining a cathode side is provided in an intermediate unit, an absolute value of an energy level of a lowest unoccupied molecular orbital (LUMO) of an electron extracting layer |LUMO (A)|, and an absolute value of an energy level of a highest occupied molecular orbital (HOMO) of an adjacent layer |HOMO (B)| are in the relationship of |HOMO (B)|−|LUMO (A)|≦1.5 eV, a light emitting layer situated on an intermediate unit of a first light emitting unit contains an arylamine-based hole transporting material, the light emitting layer is provided adjoining an electron extracting layer so as to function as the adjacent layer, and an intermediate unit supplies a hole generated by extraction of an electron from a light emitting layer by an electron extracting layer to a first light emitting unit, and supplies the extracted electron to a second light emitting unit.

The organic EL element and the organic EL display device in accordance with a third aspect of the present invention are an organic EL element provided with at least two light emitting units, and are an organic EL element and an organic EL display device which can be driven at a low voltage, and have a high light emitting efficiency.

<Fourth Aspect>

An organic EL element in accordance with a fourth aspect of the present invention is provided with a cathode, an anode, an intermediate unit arranged between a cathode and an anode, a first light emitting unit arranged between a cathode and an intermediate unit, and a second light emitting unit arranged between an anode and an intermediate unit, and is characterized in that an electron extracting layer for extracting an electron from an adjacent layer adjoining a cathode side, and an electron injecting layer adjoining an anode side of an electron extracting layer are provided in an intermediate unit, an absolute value of an energy level of a lowest unoccupied molecular orbital (LUMO) of an electron extracting layer |LUMO (A)|, and an absolute value of an energy level of a highest occupied molecular orbital (HOMO) of an adjacent layer |HOMO (B)| are in the relationship of |HOMO (B)|−|LUMO (A)|≦1.5 eV, an absolute value of an energy level of a lowest unoccupied molecular orbital (LUMO) of an electron injecting layer |LUMO (C)| or an absolute value of a work function |WF (C)| is smaller than |LUMO (A)|, and an intermediate unit supplies a hole generated by extraction of an electron from an adjacent layer by an electron extracting layer and, at the same time, supplies the extracted electron to a second light emitting unit via an electron injecting layer.

In a fourth aspect of the present invention, an absolute value of an energy level of LUMO of an electron injecting layer |LUMO (C)| or an absolute value of a work function |WF (C)| is smaller than an absolute value of an energy level of LUMO of an electron extracting layer |LUMO (A)|. For this reason, an electron extracted by an electron extracting layer is moved to an electron injecting layer, and is supplied to a second light emitting unit from an electron injecting layer.

In the present invention, it is preferable that a thickness of an electron extracting layer is in a range of 8 to 100 nm. By adopting such the range, an organic electroluminescent element excellent in life property and a light emitting efficiency is obtained. When a thickness of an electron extracting layer is less than 8 nm, life property and a light emitting efficiency are reduced in some cases. In addition, when a thickness of an electron extracting layer exceeds 100 nm, life property and a light emitting efficiency are reduced and, further, a dark spot is generated in some cases. A further preferable thickness of an electron extracting layer is in a range of 10 to 80 nm and, particularly preferably, the thickness is in a range of 10 to 30 nm.

A bottom emission-type organic electroluminescent display device in accordance with a fourth aspect of the present invention comprises an organic electroluminescent element having an element structure sandwiched between an anode and a cathode, and an active matrix driving substrate having each active element for supplying a display signal for each display pixel to the organic electroluminescent element, in which the organic electroluminescent element is provided on the active matrix driving substrate and, among the cathode and the anode, an electrode provided on the substrate side is a transparent electrode, and is characterized in that an organic electroluminescent element is provided with a cathode, an anode, an intermediate unit arranged between a cathode and an anode, a first light emitting unit arranged between a cathode and an intermediate unit, and a second light emitting unit arranged between an anode and an intermediate unit, an electron extracting layer for extracting an element from an adjacent layer adjoining a cathode side, and an electron injecting layer adjoining an anode side of an electron extracting layer are provided in an intermediate unit, an absolute value of an energy level of a lowest unoccupied molecular orbital (LUMO) of an electron extracting layer |LUMO (A)|, and an absolute value of an energy level of a highest occupied molecular orbital (HOMO) of an adjacent layer |HOMO (B)| are in the relationship of |HOMO (B)|−|LUMO (A)|≦1.5 eV, an absolute value of an energy level of a lowest unoccupied molecular orbital (LUMO) of an electron injecting layer |LUMO (C)| or an absolute value of a work function |WF (C)| is smaller than |LUMO (A)|, and an intermediate unit supplies a hole generated by extraction of an electron from an adjacent layer by an electron extracting layer to a first light emitting unit and, at the same time, supplies the extracted electron to a second light emitting unit via an electron injecting layer.

A top emission-type organic electroluminescent display device in accordance with a fourth aspect of the present invention comprises an organic electroluminescent element having an element structure sandwiched between an anode and a cathode, an active matrix driving substrate having each active element for supplying a display signal for each display pixel to the organic electroluminescent element, and a transparent sealing substrate provided opposite to the active matrix driving substrate, in which an organic electroluminescent element is arranged between an active matrix driving substrate and a sealing substrate and, among a cathode and an anode, an electrode provided on a sealing substrate side is a transparent electrode, and is characterized in that an organic electroluminescent element is provided with a cathode, an anode, an intermediate unit arranged between a cathode and an anode, a first light emitting unit arranged between a cathode and an intermediate unit, and a second light emitting unit arranged between an anode and an intermediate unit, an electron extracting layer for extracting an element from an adjacent layer adjoining a cathode side, and an electron injecting layer adjoining an anode side of an electron extracting layer are provided in an intermediate unit, an absolute value of an energy level of a lowest unoccupied molecular orbital (LUMO) of an electron extracting layer |LUMO (A)|, and an absolute value of an energy level of a highest occupied molecular orbital (HOMO) of an adjacent layer |HOMO (B)| are in the relationship of |HOMO (B)|−|LUMO (A)|≦1.5 eV, an absolute value of an energy level of a lowest unoccupied molecular orbital (LUMO) of an electron injecting layer |LUMO (C)| or an absolute value of a work function |WF (C)| is smaller than |LUMO (A)|, and an intermediate unit supplies a hole generated by extraction of an electron from an adjacent layer by an electron extracting layer to a first light emitting unit and, at the same time, supplies the extracted electron to a second light emitting unit via an electron injecting layer.

The organic EL element and the organic EL display device in accordance with a fourth aspect of the present invention are an organic EL element provided with at least two light emitting units, and are an organic EL element and an organic EL display device which can be driven at a low voltage, and have a high light emitting efficiency.

<Fifth Aspect>

An organic El element in accordance with a fifth aspect of the present invention is an organic electroluminescent element provided with a cathode, an anode, an intermediate unit arranged between a cathode and an anode, a first light emitting unit arranged between a cathode and an intermediate unit, a second light emitting unit arranged between an anode and an intermediate unit, and a hole injecting unit arranged between an anode and a second light emitting unit, in which an electron extracting layer for extracting an electron from an adjacent layer adjoining a cathode side is provided in an intermediate unit, an absolute value of an energy level of a lowest unoccupied molecular orbital (LUMO) of an electron extracting layer |LUMO (A)|, and an absolute value of an energy level of a highest occupied molecular orbital (HOMO) of an adjacent layer |HOMO (B)| are in the relationship of |HOMO (B)|−|LUMO (A)|≦1.5 eV, and an intermediate unit supplies a hole generated by extraction of an electron from an adjacent layer by an electron extracting layer to a first light emitting unit and, at the same time, supplies the extracted electron to a second light emitting unit, and is characterized in that a hole injecting unit is constructed of a hole injecting layer comprising an arylamine-based hole transporting material, and a hole injection promoting layer arranged between the hole injecting layer and the anode, and an absolute value of an energy level of a highest occupied molecular orbital (HOMO) of a hole injection promoting layer |HOMO (X)|, as well as an absolute value of a work function of an anode |WF (Y)| and an absolute value of an energy level of a highest occupied molecular orbital (HOMO) of a hole injecting layer |HOMO (Z)| have the relationship of |WF (Y)|<|HOMO (X)|<|HOMO (Z)|.

According to a fifth aspect of the present invention, a hole injecting unit is provided between an anode and a second light emitting unit, and a hole injecting unit is constructed of a hole injecting layer comprising an arylamine-based hole transporting material, and a hole injection promoting layer arranged between the hole injecting layer and an anode. In addition, an absolute value of an energy level of HOMO of a hole injection promoting layer |HOMO (X)|, as well as an absolute value of a work function of an anode |WF (Y)| and an absolute value of an energy level of HOMO of a hole injecting layer |HOMO (Z)| have the relationship of |WF (Y)|<|HOMO (X)|<|HOMO (Z)|. Since an anode, a hole injection promoting layer and a hole injecting layer have the relationship of |WF (Y)|<|HOMO (X)|<|HOMO (Z)|, a hole from an anode is effectively moved to a hole injection promoting layer and a hole injecting layer, and is supplied to a second light emitting unit.

An organic EL element in accordance with a fifth aspect of the present invention is provided with at least two light emitting units of a first light emitting unit and a second light emitting unit, and an intermediate unit arranged between these light emitting units, and an electron extracting layer for extracting an electron from an adjacent layer is provided in an intermediate unit. By extraction of an electron from an adjacent layer of this electron extracting layer, a hole is generated in an adjacent layer, and this hole is supplied to a first light emitting unit. For this reason, a hole is effectively supplied to a first light emitting unit. As a result, as compared with a first light emitting unit, supply of a hole to a second light emitting unit is not sufficient, and a balance between a light emitting intensity of a first light emitting unit, and a light emitting intensity of a second light emitting unit is worsened in some cases.

According to a fifth aspect of the present invention, since a hole injecting unit consisting of the aforementioned hole injecting layer and a hole injection promoting layer is provided on an anode side of a second light emitting unit, injection of a hole into a second light emitting unit can be promoted, and a light emitting intensity of a second light emitting unit can be enhanced. Therefore, according to a fifth aspect of the present invention, a first light emitting unit and a second light emitting unit can emit light at a better balance, and a desired emitting color can be obtained.

In a fifth aspect of the present invention, a hole injecting layer of a hole injecting unit is formed of an arylamine-based hole transporting material. Examples of the arylamine-based hole transporting material include N,N′-bis-(3-methylphenyl)-N,N′-bis-(phenyl)-benzidine (TPD) and N,N′-di(naphthacen-1-yl)-N,N′-diphenylbenzidine (NPB).

In addition, a hole injection promoting layer of a hole injecting unit can be used without any limitation as far as its absolute value of an energy level of HOMO satisfies a relationship of the aforementioned equation.

A bottom emission-type organic electroluminescent display device in accordance with a fifth aspect of the present invention comprises an organic electroluminescent element having an element structure sandwiched between an anode and a cathode, and an active matrix driving substrate having each active element for supplying a display signal for each display pixel to the organic electroluminescent element, in which the organic electroluminescent element is provided on the active matrix driving substrate and, among the cathode and the anode, an electrode provided on the substrate side is a transparent electrode, and is characterized in that an organic electroluminescent element is an organic electroluminescent element provided with a cathode, an anode, an intermediate unit arranged between a cathode and an anode, a first light emitting unit arranged between a cathode and an intermediate unit, a second light emitting unit arranged between an anode and an intermediate unit, and a hole injecting unit arranged between an anode and a second light emitting unit, an electron extracting layer for extracting an electron from an adjacent layer adjoining a cathode side is provided in an intermediate unit, an absolute value of an energy level of a lowest unoccupied molecular orbital (LUMO) of an electron extracting layer |LUMO (A)|, and an absolute value of an energy level of a highest occupied molecular orbital (HOMO) of an adjacent layer |HOMO (B)| are in the relationship of |HOMO (B)|−|LUMO (A)|<1.5 eV, and an intermediate unit supplies a hole generated by extraction of an electron from an adjacent layer by an electron extracting layer to a first light emitting unit and, at the same time, supplies the extracted element to a second light emitting unit, in which a hole injecting unit is constructed of a hole injecting layer comprising an arylamine-based hole transporting material, and a hole injection promoting layer arranged between the hole injecting layer and an anode, and an absolute value of an energy level of a highest unoccupied molecular orbital (HOMO) of a hole injection promoting layer |HOMO (X)|, as well as an absolute value of a work function of an anode |WF (Y)| and an absolute value of an energy level of a highest occupied molecular orbital (HOMO) of a hole injecting layer |HOMO (Z)| have a relationship of |WF (Y)|<|HOMO (X)|<|HOMO (Z)|.

A top emission-type organic electroluminescent display device in accordance with a fifth aspect of the present invention comprises an organic electroluminescent element having an element structure sandwiched between an anode and a cathode, an active matrix driving substrate having each active element for supplying a display signal for each display pixel to the organic electroluminescent element, and a transparent sealing substrate provided opposite to the active matrix driving substrate, in which an organic electroluminescent element is arranged between an active matrix driving substrate and a sealing substrate and, among a cathode and an anode, an electrode provided on a sealing substrate side is a transparent electrode, and is characterized in that an organic electroluminescent element is an organic electroluminescent element provided with a cathode, an anode, an intermediate unit arranged between a cathode and an anode, a first light emitting unit arranged between a cathode and an intermediate unit, a second light emitting unit arranged between an anode and an intermediate unit, and a hole injecting unit arranged between an anode and a second light emitting unit, an electron extracting layer for extracting an electron from an adjacent layer adjoining a cathode side is provided in an intermediate unit, an absolute value of an energy level of a lowest unoccupied molecular orbital (LUMO) of an electron extracting layer |LUMO (A)|, and an absolute value of an energy level of a highest occupied molecular orbital (HOMO) of an adjacent layer |HOMO (B)| are in the relationship of |HOMO (B)|−|LUMO (A)|<1.5 eV, and an intermediate unit supplies a hole generated by extraction of an electron from an adjacent layer by an electron extracting layer to a first light emitting unit and, at the same time, supplies the extracted element to a second light emitting unit, in which a hole injecting unit is constructed of a hole injecting layer comprising an arylamine-based hole transporting material, and a hole injection promoting layer arranged between the hole injecting layer and an anode, and an absolute value of an energy level of a highest unoccupied molecular orbital (HOMO) of a hole injection promoting layer |HOMO (X)|, as well as an absolute value of a work function of an anode |WF (Y)| and an absolute value of an energy level of a highest occupied molecular orbital (HOMO) of a hole injecting layer |HOMO (Z)| have a relationship of |WF (Y)|<|HOMO (X)|<|HOMO (Z)|.

The organic EL element and the organic EL display device in accordance with a fifth aspect of the present invention are an organic EL element provided with at least two light emitting units, and are an organic EL element and an organic EL display device which can be driven at a low voltage, have a high light emitting efficiency, and exhibit a desired light emitting color.

<Sixth Aspect>

An organic EL element in accordance with a sixth aspect of the present invention is an organic EL element provided with a cathode, an anode, a light emitting unit arranged between a cathode and an anode, and a hole injecting unit arranged between an anode and a light emitting unit, and is characterized in that a hole injecting unit has a first electron extracting layer provided on an anode side, and a first adjacent layer comprising a hole transporting material provided adjoining a first electron extracting layer.

A hole injecting unit in a sixth aspect of the present invention has a first electron extracting layer, and a first adjacent layer, a first electron extracting layer is provided on an anode side, and a first adjacent layer is provided on a cathode side, and adjoins a first electron extracting layer. A first adjacent layer comprises a hole transporting material and, by applying a voltage to an organic EL element, an electron in a first adjacent layer is extracted by a first electron extracting layer. By this electron extraction, a hole is generated in a first adjacent layer, and this hole is supplied to a light emitting unit. In a light emitting unit, a supplied hole is recombined with an electron from a cathode, and a light emitting unit emits light. On the other hand, an electron extracted by a first electron extracting layer is absorbed in an anode.

As described above, in the present invention, by extraction of an electron by a first electron extracting layer from a first adjacent layer, a hole is generated in a first adjacent layer, and this hole is supplied to a light emitting unit. For this reason, according to a sixth aspect of the present invention, a hole can be effectively supplied to a light emitting unit from a hole injecting unit. Therefore, a driving voltage can be reduced, and a light emitting efficiency can be enhanced. In a sixth aspect of the present invention, an absolute value of an energy level of a lowest unoccupied molecular orbital (LUMO) of a first electron extracting layer of a hole injecting unit |LUMO (A₁)|, and an absolute value of an energy level of a highest occupied molecular orbital (HOMO) of a first adjacent layer |HOMO (B₁)| are preferably in a relationship of |HOMO (B₁)|−|LUMO (A₁)|≦1.5 eV. That is, it is preferable that an energy level of LUMO of a first electron extracting layer is a value close to an energy level of HOMO of a first adjacent layer. Therefore, a first electron extracting layer becomes possible to easily extract an electron from a first adjacent layer, and many holes can be generated by a first adjacent layer. Therefore, a driving voltage can be further reduced, and a light emitting efficiency can be further improved.

In a sixth aspect of the present invention, a light emitting unit may be a single light emitting unit, or may be a combination of a plurality of light emitting units. When a plurality of light emitting units are combined, as in the aforementioned present invention, it is preferable that they are combined by holding an intermediate unit. Specifically, it is preferable that a first light emitting unit provided on a cathode side, and a second light emitting unit provided on an anode side are possessed, holding an intermediate unit. In addition, it is preferable that an intermediate unit is provided with the same electron extracting layer and adjacent layer as those of a hole injecting unit, thereby, a hole can be supplied to a first light emitting unit.

In a sixth aspect of the present invention, first and second adjacent layers are formed of preferably a hole transporting material, particularly preferably an arylamine-based hole transporting material.

In a sixth aspect of the present invention, a second adjacent layer of an intermediate unit may be provided in a first light emitting unit. In particular, when a host material of a light emitting layer situated on an intermediate unit in a first light emitting unit is a hole transporting material suitable as a second adjacent layer, a light emitting layer on an intermediate unit side in a first light emitting unit can be a second adjacent layer.

In addition, in a sixth aspect of the present invention, a second adjacent layer may be provided in an intermediate unit. When a host material in a light emitting layer on an intermediate unit side in a first light emitting unit is not a hole transporting material suitable as a second adjacent layer, since it cannot function as a second adjacent layer in some cases and, in such the case, a second adjacent layer can be provided in an intermediate unit. In such the case, a second adjacent layer is arranged between a second electron extracting layer and a first light emitting unit.

In the present invention, first and second electron extracting layers can be formed, for example, of a pyrazine derivative represented by the aforementioned structural formula.

In the present invention, first and second electron extracting layers can be further preferably formed of a hexaazatriphenylene derivative represented by the aforementioned structural formula.

A bottom emission-type organic electroluminescent display device in accordance with a sixth aspect of the present invention comprises an organic electroluminescent element having an element structure sandwiched between an anode and a cathode, and an active matrix driving substrate having each active element for supplying a display signal for each display pixel to the organic electroluminescent element, in which the organic electroluminescent element is provided on the active matrix driving substrate and, among the cathode and the anode, an electrode provided on the substrate side is a transparent electrode, and is characterized in that an organic electroluminescent element is an organic electroluminescent element provided with a cathode, an anode, a light emitting unit arranged between a cathode and an anode, and a hole injecting unit arranged between an anode and a light emitting unit, and a hole injecting unit has a first electron extracting layer provided on an anode side, and a first adjacent layer comprising a hole transporting material provided adjoining a first electron extracting layer on a cathode side.

A top emission-type organic electroluminescent display device in accordance with a sixth aspect of the present invention comprises an organic electroluminescent element having an element structure sandwiched between an anode and a cathode, an active matrix driving substrate having each active element for supplying a display signal for each display pixel to the organic electroluminescent element, and a transparent sealing substrate provided opposite to the active matrix driving substrate, in which an organic electroluminescent element is arranged between an active matrix driving substrate and a sealing substrate and, among a cathode and an anode, an electrode provided on a sealing substrate side is a transparent electrode, and is characterized in that an organic electroluminescent element is an organic electroluminescent element provided with a cathode, an anode, a light emitting unit arranged between a cathode and an anode, and a hole injecting unit arranged between an anode and a light emitting unit, and a hole injecting unit has a first electron extracting layer provided on an anode side, and a first adjacent layer comprising a hole transporting material provided adjoining a first electron extracting layer on a cathode side.

The organic EL element and the organic EL display device in accordance with a sixth aspect of the present invention are an organic EL element and an organic EL display device which can be driven at a low voltage, and have a high light emitting efficiency.

<Seventh Aspect>

An organic EL element in accordance with a seventh aspect of the present invention is an organic electroluminescent element provided with a cathode, an anode, a plurality of light emitting units arranged between a cathode and an anode, and an intermediate unit arranged between light emitting units, in which an intermediate unit has an electron transporting layer provided on an anode side, and an electron extracting layer provided on a cathode side, an electron extracting layer is a layer for extracting an electron from an adjacent layer adjoining a cathode side of an electron extracting layer, an absolute level of an energy level of a lowest unoccupied molecular orbital (LUMO) of an electron extracting layer |LUMO (A)|, and an absolute value of an energy level of a highest occupied molecular orbital (HOMO) of an adjacent layer |HOMO (B)| are in the relationship of |HOMO (B)|−|LUMO (A)|≦1.5 eV, and an intermediate unit supplies a hole generated by extraction of an electron from an adjacent layer by an electron extracting layer to a light emitting unit on a cathode side and, at the same time, supplies the extracted electron to a light emitting unit on an anode side via an electron transporting layer, and is characterized in that an electron transporting layer is provided also between a cathode, and a light emitting unit closest to a cathode, a film thickness of each electron transporting layer is set to be greater as it becomes more distant from a cathode, and to be 40 nm or smaller.

In the previous organic EL element provided with a plurality of light emitting units, injection of an electron is performed smoothly in a light emitting unit closer to a cathode, but injection of an electron becomes smaller in a light emitting unit far from a cathode. For this reason, a light emitting intensity in a light emitting unit far from a cathode becomes relatively weak, and there is a problem that a high light emitting efficiency cannot be obtained. In a seventh aspect of the present invention, a film thickness of each electron transporting layer is set to be greater as it becomes more distant from a cathode. For this reason, injection of an electron in a light emitting unit far from a cathode is enhanced, and a light emitting intensity in a light emitting unit far from a cathode can be relatively enhanced. As a result, a balance of a light emitting intensity in each light emitting unit can be improved, and a light emitting efficiency as a whole element can be improved.

In addition, in a seventh aspect of the present invention, a film thickness of each electron transporting layer is set to be 40 nm or smaller. When a film thickness of an electron transporting layer exceeds 40 nm, since an electron is not moved smoothly, there is a tendency that a light emitting efficiency is reduced.

In addition, when a plurality of light emitting units are provided, as in the aforementioned injection of an electron, injection of a hole into a light emitting unit becomes insufficient in some cases, as an anode becomes more distant from an anode. In an intermediate unit, a hole is injected from an electron extracting layer. Therefore, when a hole injecting layer is provided between an anode, and a light emitting unit closest to an anode, it is preferable that film thicknesses of the hole injecting layer and each electron extracting layer are set to be greater as they become more distant from an anode. By setting film thicknesses of a hole injecting layer and each electron extracting layer like this, also in light emitting unit far from an anode, a hole can be sufficiently injected, a balance of a light emitting intensity in each light emitting unit can be improved, and a light emitting efficiency as a whole element can be further enhanced.

It is preferable that a hole injecting layer and each electron extracting layer are set to be 100 nm or smaller. When film thicknesses of a hole injecting layer and each electron extracting layer exceeds 100 nm, movement of a hole is conversely prevented, and there is a tendency that a light emitting intensity is reduced.

An organic EL element in accordance with other embodiment of a seventh aspect of the present invention is characterized in that film thicknesses of a hole injecting layer and each electron extracting layer are set to be greater as they become more distant from an anode, and are set to be 100 nm or smaller as described above.

An organic EL element in accordance with other embodiment of a seventh aspect of the present invention is an organic electroluminescent element provided with a cathode, an anode, a plurality of light emitting units arranged between a cathode and an anode, and an intermediate unit arranged between light emitting units, in which an intermediate unit has an electron transporting layer provided on an anode side, and an electron extracting layer provided on a cathode side, an electron extracting layer is a layer for extracting an electron from an adjacent layer adjoining a cathode side of an electron extracting layer, an absolute value of an energy level of a lowest unoccupied molecular orbital (LUMO) of an electron extracting layer |LUMO (A)|, and an absolute value of an energy level of a highest occupied molecular orbital (HOMO) of an adjacent layer |HOMO (B)| are in the relationship of |HOMO (B)|−|LUMO (A)|≦1.5 eV, and an intermediate unit supplies a hole generated by extraction of an electron from an adjacent layer by an electron extracting layer to a light emitting unit on a cathode side and, at the same time, supplies the extracted electron to a light emitting unit on an anode side via an electron transporting layer, and is characterized in that a hole injecting layer is provided between an anode, and a light emitting unit closest to an anode, and film thicknesses of the hole injecting layer and each electron extracting layer are set to be greater as they become more distant from an anode, and a set to be 100 nm or smaller.

In a seventh aspect of the present invention, by arranging an intermediate unit between a plurality of light emitting units, and supplying a carrier from the intermediate unit, a light emitting unit is made to emit light. The function of an intermediate unit is as described above.

In addition, in a seventh aspect of the present invention, electron transporting layers on a cathode side and in an intermediate unit can be formed of a material which is generally used as an electron transporting material in an organic EL element. Examples include a phenanthroline derivative, a silol derivative, a triazole derivative, a quinolinol metal complex derivative, and an oxadiazole derivative.

A bottom emission-type organic electroluminescent display device in accordance with a seventh aspect of the present invention comprises an organic electroluminescent element having an element structure sandwiched between an anode and a cathode, and an active matrix driving substrate having each active element for supplying a display signal for each display pixel to the organic electroluminescent element, in which the organic electroluminescent element is provided on the active matrix driving substrate and, among the cathode and the anode, an electrode provided on the substrate side is a transparent electrode, and is characterized in that an organic electroluminescent element is an organic electroluminescent element provided with a cathode, an anode, a plurality of light emitting units arranged between a cathode and an anode, and an intermediate unit arranged between light emitting units, in which an intermediate unit has an electron transporting layer provided on an anode side, and an electron extracting layer provided on a cathode side, an electron extracting layer is a layer for extracting an electron from an adjacent layer adjoining a cathode side of an electron extracting layer, an absolute value of an energy level of a lowest unoccupied molecular orbital (LUMO) of an electron extracting layer |LUMO (A)|, and an absolute value of an energy level of a highest occupied molecular orbital (HOMO) of an adjacent layer |HOMO (B)| are in the relationship of |HOMO (B)|−|LUMO (A)|≦1.5 eV, and an intermediate unit supplies a hole generated by extraction of an electron from an adjacent layer by an electron extracting layer to a light emitting unit on a cathode side and, at the same time, supplies the extracted electron to a light emitting unit of an anode side via an electron transporting layer, an electron transporting layer is provided also between a cathode, and a light emitting unit closest to a cathode, and a film thickness of each electron transporting layer is set to be greater as it becomes more distant from a cathode, and is set to be 40 nm or smaller.

A top emission-type organic electroluminescent display device in accordance with a seventh aspect of the present invention comprises an organic electroluminescent element having an element structure sandwiched between an anode and a cathode, an active matrix driving substrate having each active element for supplying a display signal for each display pixel to the organic electroluminescent element, and a transparent sealing substrate provided opposite to the active matrix driving substrate, in which an organic electroluminescent element is arranged between an active matrix driving substrate and a sealing substrate and, among a cathode and an anode, an electrode provided on a sealing substrate side is a transparent electrode, and is characterized in that an organic electroluminescent element is an organic electroluminescent element provided with a cathode, an anode, a plurality of light emitting units arranged between a cathode and an anode, and an intermediate unit arranged between light emitting units, in which an intermediate unit has an electron transporting layer provided on an anode side, and an electron extracting layer provided on a cathode side, an electron extracting layer is a layer for extracting an electron from an adjacent layer adjoining a cathode side of an electron extracting layer, an absolute value of an energy level of a lowest unoccupied molecular orbital (LUMO) of an electron extracting layer |LUMO (A)|, and an absolute value of an energy level of a highest occupied molecular orbital (HOMO) of an adjacent layer |HOMO (B)| are in the relationship of |HOMO (B)|−|LUMO (A)|≦1.5 eV, and an intermediate unit supplies a hole generated by extraction of an electron from an adjacent layer by an electron extracting layer to a light emitting unit on a cathode side and, at the same time, supplies the extracted electron to a light emitting unit of an anode side via an electron transporting layer, an electron transporting layer is provided also between a cathode, and a light emitting unit closest to a cathode, and a film thickness of each electron transporting layer is set to be greater as it becomes more distant from a cathode, and is set to be 40 nm or smaller.

A bottom emission-type organic electroluminescent display device in accordance with other embodiment of a seventh aspect of the present invention comprises an organic electroluminescent element having an element structure sandwiched between an anode and a cathode, and an active matrix driving substrate having each active element for supplying a display signal for each display pixel to the organic electroluminescent element, in which the organic electroluminescent element is provided on the active matrix driving substrate and, among the cathode and the anode, an electrode provided on the substrate side is a transparent electrode, and is characterized in that an organic electroluminescent element is an organic electroluminescent element provided with a cathode, an anode, a plurality of light emitting units arranged between a cathode and an anode, and an intermediate unit arranged between light emitting units, in which an intermediate unit has an electron transporting layer provided on an anode side, and an electron extracting layer provided on a cathode side, an electron extracting layer is a layer for extracting an electron from an adjacent layer adjoining a cathode side of an electron extracting layer, an absolute value of an energy level of a lowest unoccupied molecular orbital (LUMO) of an electron extracting layer |LUMO (A)|, and an absolute value of an energy level of a highest occupied molecular orbital (HOMO) of an adjacent layer |HOMO (B)| are in the relationship of |HOMO (B)|−|LUMO (A)|≦1.5 eV, and an intermediate unit supplies a hole generated by extraction of an electron from an adjacent layer by an electron extracting layer to a light emitting unit on a cathode side and, at the same time, supplies the extracted electron to a light emitting unit on an anode side via an electron transporting layer, a hole injecting layer is provided between an anode, and a light emitting unit closest to an anode, and film thicknesses of the hole injecting layer and each electron extracting layer are set to be greater as they become more distant from an anode, and are set to be 100 nm or smaller.

A top emission-type organic electroluminescent display device in accordance with other embodiment of a seventh aspect of the present invention comprises an organic electroluminescent element having an element structure sandwiched between an anode and a cathode, an active matrix driving substrate having each active element for supplying a display signal for each display pixel to the organic electroluminescent element, and a transparent sealing substrate provided opposite to the active matrix driving substrate, in which an organic electroluminescent element is arranged between an active matrix driving substrate and a sealing substrate and, among a cathode and an anode, an electrode provided on a sealing substrate side is a transparent electrode, and is characterized in that an organic electroluminescent element is an organic electroluminescent element provided with a cathode, an anode, a plurality of light emitting units arranged between a cathode and an anode, and an intermediate unit arranged between light emitting units, in which an intermediate unit has an electron transporting layer provided on an anode side, and an electron extracting layer provided on a cathode side, an electron extracting layer is a layer for extracting an electron from an adjacent layer adjoining a cathode side of an electron extracting layer, an absolute value of an energy level of a lowest unoccupied molecular orbital (LUMO) of an electron extracting layer |LUMO (A)|, and an absolute value of an energy level of a highest occupied molecular orbital (HOMO) of an adjacent layer |HOMO (B)| are in the relationship of |HOMO (B)|−|LUMO (A)|≦1.5 eV, and an intermediate unit supplies a hole generated by extraction of an electron from an adjacent layer by an electron extracting layer to a light emitting unit on a cathode side and, at the same time, supplies the extracted electron to a light emitting unit on an anode side via an electron transporting layer, a hole injecting layer is provided between an anode, and a light emitting unit closest to an anode, and film thicknesses of the hole injecting layer and each electron extracting layer are set to be greater as they become more distant from an anode, and are set to be 100 nm or smaller.

The organic EL element and the organic EL display device in accordance with a seventh aspect of the present invention are provided with a plurality of light emitting units by laminating them, and exhibit a high light emitting efficiency.

<Eighth Aspect>

An organic EL element in accordance with an eighth-1 aspect of the present invention is an organic electroluminescent element provided with a cathode, an anode, a plurality of light emitting units arranged between a cathode and an anode, and an intermediate unit arranged between light emitting units, in which an intermediate unit has an electron transporting layer provided on an anode side, and an electron extracting layer provided on a cathode side, an electron extracting layer is a layer for extracting an electron from an adjacent layer adjoining a cathode side of an electron extracting layer, an absolute value of an energy level of a lowest unoccupied molecular orbital (LUMO) of an electron extracting layer |LUMO (A)|, and an absolute value of an energy level of a highest occupied molecular orbital (HOMO) of an adjacent layer |HOMO (B)| are in the relationship of |HOMO (B)|−|LUMO (A)|≦2.0 eV, and an intermediate unit supplies a hole generated by extraction of an electron from an adjacent layer by an electron extracting layer to a light emitting unit on a cathode side and, at the same time, supplies the extracted electron to a light emitting unit on an cathode side via an electron transporting layer, and is characterized in that an electron extraction promoting material having an absolute value of an energy level of a lowest unoccupied molecular orbital (LUMO) |LUMO (C)| in the relationship of |HOMO (B)|>|LUMO (C)|>|LUMO (A)| is doped into an electron extracting layer.

An organic EL element in accordance with an eighth-2 aspect of the present invention is an organic electroluminescent element provided with a cathode, an anode, a plurality of light emitting units arranged between a cathode and an anode, and an intermediate unit arranged between light emitting units, in which an intermediate unit has an electron transporting layer provided on an anode side, and an electron extracting layer provided on a cathode side, an electron extracting layer is a layer for extracting an electron from an adjacent layer adjoining a cathode side of an electron extracting layer, an absolute value of an energy level of a lowest unoccupied molecular orbital (LUMO) of an electron extracting layer |LUMO (A)|, and an absolute value of an energy level of a highest occupied molecular orbital (HOMO) of an adjacent layer |HOMO (B)| are in the relationship of |HOMO (B)−|LUMO (A)|≦2.0 eV, and an intermediate unit supplies a hole generated by extraction of an electron from an adjacent layer by an electron extracting layer to a light emitting unit on a cathode side and, at the same time, supplies the extracted electron to a light emitting unit on an anode side via an electron transporting layer, and is characterized in that an electron extraction promoting layer comprising an electron extraction promoting material having an absolute value of an energy level of a lowest occupied molecular orbital (LUMO) |LUMO (C)| in the relationship of |HOMO (B)|>|LUMO (C)|>|LUMO (A)| is provided between an electron extracting layer and an adjacent layer.

An organic EL element in accordance with an eighth-3 aspect of the present invention is an organic electroluminescent element provided with a cathode, an anode, a plurality of light emitting units arranged between a cathode and an anode, and an intermediate unit arranged between light emitting units, in which an intermediate unit has an electron transporting layer provided on an anode side, and an electron extracting layer provided on a cathode side, an electron extracting layer is a layer for extracting an electron from an adjacent layer adjoining a cathode side of an electron extracting layer, an absolute value of an energy level of a lowest unoccupied molecular orbital (LUMO) of an electron extracting layer |LUMO (A)|, and an absolute value of an energy level of a highest occupied molecular orbital (HOMO) of an adjacent layer |HOMO (B)| are in the relationship of |HOMO (B)|−|LUMO (A)|≦2.0 eV, and an intermediate unit supplies a hole generated by extraction of an electron from an adjacent layer by an electron extracting layer to a light emitting unit of a cathode side and, at the same time, supplies the extracted electron to a light emitting unit on an anode side via an electron transporting layer, and is characterized in that an electron injecting organic material having an absolute value of an energy level of a lowest unoccupied molecular orbital (LUMO) |LUMO (D)| in the relationship of |LUMO (A)|>|LUMO (D)|>|LUMO (D)| relative to an absolute value of an energy level of a lowest unoccupied molecular orbital (LUMO) of an electron transporting layer |LUMO (E)| and |LUMO (A)| is doped into an electron transporting layer and/or an electron extracting layer.

An organic EL element in accordance with an eighth-4 aspect of the present invention is an organic electroluminescent element provided with a cathode, an anode, a plurality of light emitting units arranged between a cathode and an anode, an intermediate unit arranged between light emitting units, in which an intermediate unit has an electron transporting layer provided on an anode side, and an electron extracting layer provided on a cathode side, an electron extracting layer is a layer for extracting an electron from an adjacent layer adjoining a cathode side of an electron extracting layer, an absolute value of an energy level of a lowest unoccupied molecular orbital (LUMO) of an electron extracting layer |LUMO (A)| and an absolute value of an energy level of a highest occupied molecular orbital (HOMO) of an adjacent layer |HOMO (B)| are in the relationship of |HOMO (B)|−|LUMO (A)|≦2.0 eV, and an intermediate unit supplies a hole generated by extraction of an electron from an adjacent layer by an electron extracting layer to a light emitting unit on a cathode side and, at the same time, supplies the extracted electron to a light emitting unit on an anode side via an electron transporting layer, and is characterized in that an electron injecting organic material layer comprising an electron injecting organic material having an absolute value of an energy level of a lowest unoccupied molecular orbital (LUMO) |LUMO (D)| in the relationship of |LUMO (A)|>|LUMO (D)|>|LUMO (E)| relative to an absolute value of an energy level of a lowest unoccupied molecular orbital (LUMO) of an electron transporting layer |LUMO (E)| and |LUMO (A)| is provided between an electron extracting layer and an electron transporting layer.

Organic EL element in accordance with an eighth-5 aspect of the present invention is an organic electroluminescent element provided with a cathode, an anode, a plurality of light emitting units arranged between a cathode and an anode, and an intermediate unit arranged between light emitting units, in which an intermediate unit has an electron transporting layer provided on an anode side, and an electron extracting layer provided on a cathode side, an electron extracting layer is a layer for extracting an electron from an adjacent layer adjoining a cathode side of an electron extracting layer, an absolute value of an energy level of a lowest unoccupied molecular orbital (LUMO) of an electron extracting layer |LUMO (A)|, and an absolute value of an energy level of a highest occupied molecular orbital (HOMO) of an adjacent layer |HOMO (B)| are in the relationship of |HOMO (B)|−|LUMO (A)|≦2.0 eV, and an intermediate unit supplies a hole generated by extraction of an electron from an adjacent layer by an electron extracting layer and, at the same time, supplies the extracted electron to a light emitting unit on an anode side via an electron transporting layer, and is characterized in that an electron injecting layer comprising at least one kind selected from an alkali metal, an alkaline earth metal, and an oxide thereof is provided between the electron extracting layer and the electron transporting layer, and an electron injecting organic material or an electron extracting layer having an absolute value of an energy level of a lowest unoccupied molecular orbital (LUMO) |LUMO (D)| in the relationship of |LUMO (A)|>|LUMO (D)|>|LUMO (E)| relative to an absolute value of an energy level of a lowest unoccupied molecular orbital (LUMO) of an electron transporting layer |LUMO (E)| and |LUMO (A)| is doped into an electron injecting layer.

In an eighth aspect of the present invention, by arranging an intermediate unit between a plurality of light emitting units, and supplying a carrier from the intermediate unit, a light emitting unit is made to emit light. The function of an intermediate unit is as described above.

An organic EL element in accordance with an eighth-1 of the present invention is characterized in that, in the aforementioned organic EL element of the present invention, an electron extraction promoting material having an absolute value of an energy level of a lowest unoccupied molecular orbital (LUMO) |LUMO (C)| in the relationship of |HOMO (B)|>|LUMO (C)|>|LUMO (A)| is doped into an electron extracting layer. An energy level of LUMO of an electron extraction promoting material has a value between an energy level of HOMO of an adjacent layer and an energy level of LUMO of an electron extracting layer. For this reason, in an electron extracting layer doped with such the electron extraction promoting material, extraction of an electron from an adjacent layer becomes easy. Therefore, according to an eighth-1 aspect of the present invention, since an electron extracting layer can effectively extract an electron from an adjacent layer, a light emitting efficiency can be further enhanced.

For example, as described above, it is preferable that the relationship between |LUMO(A)| of an electron extracting layer and |HOMO (B)| of an adjacent layer satisfies the following relationship.
0≦|HOMO(B)|−|LUMO(A)|≦1.5 eV

However, in the <eighth aspect>, when an electron extraction promoting material having an energy value of |LUMO(C)| is present between an electron extracting layer and an adjacent layer, and the magnitude relationship between absolute values of energies thereof is:
|HOMO(B)|>|LUMO(C)|LUMO(A)|,
an acceptable range of |HOMO(B)| and |LUMO(A)| can be extended to the following range.
0≦|HOMO(B)|−|LUMO(A)|≦2.0 eV

This is because, due to the presence of an electron extraction assisting material, extraction of an electron from an adjacent layer occurs via an electron extraction assisting material. Therefore, even when an energy difference between |LUMO(A)| of an electron extracting layer and |HOMO(B)| of an adjacent layer grows larger, the electron extracting effect is sufficiently obtained. In this case, an electron extraction assisting material may be used as a dopant, or may be inserted as a layer.

For example, Example 10 of Table 8 is a combination of an electron extracting layer HAT-CN6 and an adjacent layer CBP. In that case, a difference between |LUMO(HAT-CN6) of HAT-CN6 and |HOMO(CBP)| of CBP is 1.5 eV (Table 9).

When this electron extracting layer of Example 10 is changed from HAT-CN6 to DTN, this results in:
|HOMO(CBP)|−|LUMO(DTN)|=2.0 eV.
Wherein, |HOMO(CBP)|=5.9 eV, |LUMO(DTN)|=3.9 eV.
Then, a driving voltage of this element is 45V, and a light emitting efficiency was 8 cd/A, that is, a voltage was increased and, at the same time, a light emitting efficiency was remarkably reduced. And, 4F-TCNQ was doped into a DTN layer at a doping amount of 25%. |LUMO (4F-TCNQ)| of 4F-TCNQ is 4.6 eV. Then, a voltage of this element was reduced to 29V, and a light emitting efficiency was improved to 22 cd/A. Thereby, even in the case of |HOMO(B)|−|LUMO(A)|=2.0 eV, when an electron extraction assisting material having an intermediate energy value |LUMO(C)| is present, light emitting property can be sufficiently improved.

An organic EL element in accordance with an eighth-2 aspect of the present invention, and the aforementioned organic EL element of the present invention, are characterized in that an electron extraction promoting layer comprising an electron extraction promoting material having an absolute value of an energy level of a lowest unoccupied molecular orbital (LUMO)|LUMO (C)| in the relationship of |HOMO (B)|>|LUMO (C)|>|LUMO (A)| is provided between an electron extracting layer and an adjacent layer. In an eighth-2 aspect of the present invention, an electron extraction promoting layer comprising an electron extraction promoting material is provided between an electron extracting layer and an adjacent layer. As described above, an energy level of LUMO of an electron extraction promoting material has a value between an energy level of HOMO of an adjacent layer, and an energy level of LUMO of an electron extracting layer. For this reason, as compared with the case where an electron extracting layer is directly contacted with an adjacent layer, extraction of an electron from an adjacent layer can be more easily performed. Therefore, according to an eighth-2 aspect of the present invention, an electron can be effectively extracted from an adjacent layer, and a light emitting efficiency can be further enhanced.

An organic EL element in accordance with an eighth-3 aspect of the present invention is characterized in that, in the aforementioned organic EL element of the present invention, an electron injecting organic material having an absolute value of an energy |LUMO (D)| in the relationship of |LUMO (A)|>|LUMO (D)|>|LUMO (E)| relative to an absolute value of an energy level of a lowest unoccupied molecular orbital (LUMO) of an electron transporting layer |LUMO (E)| and |LUMO (A)| is doped into an electron transporting layer and/or an electron extracting layer. An energy level of LUMO of an electron injecting organic material is a value between an energy level of LUMO of an electron extracting layer, and an energy level of LUMO of an electron transporting layer. Since such the electron injecting organic material is doped into an electron transporting layer and/or an electron extracting layer, an intermediate energy level can be provided between an electron extracting layer and an electron transporting layer, thereby, injection of an electron into an electron transporting layer from an electron extracting layer can be promoted. Therefore, according to an eighth-3 aspect of the present invention, since an electron can be effectively injected into an electron transporting layer from an electron extracting layer, a light emitting efficiency can be further enhanced.

An organic EL element in accordance with an eighth-4 aspect of the present invention is characterized in that, in the aforementioned organic EL element of the present invention, an electron injecting organic material layer comprising an electron injecting organic material having an absolute value of an energy level of a lowest unoccupied molecular orbital (LUMO) of an electron transporting layer in the relationship of |LUMO (A)|>|LUMO (D)|>|LUMO (E)| relative to an absolute value of an energy level of a lowest unoccupied molecular orbital (LUMO) of an electron transporting layer is provided between an electron extracting layer and an electron transporting layer. In an eighth-4 aspect, an electron injecting organic material layer comprising an electron injecting organic material is provided between an electron extraction layer and an electron transporting layer. For this reason, an energy level of LUMO of an electron injecting organic material layer having an intermediate value between an energy level of LUMO of an electron extracting layer and an energy level of LUMO of an electron transporting layer is provided therebetween, and injection of an electron into an electron transporting layer from an electron extracting layer is promoted. Therefore, according to an eighth-4 aspect of the present invention, an electron can be effectively injected into an electron transporting layer from an electron extracting layer, and a light emitting efficiency can be further improved. In an eighth-1 aspect to an eighth-3 aspect of the present invention, it is preferable that an electron injecting layer comprising at least one kind selected from an alkali metal, an alkaline earth metal, and an oxide thereof is provided between an electron extracting layer and an electron transporting layer. It is preferable that an absolute value of an energy level of LUMO of an electron injecting layer |LUMO (F)| or an absolute value of a work function |WF (F)| is smaller than an absolute value of an energy level of LUMO of an electron extracting layer |LUMO (A)|. An electron extracted from an electron extracting layer is moved to an electron injecting layer, and is supplied to a light emitting unit from an electron injecting layer via an electron transporting layer.

In addition, it is preferable that an absolute value of an energy level of LUMO of an electron transporting layer |LUMO (E)| is smaller than an absolute value of an energy level of LUMO of an electron injecting layer |LUMO (F)| or an absolute value of a work function |WF (F)|. An electron moved into an electron injecting layer is supplied to a light emitting unit through an electron transporting layer. In an eighth-4 aspect of the present invention, it is preferable that the electron injecting layer is provided between an electron extracting layer and an electron injecting organic material layer. By providing an electron injecting layer between an electron extracting layer and an electron injecting organic material layer, an electron from an electron extracting layer can be effectively supplied to an electron transporting layer.

An eighth-5 aspect of the present invention is characterized in that the electron injecting layer is provided between an electron extracting layer and an electron transporting layer, and the electron injecting organic material or a material for the electron extracting layer is doped into an electron injecting layer. By doping an electron injecting organic material for a material for an electron extracting layer into an electron injecting layer, an electron from an electron extracting layer can be effectively supplied to an electron transporting layer. An electron injecting layer doped with an electron injecting organic material or a material for an electron extracting layer may be constructed of a plurality of layers. For example, an electron injecting layer may be constructed of a laminated structure in which a first electron injecting layer doped with an electron extracting layer material is arranged on a cathode side, and a second electron injecting layer doped with an electron injecting organic material is arranged on an anode side.

Examples of an alkali metal forming an electron injecting layer include Li, and Cs. Examples of an alkali metal oxide include Li₂O. Examples of an alkaline earth metal include Mg. In addition, an electron injecting layer may be formed of a carbonate salt of an alkali metal and an alkaline earth metal (e.g. Cs₂CO₃).

An electron transporting layer in an intermediate unit in the present invention may be formed of a material which is generally used as an electron transporting material in an organic EL element. Examples include a phenanthroline derivative, a silol derivative, a triazole derivative, a quinolinol metal complex derivative, and an oxadiazole derivative.

A bottom emission-type organic electroluminescent display device in accordance with a eighth aspect of the present invention comprises an organic electroluminescent element having an element structure sandwiched between an anode and a cathode, and an active matrix driving substrate having each active element for supplying a display signal for each display pixel to the organic electroluminescent element, in which the organic electroluminescent element is provided on the active matrix driving substrate and, among the cathode and the anode, an electrode provided on the substrate side is a transparent electrode, and is characterized in that an organic electroluminescent device is an organic electroluminescent element in accordance with any of an eighth-1 aspect to an eighth-5 aspect of the present invention.

A top emission-type organic electroluminescent display device in accordance with an eighth aspect of the present invention comprises an organic electroluminescent element having an element structure sandwiched between an anode and a cathode, an active matrix driving substrate having each active element for supplying a display signal for each display pixel to the organic electroluminescent element, and a transparent sealing substrate provided opposite to the active matrix driving substrate, in which an organic electroluminescent element is arranged between an active matrix driving substrate and a sealing substrate and, among a cathode and an anode, an electrode provided on a sealing substrate side is a transparent electrode, and is characterized in that an organic electroluminescent device is an organic electroluminescent element in accordance with any of an eighth-1 aspect to an eighth-5 aspect of the present invention.

The organic EL element and the organic EL display device in accordance with an eighth aspect of the present invention are provided with a plurality of light emitting units by laminating them, and exhibit a high light emitting efficiency.

According to an eighth-1 aspect and an eighth-2 aspect of the present invention, an electron extraction promoting material is doped into an electron extracting layer, or an electron extraction promoting layer comprising an electron extraction promoting material is provided between an electron extracting layer and an adjacent layer. For this reason, extraction of an electron from an adjacent layer by an electron extracting layer can be more effectively performed, and a light emitting efficiency can be further enhanced. In accordance with an eighth-3 aspect to an eighth-5 aspect of the present invention, an electron injecting organic material is doped into an electron transporting layer and/or an electron extracting layer, or an electron injecting organic material or a material for an electron extracting layer is doped into an electron injecting layer, or an electron injecting organic material layer comprising an electron injecting organic material is provided between an electron extracting layer and an electron transporting layer. Thereby, injection of an electron into an electron transporting layer from an electron extracting layer can be more effectively performed. For this reason, a light emitting efficiency can be further enhanced.

### BRIEF DESCRIPTION OF THE DRAWINGS

FIG. 1 is a schematic cross-sectional view showing an organic EL element of one example in accordance with the present invention.

FIG. 2 is a view showing an energy diagram around an intermediate unit.

FIG. 3 is a view showing a relationship between a film thickness of a Li₂O layer and a light emitting efficiency.

FIG. 4 is a cross-sectional view showing a bottom emission-type organic EL display device of an example in accordance with the present invention.

FIG. 5 is a cross-sectional view showing a top emission-type organic EL display device of an example in accordance with the present invention.

FIG. 6 is a schematic cross-sectional view showing an organic EL element of another example in accordance with the present invention.

FIG. 7 is a SIMS profile regarding Li of metal lithium thin films having different thicknesses.

FIG. 8 is a SIMS profile regarding carbon of metal lithium thin films having different thicknesses.

FIG. 9 is a schematic cross-sectional view showing an organic EL element of one example in accordance with the present invention.

FIG. 10 is a view showing an energy diagram around a hole injecting unit of an organic EL element shown in FIG. 9.

FIG. 11 is a view showing an energy diagram around a hole injecting unit of an organic EL element shown in FIG. 9.

FIG. 12 is a schematic cross-sectional view showing an organic EL element of one example in accordance with the present invention.

FIG. 13 is a view showing an energy diagram around an intermediate unit.

FIG. 14 is a schematic cross-sectional view showing an organic EL element of one example in accordance with the present invention.

FIG. 15 is a view showing an energy diagram around an intermediate unit.

FIG. 16 is a view showing an energy diagram around an intermediate unit.

### DESCRIPTION OF THE PREFERRED EMBODIMENTS

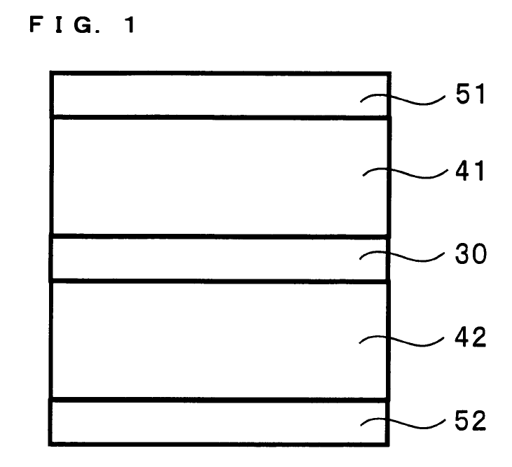

FIG. 1 is a schematic cross-sectional view showing an organic EL element in accordance with the present invention. As shown in FIG. 1, a first light emitting unit 41 and a second light emitting unit 42 are provided between a cathode 51 and an anode 52. An intermediate unit 30 is provided between a first light emitting unit 41 and a second light emitting unit 42. A first light emitting unit 41 is provided on a cathode 51 side relative to an intermediate unit 30, and a second light emitting unit 42 is provided on an anode 52 side relative to an intermediate unit 30. An electron extracting layer is provided in an intermediate unit 30. An adjacent layer is provided on a cathode 51 side of this electron extracting layer. An adjacent layer may be provided in a first light emitting unit 41, or may be provided in an intermediate unit 30 as described above.

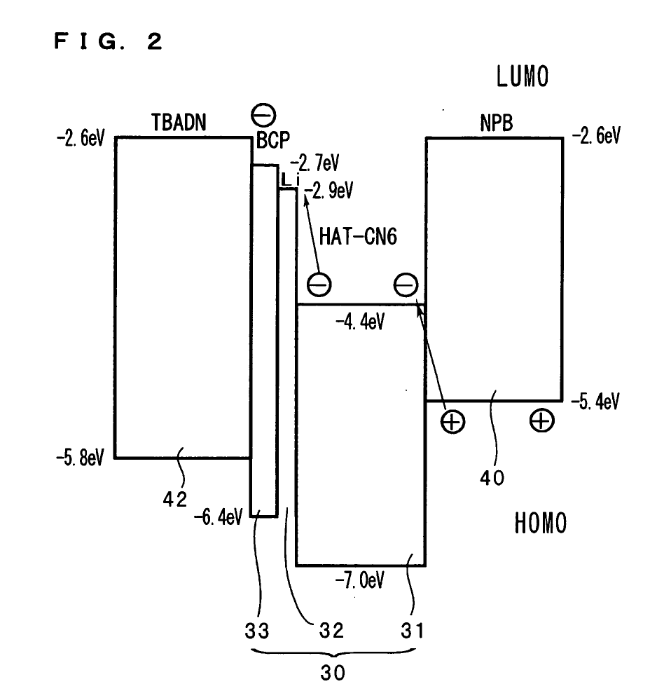

FIG. 2 is a view showing an energy diagram around an intermediate unit. An intermediate unit 30 is constituted of an electron extracting layer 31, an electron injecting layer 30 and an electron transporting layer 33. On a cathode side of an electron extraction layer 31, an adjacent layer 40 is provided. In addition, on an cathode side of an intermediate 30, a second light emitting unit 42 is provided. In FIG. 2, only layers on an intermediate unit 30 side of a second light emitting unit 42 are shown.

As shown in FIG. 2, it is preferable that an electron injecting layer 32 is provided between an electron extracting layer 31 and a light emitting unit 42. Further, it is preferable that an electron transporting layer 33 is provided between an electron injecting layer 32 and a second light emitting unit 42.

In an embodiment shown in FIG. 2, an electron extracting layer 31 is formed of hexaazatriphenylenehexacarbonitrile (hereinafter, referred to as “HAT-CN6”) represented by the following structural formula. HAT-CN6 can be prepared by the method, for example, described in Synthesis, April 1994, p 378-380 “Improved Synthesis of I,4,5,8,0,12 and Hexaazatriphenylenehexacarboxylic Acid”.

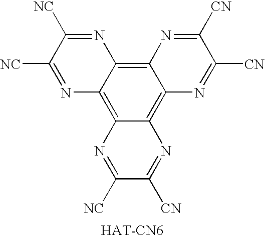

In addition, an electron injecting layer 32 is formed of Li (metal lithium). As an electron injecting layer 32, an alkali metal such as Li and Cs, an alkali metal oxide such as Li₂O, an alkaline earth metal, and an alkaline earth metal oxide can be used.

In addition, an electron transporting layer 33 is formed of o-, m-, or, p-phenanthroline derivatives, for example, such as BCP (2,9-dimethyl-4,7-diphenyl-1,10-phenanthroline) having the following structure. An electron transporting layer 33 can be formed of a material which is generally used as an electron transporting material in an organic EL element, such as chelate-metal complex, for example, tris-(8-quinolinolato)aluminium derivatives, oxadiazole derivatives, silole derivatives and triazole derivatives.

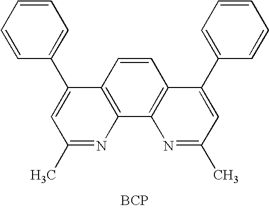

In the present invention, a thickness of an electron extracting layer is preferably in a range of 1 to 150 nm, further preferably in a range of 5 to 100 nm. A thickness of an electron injecting layer 32 is preferably in a range of 0.1 to 10 nm, further preferably in a range of 0.1 to 1 nm. A thickness of an electron transporting layer 33 is preferably in a range of 1 to 100 nm, further preferably in a range of 5 to 50 nm.

In an embodiment shown in FIG. 2, an adjacent layer 40 is formed of NPB (N,N′-di(naphthacen-1-yl)-N,N′-diphenylbenzidine) having the following structure.

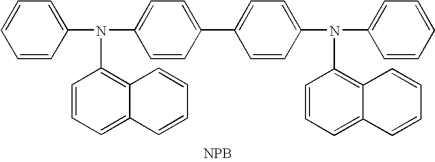

In an embodiment shown in FIG. 2, a layer designated as a second light emitting unit 42 is formed of TBADN (2-tertiary-butyl-9,10-di(2-naphthyl)anthracene) having the following structure.

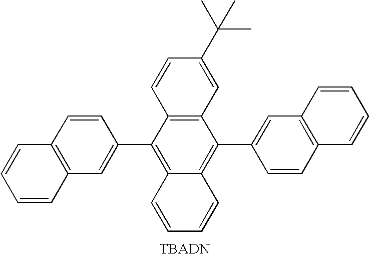

As shown in FIG. 2, a difference between an absolute value (4.4 eV) of a LUMO energy level of an electron extracting layer 31 and an absolute value (5.4 eV) of a HOMO energy level of an adjacent layer 40 is within 1.5 eV. In addition, an absolute value of a LUMO energy level (work function) of an electron injecting layer 32 is smaller than an absolute value of a LUMO energy level of an electron extracting layer 31, and an absolute value of a LUMO energy level of an electron transporting layer 33 is smaller than an absolute value of a LUMO energy level of an electron injecting layer 32.

Therefore, upon application of a voltage to an anode and a cathode, an electron extracting layer 31 can extract an electron from an adjacent layer 40. The extracted electron is supplied to a second light emitting unit 42 through an electron injecting layer 32 and an electron transporting layer 33.

In addition, in an adjacent layer 40, since an electron is extracted, a hole is generated. This hole is supplied to a first light emitting unit, and is recombined with an electron supplied from a cathode. As a result, light is emitted in a first light emitting unit.

An electron supplied to a second light emitting unit is recombined with a hole supplied from a cathode in a second light emitting unit 42. As a result, in a second light emitting unit 42, light is emitted.

As described above, according to the present invention, in a first light emitting unit and a second light emitting unit, a recombination region can be formed, and light can be emitted, respectively. As a result, a light emitting efficiency can be enhanced and, at the same time, a first light emitting unit and a second light emitting unit can emit light at an emitting color of each unit.

Examples in accordance with a first aspect of the present invention will be explained below.

### EXPERIMENT 1

### Examples 1 to 5 and Comparative Examples 1 to 2

Organic EL elements of Examples 1 to 5 and Comparative Examples 1 to 2 having an anode, a hole injecting layer, a second light emitting unit, an intermediate unit, a first light emitting unit, an electron transporting layer, and a cathode shown in Table 1 were manufactured. In the following Table, a numerical in ( ) indicates a thickness (nm) of each layer.

An anode was manufactured by forming a fluorocarbon (CFₓ) layer on a glass substrate on which an ITO (indium tin oxide) film had been formed. A fluorocarbon layer was formed by plasma polymerization of a CHF₃ gas. A thickness of a fluorocarbon layer was 1 nm.

On the thus manufactured anode, a hole injecting layer, a second light emitting unit, an intermediate unit, a first light emitting unit, an electron transporting layer, and a cathode were formed by successively depositing them by a deposition method.

A hole injecting layer was formed from HAT-CN6.

A first light emitting unit and a second light emitting unit are formed by laminating an orange emitting layer (NPB+3.0% DBzR) and a blue emitting layer (TBADN+2.5% TBP). In any light emitting unit, an orange emitting layer is situated on an anode side, and a blue emitting layer is situated on a cathode side. And, % is % by weight unless otherwise is indicated.

In an orange emitting layer, NPB is used as a host material, and DBzR is used as a dopant material. DBzR is 5,12-bis{4-(6-methylbenzothiazol-2-yl)phenyl}-6,11-diphenyl naphthacene, and has the following structure.

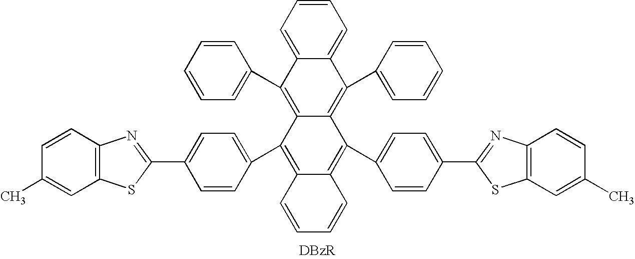

In a blue emitting layer, TBADN is used as a host material, and TBP is used as a dopant material.

TBP is 2,5,8,11-tetratertiary-butylperylene, and has the following structure.

TABLE 1

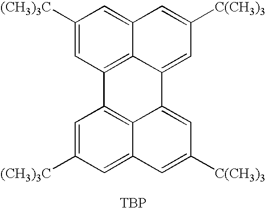

| | | | | | | |
|---|---|---|---|---|---|---|
| | | | | | Electron | |
| | Hole | | | | Trans- | |
| | Injecting | Second Light | | First Light | porting | |
| Anode | Layer | Emitting Unit | Intermediate Unit | Emitting Unit | Layer | Cathode |

| | | | | | | | |
|---|---|---|---|---|---|---|---|
| EX. 1 | ITO/ | HAT-CN6 | NPB + 3.0% DBzR (30)/ | BCP/Li₂O/HAT-CN6 | NPB + 3.0% DBzR (30)/ | BCP | Li₂O/Al |
| | CFx | (100) | TBADN + 2.5% TBP (40) | (15)/(0.1)/(100) | TBADN + 2.5% TBP (40) | (15) | (0.1)/200 |
| EX. 2 | ITO/ | HAT-CN6 | NPB + 3.0% DBzR (30)/ | BCP/HAT-CN6 | NPB + 3.0% DBzR (30)/ | BCP | Li₂O/Al |
| | CFx | (100) | TBADN + 2.5% TBP (40) | (15)/(100) | TBADN + 2.5% TBP (40) | (15) | (0.1)/200 |
| EX. 3 | ITO/ | HAT-CN6 | NPB + 3.0% DBzR (30)/ | BCP/Li₂O/HAT-CN6/NPB | NPB + 3.0% DBzR (10)/ | BCP | Li₂O/Al |
| | CFx | (100) | TBADN + 2.5% TBP (40) | (15)/(0.1)/(100)/(20) | TBADN + 2.5% TBP (40) | (15) | (0.1)/200 |
| EX. 4 | ITO/ | HAT-CN6 | NPB + 3.0% DBzR (30)/ | BCP/Li/HAT-CN6 | NPB + 3.0% DBzR (30)/ | BCP | Li₂O/Al |
| | CFx | (100) | TBADN + 2.5% TBP (40) | (15)/(0.3)/(100) | TBADN + 2.5% TBP (40) | (15) | (0.1)/200 |
| EX. 5 | ITO/ | HAT-CN6 | NPB + 3.0% DBzR (30)/ | BCP/Cs/HAT-CN6 | NPB + 3.0% DBzR (30)/ | BCP | Li₂O/Al |
| | CFx | (100) | TBADN + 2.5% TBP (40) | (15)/(0.3)/(100) | TBADN + 2.5% TBP (40) | (15) | (0.1)/200 |
| Comp | ITO/ | HAT-CN6 | NPB + 3.0% DBzR (30)/ | None | None | BCP | Li₂O/Al |
| Ex. 1 | CFx | (50) | TBADN + 2.5% TBP (40) | | | (15) | (0.2)/200 |
| Comp | ITO/ | HAT-CN6 | NPB + 3.0% DBzR (30)/ | BCP/Li₂O | NPB + 3.0% DBzR (30)/ | BCP | Li₂O/Al |
| Ex. 2 | CFx | (100) | TBADN + 2.5% TBP (40) | (15)/(0.1) | TBADN + 2.5% TBP (40) | (15) | (0.1)/200 |

Each organic EL element manufactured was measured for a chromaticity (CIE (x, y)) and a light emitting efficiency, and measurement results together with a driving voltage are shown in Table 2. A light emitting efficiency is a value at 10 mA/cm².

TABLE 2

| | Driving | | | Light Emitting |
|---|---|---|---|---|
| | Voltage | | | Efficiency |
| | (V) | CIEₓ | CIE_{y} | (cd/A) |
| Ex. 1 | 10.3 | 0.37 | 0.41 | 22.8 |
| Ex. 2 | 22.1 | 0.32 | 0.36 | 10.2 |
| Ex. 3 | 16.8 | 0.33 | 0.38 | 15.3 |
| Ex. 4 | 10.0 | 0.36 | 0.40 | 23.1 |
| Ex. 5 | 10.1 | 0.36 | 0.40 | 22.9 |
| Comp. | 6.0 | 0.30 | 0.40 | 10.1 |
| Ex. 1 | | | | |
| Comp. | 26.0 | 0.15 | 0.21 | 3.1 |
| Ex. 2 | | | | |

As apparent from results shown in Table 2, each organic EL element is provided with a light emitting unit having an orange emitting layer and a blue emitting layer, and it is seen that white is emitted from results of chromaticity measurement.

As apparent from comparison of Examples 1 to 5 and Comparative Example 2, in Examples 1 to 5 provided with “HAT-CN6” which is an electron extracting layer, a higher light emitting efficiency is obtained as compared with Comparative Example 2 not provided with an electron extracting layer. In addition, it is seen that organic EL elements of Examples 1 to 5 exhibit an emitting color originally possessed by a light emitting unit as compared with Comparative Example 2.

The reason why organic EL elements of Examples 1 to 5 exhibit a high light emitting efficiency is thought as follows: that is, in organic EL elements of Examples 1 to 5, since a second light emitting unit is situated on an anode side, the state where the number of holes is relatively larger is realized. Therefore, when an intermediate unit is not present, the electron-deficient state is realized. On the other hand, since a first light emitting unit is situated on a cathode side, the state where the number of electrons is relatively large is realized and, when an intermediate unit is not present, the hole-deficient state is realized.

As described above, when an intermediate unit is not present, since the state where four light emitting layers are continuously directly contacted is realized, carriers are recombined in one region in four light emitting layers. In accordance with the present invention, by providing an intermediate unit at a center of four light emitting layers, deficiency of an electron in a second light emitting unit on an anode side can be supplemented, and deficiency of a hole in a first light emitting unit on a cathode side can be supplemented. The mechanism is, as explained referring to FIG. 2, as follows: when a voltage is applied to an anode and a cathode, extraction of an electron from an adjacent layer to an electron extracting layer in a first light emitting unit occurs, and the extracted electron enters LUMO of an electron extracting layer. In addition, as a result of extraction of an electron, a hole is generated in HOMO of an adjacent layer. An electron of LUMO of an electron extracting layer enters LUMO of an electron transporting layer via an electron injecting layer in an intermediated unit and, thereafter, enters a second light emitting, and is recombined with a hole injected from an anode. Thereupon, it is thought that, in addition to an electron from an intermediate unit, an electron which is an electron injected from a cathode and has not been consumed in a first light emitting unit contributes recombination at the same time. Thereby, an orange emitting layer and a blue emitting layer in a second light emitting unit emit light at the same time, generating a complementary-type white emission.

On the other hand, a hole generated in HOMO of an adjacent layer of a first light emitting unit, and a hole from an anode which has not been consumed in a second light emitting unit are moved to a first light emitting unit in the high electric field, and are recombined with an electron injected from a cathode, in a first light emitting unit. Thereby, an orange emitting layer and a blue emitting layer in a first light emitting unit emit light at the same time, generating complementary-type white emission.

As described above, since white emission occurs at two places of a first light emitting unit and a second light emitting unit, a light emitting deficiency is improved 2-fold. In the case of the previous organic EL element in which a plurality of light emitting units are combined by intervening inorganic semiconductor layer such as V₂O₅, carriers originally present in an inorganic semiconductor layer are utilized. To the contrary, in the present invention, by separating a carrier from a neutral organic layer in which a carrier is not present, that is, an adjacent layer, this carrier is used to emit light. Therefore, an organic EL element of the present invention can be made to have a low driving voltage as compared with the previous element. That is, an energy for extracting an electron (a difference in LUMO of an electron extracting layer and HOMO of an adjacent layer), and an energy difference for injecting a generated electron into a light emitting layer on an anode side, light can be emitted.

In addition, in the present invention, since a light emitting efficiency can be made to be 2-fold, reliance of an element can be also enhanced. For example, when continuous light emitting is performed at a luminance of an initial luminance 5000 cd/m², in the normal organic EL element, light must be emitted as it is at a luminance of 5000 cd/m². To the contrary, in an organic EL element of the present invention, since a light emitting efficiency becomes 2-fold, one light emitting unit in an element may emit light at a luminance of 2500 cd/m² which is a half of 5000 cd/m². Therefore, an amount of a current flowing in an element may be a half, and a load exerting on an element is reduced. Since a life of an element in continuous light emitting is influenced by a value of a flowing current, a life of an element can be improved by the present invention.

As described above, it is seen that, in accordance with the present invention, by providing an electron extracting layer in an intermediate unit, an organic EL element which can be driven at a low voltage, has a high light emitting efficiency, and exhibits a desired emitting color can be obtained.

### EXPERIMENT 2

### Example 6 and Comparative Example 3

An organic EL element of Example 6 provided with an anode, a hole injecting layer, a second light emitting unit, an intermediate unit, a first light emitting unit, an electron transporting layer, and a cathode shown in Table 3 was manufactured as in the aforementioned Experiment 1. In addition, an organic EL element of Comparative Example 3 of a structure shown in Table 3, which is the same as the organic EL element of Example 4 except that an intermediate unit and a first light emitting unit were not possessed, was manufactured.

In the present Example, an adjacent layer comprising NPB is formed between a “HAT-CN6” layer of an intermediate unit, and a first light emitting unit. In addition, in the present Example, a first light emitting unit and a second light emitting unit are constructed of a blue single light emitting layer. Like this, when an arylamine-based hole transporting material such as NPB is not used as a host material in a layer of an anode side of a first light emitting unit, it is preferable to provide an adjacent layer in an intermediate unit.

TABLE 3

| | | Hole | | | | Electron | |
|---|---|---|---|---|---|---|---|
| | | Injecting | Second Light | | First Light | Transporting | |
| | Anode | Layer | Emitting Unit | Intermediate Unit | Emitting Unit | Layer | Cathode |
| Ex. 6 | ITO/ | HAT-CN6/NPB | TBADN + 2.5% TBP | BCP/Li₂O/HAT-CN6/NPB | TBADN + | BCP | Li₂O/Al |
| | CFx | (50)/(30) | (40) | (15)/(0.1)/(50)/(30) | 2.5% TBP | (15) | (0.1)/(200) |
| | | | | | (40) | | |
| Comp. | ITO/ | HAT-CN6/NPB | TBADN + 2.5% TBP | None | None | BCP | Li₂O/Al |
| Ex. 3 | CFx | (50)/(30) | (40) | | | (15) | (0.1)/(200) |

Organic EL elements of Example 6 and Comparative Example 3 were measured for a chromaticity and a light emitting efficiency as in the Experiment 1, and measurement results together with a driving voltage are shown in Table 4.

TABLE 4

| | Driving | | | Light Emitting |
|---|---|---|---|---|
| | Voltage | | | Efficiency |
| | (V) | CIEₓ | CIE_{y} | (cd/A) |
| Ex. 6 | 9.9 | 0.17 | 0.40 | 31.6 |
| Comp. | 3.1 | 0.18 | 0.39 | 19.6 |
| Ex. 3 | | | | |

As apparent from results shown in Table 4, it is seen that an organic EL element of Example 6 in accordance with the present invention exhibits the same chromaticity as that of Comparative Example 3 provided with a single light emitting unit, and the same emitting color as that of the case where each light emitting unit is used alone is obtained. In addition, a light emitting efficiency of Example 6 is about 1.6-fold a light emitting efficiency of Comparative Example 3, and it is seen that a high light emitting efficiency is obtained.

### EXPERIMENT 3

An organic EL element of Example 7 having an anode, a hole injecting layer, a second light emitting unit, an intermediate unit, a first light emitting unit, an electron transporting layer, and a cathode shown in Table 5 was manufactured as in the Experiment 1.

In the present Example, as a first light emitting unit and a second light emitting unit, the same blue single light emitting layer as that of Example 1 is used. In addition, in the present Example, an adjacent layer comprising TPD is provided in an intermediate unit. A hole transporting layer comprising NPB is provided between this adjacent layer comprising TPD, and a first light emitting unit.

In addition, in the present Example, TPD is used also in a hole injecting layer provided between an anode and a second light emitting unit. As shown in Table 5, a layer comprising TPD is provided between a “HAT-CN6” layer and a NPB layer.

TPD is N,N′-bis-(3-methylphenyl) -N,N′-bis-(phenyl)-benzidine, and has the following structure.

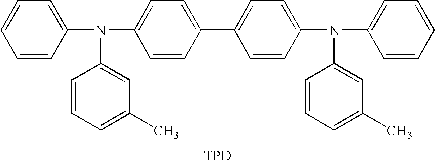

A HOMO energy level of TPD is −5.3 eV, a LUMO energy level is −2.5 eV, and these are approximately the same extents as a NPB (HOMO energy level=−5.4 eV, LUMO energy level=−2.6 eV).

TABLE 5

| | | | | | | Electron | |
|---|---|---|---|---|---|---|---|
| | | Hole Injecting | Second Light | | First Light | Transporting | |
| | Anode | Layer | Emitting Unit | Intermediate Unit | Emitting Unit | Layer | Cathode |
| Ex. 7 | ITO/ | HAT-CN6/TPD/NPB | TBADN + 2.5% TBP | BCP/Li₂O/HAT-CN6/ | TBADN + 2.5% TBP | BCP | Li₂O/Al |
| | CFx | (50)/(10)/(20) | (40) | TPD/NPB | (40) | (15) | (0.1)/(200) |
| | | | | (15)/(0.1)/(50)/ | | | |
| | | | | (10)/(20) | | | |

An organic EL element of Example 7 was measured for a chromaticity and a light emitting efficiency as in the Experiment 1, and measurement results together with a driving voltage are shown in Table 6.

TABLE 6

| | Driving | | | Light Emitting |
|---|---|---|---|---|
| | Voltage | | | Efficiency |
| | (V) | CIEₓ | CIE_{y} | (cd/A) |
| Ex. 7 | 8.9 | 0.16 | 0.39 | 32.0 |

As shown in Table 6, also when an adjacent layer comprising TPD is formed, a high light emitting efficiency can be obtained as in the case of an adjacent layer comprising NPB. This is thought that since its HOMO energy level and LUMO energy level are the same extent as that of NPB as described above, extraction of an electron from an adjacent layer is easily generated, and a hole generated in an adjacent layer is easily moved to a first light emitting unit.

### EXPERIMENT 4

Organic EL elements of Examples 8 to 11 provided with an anode, a hole injecting layer, a second light emitting unit, an intermediate unit, a first light emitting unit, an electron transporting layer, and a cathode shown in Table 7 were manufactured.

In Example 8, as in Example 7, an adjacent layer comprising TPD is formed, and a layer comprising TPD is provided also in a hole injecting layer.

In Example 9, an adjacent layer comprising CuPc is formed, and a CuPc layer is provided also in a hole injecting layer. CuPc is copper phthalocyanine, and has the following structure.

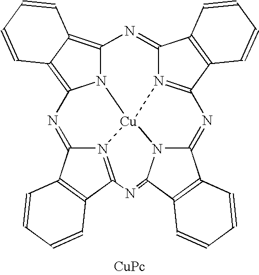

In Example 10, an adjacent layer comprising CBP is formed, and a CBP layer is provided also in a hole injecting layer. CBP is 4,4′-N,N′-dicarbazole-biphenyl, and has the following structure.

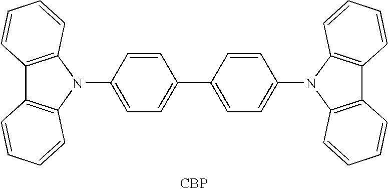

In Example 11, NPB is used as an adjacent layer.

In organic EL elements of Examples 8 to 11, as a first light emitting unit and a second light emitting unit, a blue single light emitting layer is used as in Example 7.

TABLE 7

| | | | | | | Electron | |
|---|---|---|---|---|---|---|---|
| | | Hole Injecting | Second | | First Light | Transporting | |
| | Anode | Layer | Light Emitting Unit | Intermediate Unit | Emitting Unit | Layer | Cathode |
| Ex. 8 | ITO/CFx | HAT-CN6/TPD/NPB | TBADN + 2.5% TBP | BCP/Li₂O/HAT-CN6/ | TBADN + 2.5% TBP | BCP | Li₂O/Al |
| | | (50)/(10)/(20) | (40) | TPD/NPB | (40) | (15) | (0.1)/(200) |
| | | | | (15)/(0.1)/(50)/ | | | |
| | | | | (10)/(20) | | | |
| Ex. 9 | ITO/ | HAT-CN6/CuPc/NPB | TBADN + 2.5% TBP | BCP/Li₂O/HAT-CN6/ | TBADN + 2.5% TBP | BCP | Li₂O/Al |
| | CFx | (50)/(10)/(20) | (40) | CuPc/NPB | (40) | (15) | (0.1)/(200) |
| | | | | (15)/(0.1)/(50)/ | | | |
| | | | | (10)/(20) | | | |
| Ex. 10 | ITO/ | HAT-CN6/CBP/NPB | TBADN + 2.5% TBP | BCP/Li₂O/HAT-CN6/ | TBADN + 2.5% TBP | BCP | Li₂O/Al |
| | CFx | (50)/(10)/(20) | (40) | CBP/NPB | (40) | (15) | (0.1)/(200) |
| | | | | (15)/(0.1)/(50)/ | | | |
| | | | | (10)/(20) | | | |
| Ex. 11 | ITO/ | HAT-CN6/NPB | TBADN + 2.5% TBP | BCP/Li₂O/HAT-CN6/NPB | TBADN + 2.5% TBP | BCP | Li₂O/Al |
| | CFx | (50)/(30) | (40) | (15)/(0.1)/(50)/(30) | (40) | (15) | (0.1)/(200) |

Respective organic EL elements of Examples 8 to 11 were measured for a chromaticity and a light emitting efficiency as in the Experiment 1, and measurement results together with a driving voltage are shown in Table 8.

TABLE 8

| | | Driving | | | Light Emitting |
|---|---|---|---|---|---|
| | Adjacent | Voltage | | | Efficiency |
| | Layer | (V) | CIEₓ | CIE_{y} | (cd/A) |
| Ex. 8 | TPD | 8.9 | 0.16 | 0.39 | 32.0 |
| Ex. 9 | CuPc | 6.6 | 0.13 | 0.36 | 25.1 |
| Ex. 10 | CBP | 39.0 | 0.16 | 0.34 | 20.1 |
| Ex. 11 | NPB | 9.9 | 0.17 | 0.40 | 31.6 |

As shown in Table 8, in any of organic EL elements of Examples 8 to 11, a high light emitting efficiency is obtained, and the substantially same emitting color as that of a blue light emitting layer used in a light emitting unit is obtained. [Measurement of HOMO and LUMO energy levels of material for adjacent layer and material for electron extracting layer]

Regarding a material used in an adjacent layer and a material used in an electron extracting layer, values of respective energy levels of HOMO and LUMO were calculated by cyclic voltammetry (CV) as follows:

1, CV measurement

(1) Measurement of oxidation side

A supporting electrolyte tert-butylammonium perchlorate was placed at a concentration of 10⁻¹ mol/l using dichloromethane as a solvent, a measuring material was placed at 10⁻³ mol/l, and a sample was prepared. Measurement atmosphere is in the air, and measurement was performed at room temperature.

(2) Measurement of reduction side

A sample was prepared by placing a supporting electrolyte tert-butyl ammonium perchlorate at a concentration of 10⁻¹ mol/l, and placing a measuring material at 10⁻³ mol/l using tetrahydrofuran as a solvent. Measuring atmosphere was under the nitrogen gas atmosphere, and measurement was performed at room temperature.

2, Calculation of HOMO and LUMO

(1) An ionization potential in a thin film of NPB of a standard sample is measured in advance using an ionization potential measuring apparatus (“AC-2” manufactured by Rikenkeiki). Measurement principle of AC-2 is as follows: a sample is irradiated with ultraviolet-ray which has been emitted from a light source part and separated into spectral components, and a ultraviolet-ray energy (wavelength) is increased (shortened). In the case of a semiconductor as a sample, when a ultraviolet-ray energy exceeds an ionization potential, a photoelectron begins to be released from a surface of a sample. This photoelectron is counted using a detector (open counter).

A relationship between a ultraviolet-ray energy and a root of a calculated value (Yield) of a photoelectron is graphed, and an approximate straight line is drawn on this graph by a minimum square method to obtain a threshold energy of photoelectron release. When this threshold energy is interpreted as ionization potential when a sample is a semiconductor. When a sample is a metal, it is a work function. An ionization potential of NPB measured with AC-2 is −5.4 eV.

(2) Then, NPB is CV-measured, and an oxidation-reduction-potential is measured. An oxidation potential of NPB is −0.5V, and a reduction potential is −2.3 V. Therefore, HOMO of NPB is −5.4 eV, and LUMO is −2.6 eV (5.4−(0.5+2.3)=2.6). In addition, in measurement of other materials, for example, in the case of Alq, an oxidation potential is +0.8V, and a reduction potential is −2.0V. Therefore, when NPB is a standard, HOMO of Alq is −5.7 eV (5.4−(0.8−0.5)=5.7), and LUMO is −2.9 eV (5.7−(0.8+2.0)=2.9).

By the aforementioned measuring method, HOMO and LUMO energy levels of TPD, CuPu, CBP, NPB, and HAT-CN6 were calculated, and results thereof are shown in Table 9. A light emitting efficiency when each material is used in a material for an adjacent layer (light emitting efficiency in Examples 6 to 9) is also shown in Table 9.

TABLE 9

| | | | | Light |
|---|---|---|---|---|
| | | | Value of | Emitting |
| | HOMO | LUMO | \|HOMO(B)\| − \|LUMO(A)\| | Efficiency |
| | (eV) | (eV) | (eV) | (cd/A) |
| TPD | 5.3 | 2.5 | 0.9 | 32.0 |
| CuPc | 5.1 | 3.3 | 0.7 | 25.1 |
| CBP | 5.9 | 2.6 | 1.5 | 20.1 |
| NPB | 5.4 | 2.6 | 1.0 | 31.6 |
| HAT-CN6 | 7.0 | 4.4 | — | — |

As apparent from results shown in Table 9, it is seen that in a range of a difference between an absolute value of an energy level of HOMO of a material for an adjacent layer, and an absolute value of an energy level of LUMO of a material for an electron extracting layer, of 0 to 1.5 eV, an organic EL element having a high light emitting efficiency is obtained.

### EXPERIMENT 5

Organic EL elements having an anode, a hole injecting layer, a second light emitting unit, an intermediate unit, a first light emitting unit, an electron transporting layer, and a cathode shown in Table 10, in which a thickness x of a Li₂O layer in an intermediate unit is changed into 0.1 nm, 0.2 nm, 0.3 nm, 0.5 nm, 1 nm and 3 nm were manufactured.

TABLE 10

| | | Second Light | | | | | | |
|---|---|---|---|---|---|---|---|---|
| | | Emitting Unit | | | First Light Emitting Uunit | | | |
| | Hole | Orange | Blue | | Orange | Blue | Electron | |
| | Injecting | Emitting | Emitting | | Emitting | Emitting | Transporting | |
| Anode | Layer | Layer | Layer | Intermediate Unit | Layer | Layer | Layer | Cathode |
| ITO/ | HAT-CN6 | NPB + 3.0% | 80% TBADN + | BCP(15)/Li₂O(x)/ | NPB + | 80% TBADN + 20% | BCP | Li₂O(0.1)/ |
| CFx | (80) | DBzR | 20% NPB + | HAT-CN6(80) | 3.0% DBzR | NPB + 2.5% | (15) | Al(200) |
| | | (20) | 2.5% TBP | | (20) | TBP | | |
| | | | (50) | | | (50) | | |

An orange light emitting layer in a first light emitting unit and a second light emitting unit is the same as the orange light emitting layer in the Experiment 1. In addition, in a blue light emitting layer, 80% by weight of TBADN is used as a host material, 2.5% by weight of TBP is used as a first dopant material, and 20% by weight of NPB is used as a second dopant material.

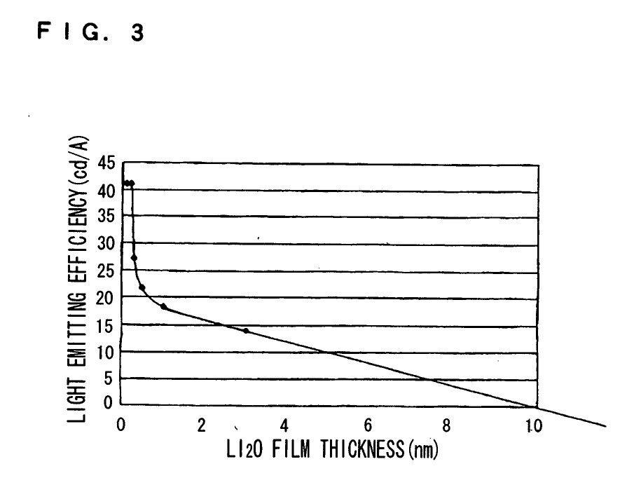

Regarding respective organic EN elements in which a film thickness of a Li₂O layer is changed, a light emitting efficiency at 10 mA/m² is measured, and results thereof are shown in FIG. 3.

As apparent from results shown in FIG. 3, it is seen that light emission is possible in a range of a film thickness of Li₂O in a range of 0.1 nm to 10 nm. In addition, it is seen that a light emitting efficiency is particularly high in a range of a film thickness of Li₂O of 0.1 nm to 3 nm.

### EXPERIMENT 6

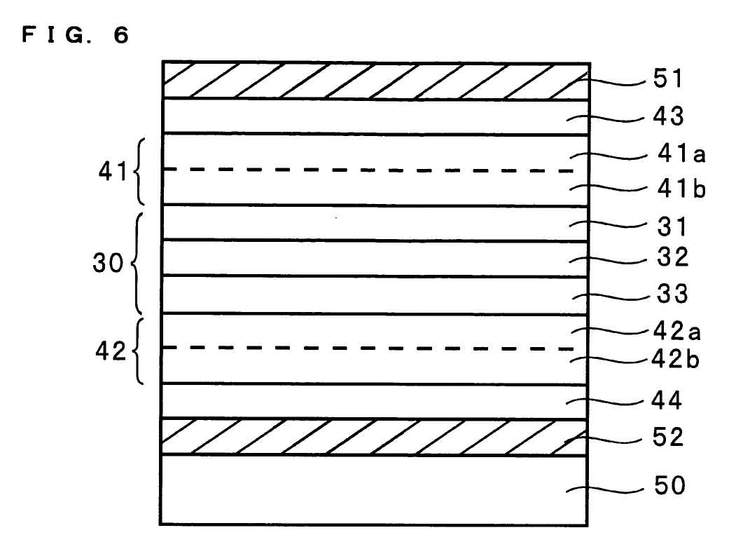

An organic EL element shown in FIG. 6 was manufactured. In an organic EL element shown in FIG. 6, an anode 52 is formed on a glass substrate 50 and, on an anode 52, a hole injecting layer 44 comprising HAT-CN6 is formed. On a hole injecting layer 44, a second light emitting unit 44 consisting of a blue light emitting layer 42a and an orange light emitting layer 42b is formed. On a second light emitting unit 42, an intermediate unit 30 is formed. An intermediate unit 30 is constructed of an electron extracting layer 31, an electron injecting layer 32, and an electron transporting layer 33. On an intermediate unit 30, a first light emitting unit 41 consisting of a blue emitting layer 41a and an orange emitting layer 41b is formed. On a first light emitting unit 41, an electron transporting layer 43 comprising BCP is formed. On an electron transporting layer 43, a cathode 41 is formed. As shown in Table 11, organic EL elements of Examples 12 to 19 in which a thickness of an electron injecting layer 32 comprising a metal lithium was changed in a range of 0.2 nm to 1.0 nm were manufactured.

TABLE 11

| | | | Second Light Emitting Unit | | | | | Electron | |
|---|---|---|---|---|---|---|---|---|---|
| | | Hole | Orange | | | First Light Emitting Uunit | | Trans- | |
| | An- | Injecting | Emitting | Blue | Intermediate | Orange | Blue | porting | |
| Ex. | ode | Layer | Layer | Emitting Layer | Unit | Emitting Layer | Emitting Layer | Layer | Cathode |
| 12 | ITO/ | HAT-CN6 | NPB + | TBADN + 2.5% TBP | BCP/Li/HAT-CN6 | NPB + 3.0% DBzR | TBADN + 2.5% TBP | BCP | LiF/Al |
| | CFₓ | (10) | 3.0% DBzR | (50) | (10)/(0.2)/(10) | (60) | (50) | (10) | (1)/(200) |
| | | | (60) | | | | | | |
| 13 | ITO/ | HAT-CN6 | NPB + | TBADN + 2.5% TBP | BCP/Li/HAT-CN6 | NPB + 3.0% DBzR | TBADN + 2.5% TBP | BCP | LiF/Al |
| | CFₓ | (10) | 3.0% DBzR | (50) | (10)/(0.3)/(10) | (60) | (50) | (10) | (1)/(200) |
| | | | (60) | | | | | | |
| 14 | ITO/ | HAT-CN6 | NPB + | TBADN + 2.5% TBP | BCP/Li/HAT-CN6 | NPB + 3.0% DBzR | TBADN + 2.5% TBP | BCP | LiF/Al |
| | CFₓ | (10) | 3.0% DBzR | (50) | (15)/(0.5)/(10) | (60) | (50) | (10) | (1)/(200) |
| | | | (60) | | | | | | |
| 15 | ITO/ | HAT-CN6 | NPB + | TBADN + 2.5% TBP | BCP/Li/HAT-CN6 | NPB + 3.0% DBzR | TBADN + 2.5% TBP | BCP | LiF/Al |
| | CFₓ | (10) | 3.0% DBzR | (50) | (10)/(0.6)/(10) | (60) | (50) | (10) | (1)/(200) |
| | | | (60) | | | | | | |
| 16 | ITO/ | HAT-CN6 | NPB + | TBADN + 2.5% TBP | BCP/Li/HAT-CN6 | NPB + 3.0% DBzR | TBADN + 2.5% TBP | BCP | LiF/Al |
| | CFₓ | (10) | 3.0% DBzR | (50) | (10)/(0.6)(10) | (60) | (50) | (10) | (1)/(200) |
| | | | (60) | | | | | | |
| 17 | ITO/ | HAT-CN6 | NPB + | TBADN + 2.5% TBP | BCP/Li/HAT-CN6 | NPB + 3.0% DBzR | TBADN + 2.5% TBP | BCP | LiF/Al |
| | CFₓ | (10) | 3.0% DBzR | (50) | (20)/(0.8)/(10) | (60) | (50) | (10) | (1)/(200) |
| | | | (60) | | | | | | |
| 18 | ITO/ | HAT-CN6 | NPB + | TBADN + 2.5% TBP | BCP/Li/HAT-CN6 | NPB + 3.0% DBzR | TBADN + 2.5% TBP | BCP | LiF/Al |
| | CFₓ | (10) | 3.0% DBzR | (50) | (10)/(0.9)/(10) | (60) | (50) | (10) | (1)/(200) |
| | | | (60) | | | | | | |
| 19 | ITO/ | HAT-CN6 | NPB + | TBADN + 2.5% TBP | BCP/Li/HAT-CN6 | NPB + 3.0% DBzR | TBADN + 2.5% TBP | BCP | LiF/Al |
| | CFₓ | (10) | 3.0% DBzR | (50) | (10)/(1.0)/(10) | (60) | (50) | (10) | (1)/(200) |
| | | | (60) | | | | | | |

Respective organic EL elements of Examples 12 to 19 were assessed for their property. Assessment results are shown in Table 12. A voltage and a chromaticity are values when elements were driven at a current of 10 mA/cm². A luminance half life is a value when elements were driven at a current of 40 mA/cm².

TABLE 12

| | Thickness | | | | Luminance |
|---|---|---|---|---|---|
| | of Li Layer | Voltage | | | Half time |
| Ex. | (nm) | (V) | CIEₓ | CIE_{y} | (hr) at 40 mA/cm² |
| 12 | 0.2 | 9.58 | 0.33 | 0.37 | 46 |
| 13 | 0.3 | 9.33 | 0.32 | 0.37 | 670 |
| 14 | 0.5 | 9.33 | 0.32 | 0.4 | 500 |
| 15 | 0.6 | 9.14 | 0.31 | 0.36 | 1000 |
| 16 | 0.6 | 8.98 | 0.29 | 0.37 | 1100 |
| 17 | 0.8 | 8.33 | 0.29 | 0.38 | 1000 |
| 18 | 0.9 | 8.64 | 0.29 | 0.35 | 730 |
| 19 | 1.0 | 9.44 | 0.32 | 0.37 | 300 |

As apparent from results shown in Table 12, it is seen that a luminance half life is 500 hours or longer in a range of a thickness of an electron injecting layer comprising Li of 0.3 to 0.9 nm, and excellent life property is obtained. In particular, in a range of 0.6 to 0.9 nm, a driving voltage is lowered, and a value of a luminance half life of 1000 hours or longer is obtained.

In Example 12 in which a thickness of an electron injecting layer is 0.2 nm, a life is extremely shortened, and a driving voltage is increased. In addition, in Example 19 in which a thickness of an electron injective layer is 1.0 nm, a life is short, and a driving voltage is increased.

From the foregoing, it is seen that when an electron injecting layer comprising Li is provided, by adopting a thickness of an electron injecting layer in a range of 0.3 to 0.9 nm, an organic EL element which is low in a driving voltage, and is excellent in life property can be obtained.

It is thought that, by providing an electron injecting layer comprising Li, a complex of Li-BCP is formed at an interface of an electron transporting layer comprising BCP. It is thought that, by formation of such the complex, a LUMO value of BCP is lowered, and injection of an electron from Li into BCP becomes smooth.

[Measurement of Thickness of Metal Lithium Thin Film]

In Experiment 6, a thickness of a metal lithium thin film which is an electron injecting layer was measured as follows:

That is, a standard sample was prepared, a thickness of a metal lithium thin film of a standard sample was measured and, thereafter, a calibration curve was produced by SIMS regarding a standard sample and, using this calibration curve, SIMS of an organic EL element was measured, and a thickness of a metal lithium thin film was calculated. Details of this measuring method will be explained below.

(1) Measurement of thickness of metal lithium thin film of standard sample

Upon manufacturing of organic EL elements of Examples 12, 13, 15 and 19, a thickness of a metal lithium thin film was measured by ICP (induction-coupled plasma method). That is, immediately before manufacturing of each element, only metal lithium thin films were formed on a glass substrate of a size of 100 mm×100 mm under the same condition, and a lithium metal was extracted from these thin films using 50 ml of a solution of hydrochloric acid and water of a volume ratio of 1:9. A weight of a metal lithium film was measured from the extracted solution by an ICP method. A volume (mm³) of a metal lithium thin film was obtained from a solid density 0.534 mg/mm³ of lithium.

Then, by dividing this volume by a film area 10,000 mm² (100 mm×100 mm), an actual thickness (mm) is calculated.

As described above, a thickness of a metal lithium thin film was calculated. A thickness of an electron injecting layer (metal lithium thin film) in an actually manufactured organic EL element (Examples 12, 13, 15 and 19) can be thought to be the same as a thickness of the metal lithium thin film manufactured as described above.

A thickness of a metal lithium thin film obtained by an ICP method as described above is shown in Table 13.

TABLE 13

| | | | | Li | Li |
|---|---|---|---|---|---|
| | Predicted Film | Li | Li | Actual | Actual |
| | Thickness | Concentration | Weight | Volume | Thickness |
| Ex. | (nm) | (mg/l) | (mg) | (mm³) | (nm) |
| 12 | 0.2 | 0.022 | 0.0011 | 0.0021 | 0.21 |
| 13 | 0.3 | 0.031 | 0.0016 | 0.0029 | 0.29 |
| 15 | 0.6 | 0.063 | 0.0032 | 0.0059 | 0.59 |
| 19 | 1.0 | 0.11 | 0.0054 | 0.0101 | 1.01 |

(2) Preparation of calibration curve by SIMS regarding standard sample

Regarding respective samples of Examples 12, 13, 15 and 19, a concentration distribution in a depth direction of lithium was measured by SIMS.

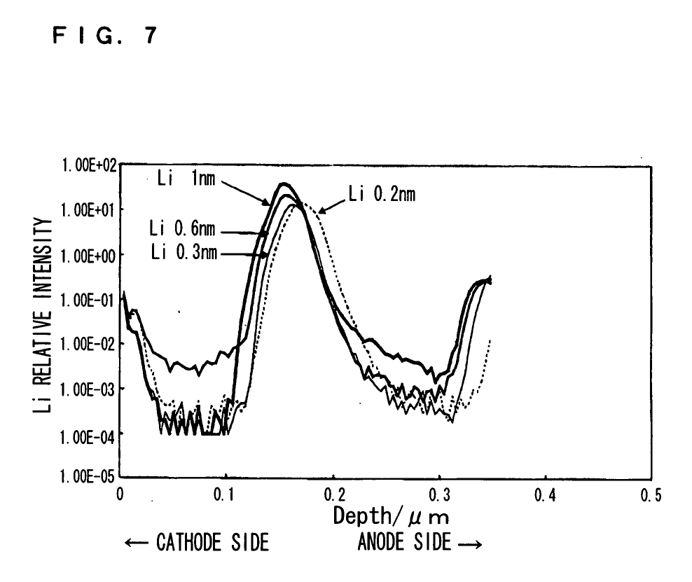

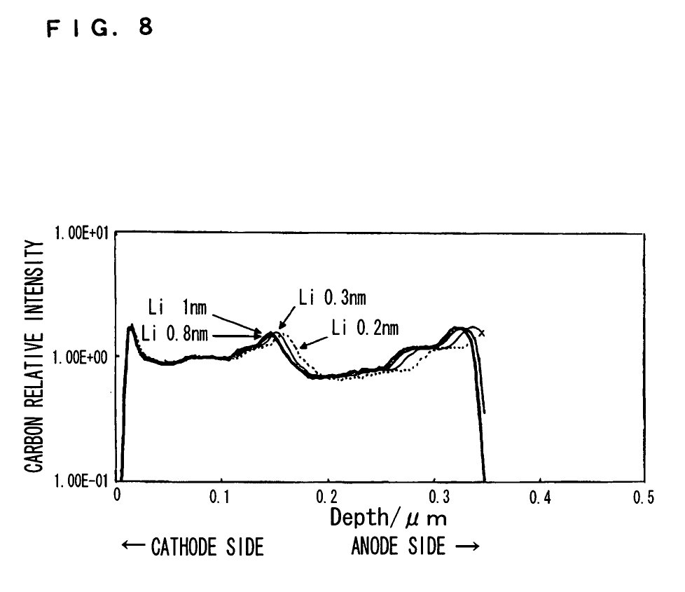

FIG. 7 indicates a SIMS profile regarding Li, and FIG. 8 indicates a SIMS profile regarding carbon. From FIG. 7 and FIG. 8, an intensity ratio of Li and C (Li/C counting ratio) was calculated, and this is shown in Table 14. A counting ratio is an intensity (peak height) of Li letting an average intensity of carbon in a carbon profile to be 1. For example, when an average intensity of carbon is 1×10, and a peak intensity of Li is 4×100, a counting ratio is 40.

TABLE 14

| | Li | Li/C |
|---|---|---|
| | Film Thickness | Counting |
| Ex. | (nm) | Ratio |
| 12 | 0.2 | 15.2 |
| 13 | 0.3 | 14.2 |
| 15 | 0.6 | 22.2 |
| 19 | 1.0 | 40.5 |

As apparent from Table 14, it is seen that a film thickness of a metal lithium and a Li/C counting ratio are in a proportion reaction in a range of a thickness of a metal lithium thin film of 0.3 nm or greater. Therefore, by obtaining a Li/C counting ratio, a thickness of a metal lithium thin film can be calculated. Based on results of Table 14, a calibration curve of a thickness of a metal lithium thin film and a Li/C counting ratio was produced and, regarding Examples 14, 16, 17 and 18, SIMS was measured, and a thickness of a metal lithium thin film (electron injecting layer) in each case was measured from a Li/C counting ratio.

Examples in accordance with a second aspect of the present invention will be explained below.

### EXPERIMENT 7

### Examples 20 to 22 and Comparative Example 4

An organic EL element having an anode, a hole injecting layer, a second light emitting unit, an intermediate unit, a first light emitting unit, an electron transporting layer, and a cathode shown in Table 15 was manufactured. In addition, as shown in Table 15, an organic EL element of Comparative Example 4 was manufactured according to the same manner as that of Examples 20 to 22 except that an intermediate unit was not provided. In the following Table, a numerical in ( ) indicates a thickness (nm) of each layer.

An anode was manufactured by forming a fluorocarbon (CFₓ) layer on a glass substrate on which an ITO (indium tin oxide) film had been formed. A fluorocarbon layer was formed by plasma polymerization of a CHF₃ gas. A thickness of a fluorocarbon layer was 1 nm.

On the thus manufactured anode, a hole injecting layer, a second light emitting unit, an intermediate unit, a first light emitting unit, an electron transporting layer, and a cathode were formed by successively depositing them by a deposition method.

A hole injecting layer was formed from HAT-CN6.

A second light emitting unit is formed by laminating a green emitting layer (NPB+1.0% tBuDPN) and a blue emitting layer (TBADN+2.5% TBP). In a second light emitting unit, a green emitting layer is situated on an anode side, and a blue emitting layer is situated on a cathode side. In addition, % is % by weight unless otherwise is indicated.

In a green emitting layer, NPB is used as a host material, and tBuDPN is used as a dopant material. And, tBuDPN is 5,12-bis(4-tertiary-butylphenyl)naphthacene, and has the following structure.

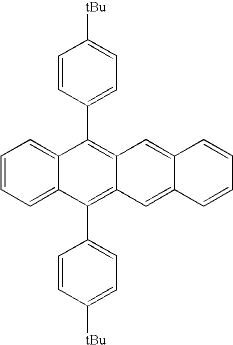

In a blue emitting layer, TBADN is used as a host material, and TBP is used as a dopant material.

A first light emitting unit is formed of a red light emitting layer (Alq+20% rubrene+1.0% DCJTB). Therefore, a first light emitting unit is formed of a single light emitting layer.

In a red light emitting layer, Alq is used as a host material, DCJTB is used as a first dopant material (light emitting material), and rubrene is used as a second dopant material (carrier transporting material). Alq is tris-(8-quinolilato)aluminum (III), and has the following structure.

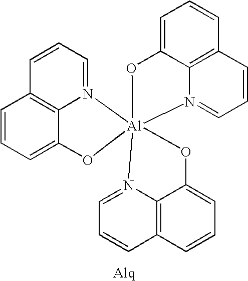

Rubrene has the following structure.

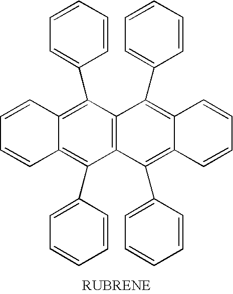

DCJTB is
(4-dicyanomethylene)-2-tertiary-butyl-6-(1,1,7,7-tetramethyljulolibyl)-9-enyl)-4H-pyran, and has the following structure.

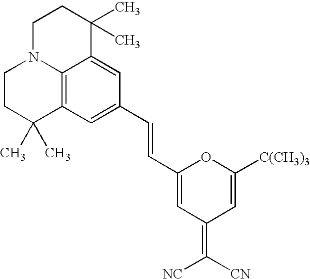

In the present Example, an adjacent layer comprising NPB is formed in an intermediate unit between a “HAT-CN6” layer of an intermediate unit, and a first light emitting unit. In addition, in the present Example, a first light emitting unit is constructed of a red simple light emitting layer. Like this, in a layer on an anode side of a first light emitting unit, when an arylamine-based hole transporting material such as NPB is not used as a host material, it is preferable to provide an adjacent layer in an intermediate unit.

TABLE 15

| | | Hole | | | | | Electron | |
|---|---|---|---|---|---|---|---|---|
| | | Injecting | Second Light | | Intermediate | First Light | Transporting | |
| | Anode | Layer | Emitting Unit | | Unit | Emitting Unit | Layer | Cathode |
| Ex. 20 | ITO/ | HAT- | NPB + 1.0% | TBADN + 2.5% | BCP(15)/ | Alq + 20% | BCP | Li₂O(0.1)/ |
| | CFₓ | CN6 | tBuDPN | TBP | Li₂O(0.1)/ | rubrene + 1.0% | (15) | Al(200) |
| | | (50) | (30) | (40) | HAT-CN6(50)/ | DCJTB | | |
| | | | | | NPB(30) | (30) | | |
| Ex. 21 | ITO/ | HAT- | NPB + 1.0% | TBADN + 2.5% | BCP(15)/ | Alq + 20% | BCP | Li₂O(0.1)/ |
| | CFₓ | CN6 | tBuDPN | TBP | Li(0.3)/ | rubrene + 1.0% | (15) | Al(200) |
| | | (50) | (30) | (40) | HAT-CN6(50)/ | DCJTB | | |
| | | | | | NPB(30) | (30) | | |
| Ex. 22 | ITO/ | HAT- | NPB + 1.0% | TBADN + 2.5% | BCP(15)/ | Alq + 20% | BCP | Li₂O(0.1)/ |
| | CFₓ | CN6 | tBuDPN | TBP | Cs(0.3)/ | rubrene + 1.0% | (15) | Al(200) |
| | | (50) | (30) | (40) | HAT-CN6(50)/ | DCJTB | | |
| | | | | | NPB(30) | (30) | | |
| Comp. | ITO/ | HAT- | NPB + 1.0% | TBADN + 2.5% | None | Alq + 20% | BCP | Li₂O(0.1)/ |
| Ex. 4 | CFₓ | CN6 | tBuDPN | TBP | | rubrene + 1.0% | (15) | Al(200) |
| | | (50) | (30) | (40) | | DCJTB | | |
| | | | | | | (30) | | |

Respective organic EL elements manufactured were measured for a chromaticity (CIE(x,y)), and a light emitting efficiency, and measurement results together with a driving voltage are shown in Table 2. A light emitting efficiency is a value at 10 mA/cm².

TABLE 16

| | Driving | | | Light emitting |
|---|---|---|---|---|
| | voltage | | | efficiency |
| | (V) | CIEₓ | CIE_{y} | (cd/A) |
| Ex. 20 | 6.7 | 0.23 | 0.38 | 20.5 |
| Ex. 21 | 6.2 | 0.23 | 0.37 | 21.5 |
| Ex. 22 | 6.4 | 0.23 | 0.38 | 20.9 |
| Comp. | 18 | 0.63 | 0.34 | 2.6 |
| Ex. 4 | | | | |

As apparent from results shown in Table 16, in organic EL elements of Examples 20 to 22, a high light emitting efficiency is obtained as compared with an organic EL element of Comparative Example 4. In addition, as apparent from results of chromaticity measurement, in organic EL elements of Examples 21 to 22, light emission closer to white is obtained as compared with an organic EL element of Comparative Example 4. In Comparative Example 4, recombination occurs around a center of a red light emitting layer, generating red emission.

The reason why organic EL elements of Examples 20 to 22 exhibit a high light emitting efficiency and better white is as described above.

In the present Example, since light emission occurs at two places of a first light emitting unit and a second light emitting unit, a light emitting efficiency is improved 2-fold. In addition, since light is emitted in each of a first light emitting unit and a second light emitting unit, white emission combining green and blue of a first light emitting unit, and red of a second light emitting unit can be obtained. To the contrary, when an intermediate unit is not provided, as described above, since light is emitted at one region in three light emitting layers, by shifting of a position of a light emitting region, a balance between light emitting intensities of R(red), G(green) and B(blue) is easily disintegrated, and better white cannot be obtained. Therefore, according to a second aspect of the present invention, white emission having a better balance of RCB can be obtained.

Not only in the case of a second light emitting unit of the present Example, but also in the case of a light emitting unit in which two light emitting layers are laminated, it is preferable to use a host material for a light emitting layer as a pair of an electron transporting material and a hole transporting material (in the present Example, PBADN which is an electron transporting material is used in a blue emitting layer, and NPB which is of hole transporting property is used in a green emitting layer). Thereby, recombination of an electron and a hole is fixed at an interface of both light emitting layers, and a light emitting site is not moved to change an emitting color relative to a change in a voltage to be applied to an element. Herein, an electron transporting material is an organic material having a higher mobility of an electron than a mobility of a hole, and a hole transporting material is an organic material having a higher mobility of a hole than a mobility of an electron.

### EXPERIMENT 8

### Example 23 and Comparative Example 5

An organic EL element of Example 23 provided with an anode, a hole injecting layer, a second light emitting unit, an intermediate unit, a first light emitting unit, an electron transporting layer, and a cathode shown in Table 17 was manufactured as in the Experiment 7. In addition, an organic EL element of Comparative Example 5 of a structure shown in Table 17 was manufactured, which is the same as the organic EL element of Example 23 except that an intermediate unit is not possessed.

In the present Example, a first light emitting unit is formed like a second light emitting unit of Experiment 7, and is formed of a green emitting layer provided on an anode side, and a blue emitting layer provided on a cathode layer.

In the present Example, a second light emitting layer is formed by laminating an orange emitting layer (NPB+3.0% DBzR) and a blue emitting layer (TBADN+2.5% TBP). In an orange emitting layer, NPB is used as a host material, and DBzR is used as a dopant material.

Organic EL elements of Example 23 and Comparative Example 5 have the aforementioned structure, and have four light emitting layers of orange/blue/green/blue.

TABLE 17

| | | | | | | | | Electron | |
|---|---|---|---|---|---|---|---|---|---|
| | | Hole Injecting | Second Light | | Intermediate | First Light | | Transporting | |
| | Anode | Layer | Emitting Unit | | Unit | Emitting Unit | | Layer | Cathode |
| Ex. 23 | ITO/CFₓ | HAT- | NPB + 3.0% | TBADN + 2.5% | BCP(15)/ | NPB + 1.0% | TBADN + 2.5% | BCP | Li₂O(0.1)/ |
| | | CN6 | DBzR | TBP | Li₂O(0.1)/ | tBuDPN | TBP | (15) | Al(200) |
| | | (100) | (30) | (40) | HAT-CN6(100) | (30) | (40) | | |
| Comp. | ITO/CFₓ | HAT- | NPB + 3.0% | TBADN + 2.5% | None | NPB + 1.0% | TBADN + 2.5% | BCP | Li₂O(0.1) |
| Ex. 5 | | CN6 | DBzR | TBP | | tBuDPN | TBP | (15) | Al/(200) |
| | | (100) | (30) | (40) | | (30) | (40) | | |

Organic EL elements of Example 23 and Comparative Example 5 were measured for a chromaticity and a light emitting efficiency as in Experiment 7, and measurement results together with a driving voltage are shown in Table 18.

TABLE 18

| | Driving | | | Light Emitting |
|---|---|---|---|---|
| | Voltage | | | Efficiency |
| | (V) | CIEₓ | CIE_{y} | (cd/A) |
| Ex. 23 | 17.0 | 0.25 | 0.35 | 13.0 |
| Comp. | 24.0 | 0.26 | 0.34 | 6.3 |
| Ex. 5 | | | | |

As apparent from results shown in Table 18, an organic EL element of Example 23 in accordance with the present invention has a high light emitting efficiency as compared with an organic EL element of Comparative Example 5. In addition, an organic EL element of Example 23 exhibits better white emission as compared with an organic EL element of Comparative Example 5. This is because, in an organic EL element of Example 23, light is emitted in a first light emitting unit and a second light emitting unit separately, respectively, while in an organic EL element of Comparative Example 5, light is emitted at one place in four light emitting layers which are continuously provided. In Comparative Example 5, recombination occurs only in one of light emitting units, and a recombination region is not expanded, therefore, a light emitting deficiency is reduced by a half.

Examples in accordance with a third aspect of the present invention will be explained below.

### EXPERIMENT 9

### Examples 24 to 26 and Comparative Example 6

Organic EL elements of Examples 24 to 26 and Comparative Example 6 having an anode, a hole transporting layer, a second light emitting unit, an intermediate unit, a first light emitting unit, an electron transporting layer, and a cathode shown in Table 19 were manufactured. As shown in Table 19, in Examples 24 to 26, a “HAT-CN6” layer which is an electron extracting layer of an intermediate unit is provided adjoining so as to directly contact with a first light emitting unit. In Comparative Example 6, a NPB layer as an adjacent layer is provided between a “HAT-CN6” layer which is an electron extracting layer, and a light emitting unit. In the following Table, a numerical in ( ) indicates a thickness (nm) of each layer.

An anode was manufactured by forming a fluorocarbon (CFₓ) layer on a glass substrate on which an ITO (indium tin oxide) layer had been formed. A fluorocarbon layer was formed by plasma polymerization of a CHF₃ gas. A thickness of a fluorocarbon layer was 1 nm.

On the thus manufactured anode, a hole transporting layer, a second light emitting unit, an intermediate unit, a first light emitting unit, an electron transporting layer, and a cathode were formed by successively depositing them by a deposition method.

A hole transporting layer was formed from NPB.

A first light emitting unit and a second light emitting unit are formed by laminating an orange light emitting layer (NPB+3.0% DBzR) and a blue emitting layer (TBADN+2.5% TBP). In any light emitting unit, an orange emitting layer is situated on an anode side, and a blue emitting layer is situated on a cathode side. In addition, % is % by weight unless otherwise is indicated.

In an orange emitting layer, NPB is used as a host material, and DBzR is used as a dopant material.

In a blue emitting layer, TBADN is used as a host material, and TBP is used as a dopant material.

TABLE 19

| | | Hole | | | | | | Electron | |
|---|---|---|---|---|---|---|---|---|---|
| | | Transporting | Second Light | | Intermediate | | | Transporting | |
| | Anode | Layer | Emitting Unit | | Unit | First Light Emitting Unit | | Layer | Cathode |
| Ex. 24 | ITO/ | NPB | NPB + 3.0% | TBADN + 2.5% | BCP(15)/ | NPB + 3.0% | TBADN + 2.5% | BCP | Li₂O(0.1)/ |
| | CFₓ | (100) | DBzR | TBP | Li₂O(0.1)/ | DBzR | TBP | (15) | Al(200) |
| | | | (30) | (40) | HAT-CN6(100) | (30) | (40) | | |
| Ex. 25 | ITO/ | NPB | NPB + 3.0% | TBADN + 2.5% | BCP(15)/ | NPB + 3.0% | TBADN + 2.5% | BCP | Li₂O(0.1)/ |
| | CFₓ | (100) | DBzR | TBP | Li(0.3)/ | DBzR | TBP | (15) | Al(200) |
| | | | (30) | (40) | HAT-CN6(100) | (30) | (40) | | |
| Ex. 26 | ITO/ | NPB | NPB + 3.0% | TBADN + 2.5% | BCP(15)/ | NPB + 3.0% | TBADN + 2.5% | BCP | Li₂O(0.1)/ |
| | CFₓ | (100) | DBzR | TBP | Cs(0.3)/ | DBzR | TBP | (15) | Al(200) |
| | | | (30) | (40) | HAT-CN6(100) | (30) | (40) | | |
| Comp. | ITO/ | NPB | NPB + 3.0% | TBADN + 2.5% | BCP(15)/ | NPB + 3.0% | TBADN + 2.5% | BCP | Li₂O(0.1)/ |
| Ex. 6 | CFₓ | (100) | DBzR | TBP | Li₂O(0.1)/ | DBzR | TBP | (15) | Al(200) |
| | | | (30) | (40) | HAT-CN6(100)/ | (30) | (40) | | |
| | | | | | NPB(20) | | | | |

Respective organic EL elements manufactured were measured for a chromaticity (CIE(x,y)), and a light emitting efficiency, and measurement results together with a driving voltage are shown in Table 20. In addition, a light emitting efficiency is a value at 10 mA/cm².

TABLE 20

| | Driving | | | Light Emitting |
|---|---|---|---|---|
| | Voltage | | | Efficiency |
| | (V) | CIEₓ | CIE_{y} | (cd/A) |
| Ex. 24 | 21.2 | 0.36 | 0.42 | 11.7 |
| Ex. 25 | 20.8 | 0.35 | 0.41 | 12.0 |
| Ex. 26 | 21.0 | 0.36 | 0.41 | 11.9 |
| Comp. | 23.2 | 0.35 | 0.41 | 9.7 |
| Ex. 6 | | | | |

As apparent from results shown in Table 20, it is seen that, in Examples 24 to 26 using an orange emitting layer of a first light emitting unit as an adjacent layer, a driving voltage is lowered as compared with Comparative Example 6 using a NPB layer in an intermediate unit as an adjacent layer. In addition, it is also seen that a light emitting efficiency is improved. This is thought as follows: by providing an orange emitting layer of a first light emitting unit adjoining an electron extracting layer, a hole generated by extraction of an electron from an electron extracting layer is effectively supplied to a first light emitting unit.

According to the third aspect of the present invention, a light emitting layer on an intermediate unit side of a first light emitting unit functions as an adjacent layer. Therefore, a first light emitting unit is provided so as to directly contact with an electron instructing layer, a driving voltage can be lowered, and a light emitting efficiency can be improved as compared with the case where an adjacent layer is provided between an electron extracting layer and a first light emitting unit.

Examples in accordance with a fourth aspect of the present invention will be explained below.

### EXPERIMENT 10

An organic EL element shown in FIG. 6 was manufactured.

As shown in Table 21, in an element structure shown in FIG. 6, a thickness of an electron extracting layer (HAD-CN6) of an intermediate minute was changed in a range of 5 to 150 nm.

TABLE 21

| | | | Second Light Emitting Unit | | | First Light Emitting Unit | | | |
|---|---|---|---|---|---|---|---|---|---|
| | | Hole | Orange | | | Orange | | Electron | |
| | | Injecting | Emitting | | Intermediate | Emitting | Blue Emitting | Transporting | |
| Ex. | Anode | Layer | Layer | Blue Emitting Layer | Unit | Layer | Layer | Layer | Cathode |
| 27 | ITO/ | HAT-CN6 | NPB + 3.0% | TBADN + 2.5% | BCP/Li/HAT-CN6 | NPB + 3.0% | TBADN + 2.5% TBP | BCP | LiF/Al |
| | CFₓ | (10) | DBzR (60) | TBP (50) | (10)/(0.6)/(5) | DBzR (60) | (50) | (10) | (1)/(200) |
| 28 | ITO/ | HAT-CN6 | NPB + 3.0% | TBADN + 2.5% | BCP/Li/HAT-CN6 | NPB + 3.0% | TBADN + 2.5% TBP | BCP | LiF/Al |
| | CFₓ | (10) | DBzR (60) | TBP (50) | (10)/(0.6)/(10) | DBzR (60) | (50) | (10) | (1)/(200) |
| 29 | ITO/ | HAT-CN6 | NPB + 3.0% | TBADN + 2.5% | BCP/Li/HAT-CN6 | NPB + 3.0% | TBADN + 2.5% TBP | BCP | LiF/Al |
| | CFₓ | (10) | DBzR(60) | TBP (50) | (10)/(0.6)/(30) | DBzR (60) | (50) | (10) | (1)/(200) |
| 30 | ITO/ | HAT-CN6 | NPB + 3.0% | TBADN + 2.5% | BCP/Li/HAT-CN6 | NPB + 3.0% | TBADN + 2.5% TBP | BCP | LiF/Al |
| | CFₓ | (10) | DBzR (60) | TBP (50) | (10)/(0.69)/(80) | DBzR (60) | (50) | (10) | (1)/(200) |
| 31 | ITO/ | HAT-CN6 | NPB + 3.0% | TBADN + 2.5% | BCP/Li/HAT-CN6 | NPB + 3.0% | TBADN + 2.5% TBP | BCP | LiF/Al |
| | CFₓ | (10) | DBzR (60) | TBP (50) | (10)/(0.6)/(100) | DBzR (60) | (50) | (10) | (1)/(200) |
| 32 | ITO/ | HAT-CN6 | NPB + 3.0% | TBADN + 2.5% | BCP/Li/HAT-CN6 | NPB + 3.0% | TBADN + 2.5% TBP | BCP | LiF/Al |
| | CFₓ | (10) | DBzR (60) | TBP (50) | (10)/(0.6)/(150) | DBzR (60) | (50) | (10) | (1)/(200) |

Properties of organic EL elements of Examples 27 to 32 were assessed. A voltage, a chromaticity and an efficiency are values when driven at a current of 10 mA/cm², and a luminance half life is a value when driven at a current of 40 mA/cm². Assessment results are shown in Table 22.

TABLE 22

| | Thickness | | | | | | |
|---|---|---|---|---|---|---|---|
| | of Electron | | | | | | |
| | Extracting | | | | Current | Power | Luminance |
| | Layer | | | | Efficiency | Efficiency | Half Life |
| Ex. | (nm) | Voltage (V) | CIEₓ | CIE_{y} | (cd/A) | (lm/W) | (hr) at40 mA/cm² |
| 27 | 5 | 8.85 | 0.29 | 0.36 | 28.74 | 10.20 | 500 |
| 28 | 10 | 8.98 | 0.29 | 0.37 | 29.84 | 10.44 | 1100 |
| 29 | 30 | 8.93 | 0.31 | 0.4 | 33.15 | 11.66 | 1000 |
| 30 | 80 | 8.94 | 0.31 | 0.41 | 30.21 | 10.62 | 950 |
| 31 | 100 | 8.97 | 0.31 | 0.41 | 29.14 | 10.2 | 900 |
| 32 | 150 | 8.99 | 0.32 | 0.42 | 25.71 | 8.98 | 600 |

As apparent from results shown in Table 22, in Examples 28 to 31, a luminance half life is 900 hours or longer, and it is seen that they are excellent in life property. In addition, they are also excellent in a power efficiency. Particularly, in Examples 28 and 29, a luminance half life is 1000 hours or longer, a power efficiency is 101 m/W or higher, and it is seen that life property and a light emitting efficiency are better.

To the contrary, in Example 27, a luminance half life is low, and it is seen that life property is inferior. This is thought that, since a thickness of an electron extracting layer is too small, Li is diffused from an electron injecting layer in a cathode direction, diffused lithium reaches a light emitting layer of a first light emitting unit, and suppresses recombination of a hole and an electron.

In addition, in Example 32, a luminance half life is reduced, and a power efficiency is also reduced, and it is seen that life property and a light emitting efficiency are reduced. In addition, in Example 32, a dark spot was generated.

From the forgoing, it is seen that a thickness of an electron extracting layer is preferably in a range of 8 to 100 nm, further preferably in a range of 10 to 80 nm, particularly preferably in a range of 10 to 30 nm.

Examples in accordance with a fifth aspect of the present invention will be explained below.

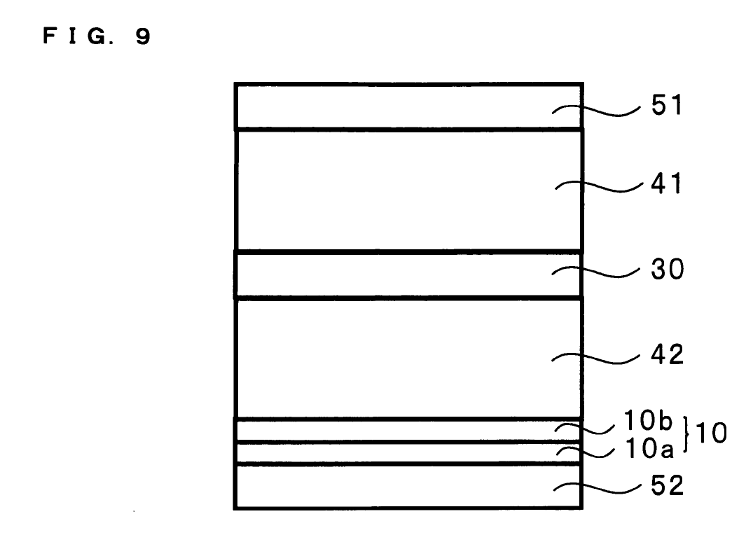

FIG. 9 is a schematic cross-sectional view showing an organic EL element in accordance with the present invention. As shown in FIG. 9, between a cathode 51 and an anode 52, a first light emitting unit 41 and a second light emitting unit 42 are provided. Between a first light emitting unit 41 and a second light emitting unit 42, an intermediate unit 30 is provided. A first light emitting unit 41 is provided on a cathode 51 side relative to an intermediate unit 31, and a second light emitting unit 42 is provided on an anode 52 side relative to an intermediate unit 30. An electron extracting layer is provided in an intermediate unit 30. An adjacent layer is provided on a cathode 51 side of this electron extracting layer. An adjacent layer may be provided in a first light emitting unit 41, or may be provided in an intermediate unit 30, as described above.

Between a second light emitting unit 42 and an anode 52, a hole injecting unit 10 is provided. A hole injecting unit 10 is constructed of a hole injecting layer 10b situated on a second light emitting unit 42, and a hole injection promoting layer 10a situated on an anode 52 side.

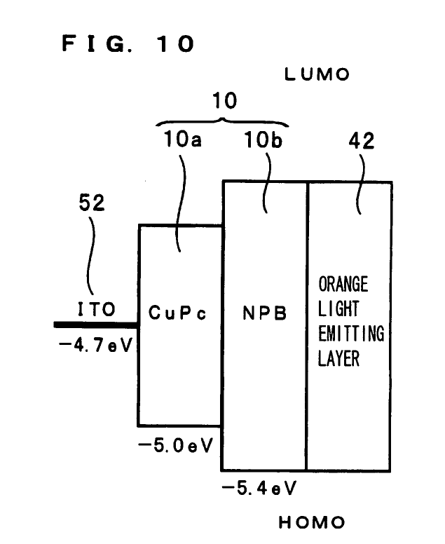

FIG. 10 is a view showing an energy diagram around a hole injecting unit.

In Example shown in FIG. 10, an anode 52 is formed of ITO (indium tin oxide).

A hole injection promoting layer 10a is formed of CuPc.

A hole injecting layer 10b is formed of NPB.

In FIG. 10, only an orange emitting layer which is a light emitting layer on an anode 52 side is shown as a second light emitting unit 42. This orange emitting layer uses NPB as a host material.

As shown in FIG. 10, an absolute value of a work function of an anode 52 is 4.7 eV, an absolute value of a HOMO energy level of a hole injection promoting layer 10a is 5.0 eV, and an absolute value of a HOMO energy level of a hole injecting layer is 5.4 eV.

Since a value of HOMO of a hole injection promoting layer 10a is a value between a value of work function of an anode and a value of HOMO of a hole injecting layer 10b as described above, this facilitates movement of a hole from an anode 52 to a hole injecting layer 10b. Therefore, injection of a hole from an anode 52 into a second light emitting unit can be promoted. Thereby, a hole can be effectively injected into a second light emitting unit, a light emitting intensity in a second light emitting unit can be relatively enhanced, and a light emitting efficiency as a hole element can be improved.

In a fifth aspect of the present invention, a thickness of a hole injection promoting layer 10a is preferably in a range of 1 to 100 nm, further preferably in a range of 5 to 20 nm. In addition, a thickness of a hole injecting layer 10b is preferably in a range of 1 to 300 nm, further preferably in a range of 10 to 200 nm.

### EXPERIMENT 11

### Examples 33 to 35 and Comparative Example 7

Organic EL elements of Examples 33 to 35 and Comparative Example 7 having an anode, a hole injecting unit, a second light emitting unit, an intermediate unit, a first light emitting unit, an electron transporting layer, and a cathode shown in Table 23 were manufactured. In the following Table, a numerical in ( ) indicates a thickness (nm) of each layer.

An anode was manufactured by forming a fluorocarbon (CFₓ) layer on a glass substrate on which an ITO (indium tin oxide) film had been formed. A fluorocarbon layer was formed by plasma polymerization of a CHF₃ gas. A thickness of a fluorocarbon layer was 1 nm.

On the anode manufactured as described above, a hole injecting unit, a second light emitting unit, an intermediate unit, a first light emitting unit, an electron transporting layer, and a cathode were formed by successively depositing them by a deposition method.

In Examples 33 to 35, a hole injecting unit is constructed of a hole injection promoting layer comprising CuPc, and a hole injecting layer comprising NPB. In Comparative Example 7, a hole injecting unit comprising a NPB layer is formed.

In addition, an intermediate unit is formed as in the intermediate unit 30 shown in FIG. 2 except that an electron injecting layer is formed of Li₂O, Li or Cs.

A first light emitting unit and a second light emitting unit are formed by laminating an orange light emitting layer (NPB+3.0% DBzR) and a blue emitting layer (TBADN+2.5% TBP). In any light emitting unit, an orange emitting layer is situated on an anode side, and a blue emitting layer is situated on a cathode side. And, % is % by weight unless otherwise is indicate.

In an orange emitting layer, NPB is used as a host material, and DBzR is used as a dopant material.

In a blue emitting layer, TBADN is used as a host material, and TBP is used as a dopant material.

TABLE 23

| | | Hole | | | | | | Electron | |
|---|---|---|---|---|---|---|---|---|---|
| | | Injecting | Second Light | | | First Light | | Transporting | |
| | Anode | Unit | Emitting Unit | | Intermediate Unit | Emitting Unit | | Layer | Cathode |
| Ex. 33 | ITO/ | CuPc/NPB | NPB + 3.0% | TBADN + 2.5% | BCP/Li₂O/HAT-CN6 | NPB + 3.0% | TBADN + 2.5% | BCP | Li₂O/Al |
| | CFx | (10)/(50) | DBzR | TBP | (15)/(0.1)/(100) | DBzR | TBP | (15) | (0.1)/(200) |
| | | | (30) | (40) | | (30) | (40) | | |
| Ex. 34 | ITO/ | CuPc/NPB | NPB + 3.0% | TBADN + 2.5% | BCP/Li/HAT-CN6 | NPB + 3.0% | TBADN + 2.5% | BCP | Li₂O/Al |
| | CFx | (10)/(50) | DBzR | TBP | (15)/(0.3)/(100) | DBzR | TBP | (15) | (0.1)/(200) |
| | | | (30) | (40) | | (30) | (40) | | |
| Ex. 35 | ITO/ | CuPc/NPB | NPB + 3.0% | TBADN + 2.5% | BCP/Cs/HAT-CN6 | NPB + 3.0% | TBADN + 2.5% | BCP | Li₂O/Al |
| | CFx | (10)/(50) | DBzR | TBP | (15)/(0.3)/(100) | DBzR | TBP | (15) | (0.1)/(200) |
| | | | (30) | (40) | | (30) | (40) | | |
| Comp. | ITO/ | NPB | NPB + 3.0% | TBADN + 2.5% | BCP/Li₂O/HAT-CN6 | NPB + 3.0% | TBADN + 2.5% | BCP | Li₂O/Al |
| Ex. 7 | CFx | (100) | DBzR | TBP | (15)/(0.1)/(100) | DBzR | TBP | (15) | (0.1)/(200) |
| | | | (30) | (40) | | (30) | (40) | | |

Respective organic EL elements manufactured were measured for a chromaticity (CIE(x,y)), and a light emitting efficiency, and measurement results together with a driving voltage are shown in Table 24. A light emitting efficiency is a value at 10 mA/cm².

TABLE 24

| | | | | Light Emitting |
|---|---|---|---|---|
| | Driving | | | Efficiency |
| | Voltage (V) | CIEₓ | CIE_{y} | (cd/A) |
| Ex. 33 | 16.7 | 0.33 | 0.39 | 19.8 |
| Ex. 34 | 15.8 | 0.33 | 0.38 | 20.8 |
| Ex. 35 | 16.1 | 0.32 | 0.38 | 20.1 |
| Comp. | 21.2 | 0.36 | 0.42 | 11.7 |
| Ex. 7 | | | | |

As apparent from results shown in Table 24, in Examples 33 to 35 in which a hole injecting unit consisting of a hole injection promoting layer and a hole injecting layer is provided in accordance with a fifth aspect of the present invention, a driving voltage is lowered, and a high light emitting efficiency is obtained as compared with Comparative Example 7 using a hole injecting unit consisting only of a NPB layer. This is thought that, by providing a hole injection promoting layer between an anode and a hole injecting layer in accordance with a fifth aspect of the present invention, movement of a hole from an anode to a second light emitting unit becomes easy, and injection of a hole into a second light emitting unit is promoted.

Examples in accordance with a sixth aspect of the present invention will be explained below.

An organic EL element of Examples in accordance with a sixth aspect of the present invention has a structure shown in FIG. 9 and, in FIG. 9, a hole injecting unit 10 is constructed of a first electron extracting layer 10a and a first adjacent layer 10b.

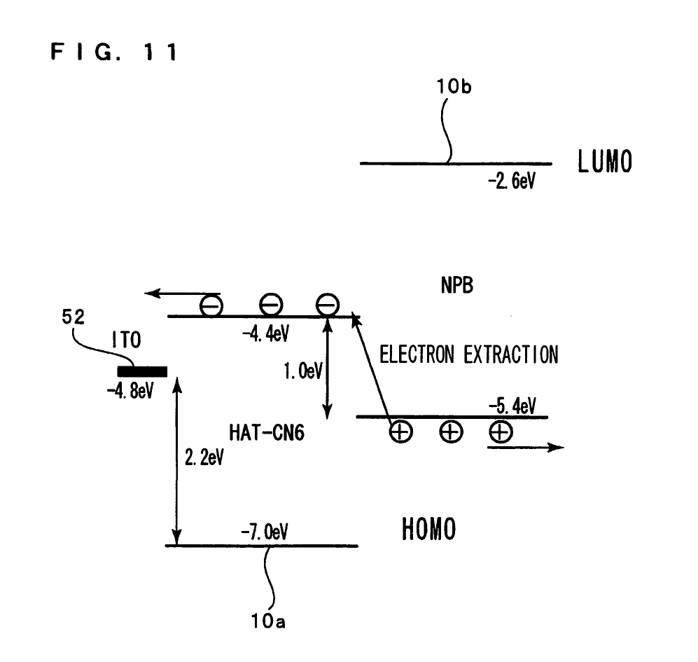

FIG. 11 is a view showing energy diagram around a hole injecting unit 10. A hole injecting unit 10 is constructed of a first electron extracting layer 10a and a first adjacent layer 10b, and a first electron extracting layer 10a is formed of HAT-CN6.

A first adjacent layer 10b is formed of NPB.

In a sixth aspect of the present invention, a thickness of a first electron extracting layer 10a is preferably in a range of 1 to 150 nm, further preferably in a range of 5 to 100 nm. In addition, a thickness of a first adjacent layer 10b is preferably in a range of 1 to 300 nm, further preferably in a range of 5 to 200 nm.

An anode 52 is formed of ITO (indium tin oxide).

As shown in FIG. 11, a difference between an absolute value (4.4 eV) of a LUMO energy level of a first electron extracting layer 10a and an absolute value (5.4 eV) of a HOMO energy level of a first adjacent layer 10b is 1.0 eV. Therefore, a first electron extracting layer 10b can extract an electron from a first adjacent layer 10b upon application of a voltage to an anode and a cathode. The extracted electron is absorbed into an anode 52.

On the other hand, in a first adjacent layer 10b, since an electron is extracted, a hole is generated. This hole is supplied to a second light emitting unit, and is recombined with an electron supplied from an intermediate unit 30 or a cathode 51. As described above, by extraction of an electron from a first adjacent layer 10b by a first electron extracting layer 10a, a hole is generated in a first adjacent layer 10b, and this hole is supplied to a light emitting unit. An absolute value of a work function of an anode 52 is 4.8 eV, an absolute value of an energy level of HOMO of a first electron extracting layer 10a is 7.0 eV and, since a difference thereof is large as 2.2 eV, a hole is injected from an anode 52 into a first electron extracting layer 10a with difficulty. In a sixth aspect of the present invention, as described above, by extraction of an electron from a first adjacent layer 10b by a first electron extracting layer 10a, a hole is generated in a first adjacent layer 10b, and this hole is supplied to a light emitting unit.

In a sixth aspect of the present invention, by the aforementioned mechanism, a hole can be effectively supplied from a hole injecting unit 10 to a light emitting unit and, for this reason, a driving voltage can be reduced, and a light emitting efficiency can be improved.

### EXPERIMENT 12

### Examples 36 to 38 and Comparative Examples 8 to 9

Organic EL elements of Examples 36 to 38 and Comparative Examples 8 to 9 having an anode, a hole injecting unit, a second light emitting unit, an intermediate unit, a first light emitting unit, an electron transporting layer, and a cathode shown in Table 25 were manufactured. In the following Table, a numerical in ( ) indicates a thickness (nm) of each layer.

TABLE 25

| | | Hole | | | | | | Electron | |
|---|---|---|---|---|---|---|---|---|---|
| | | Injecting | Second Light | | Intermediate | First Light | | Transporting | |
| | Anode | Unit | Emitting Unit | | Unit | Emitting Unit | | Layer | Cathode |
| Ex. 36 | ITO/ | HAT- | NPB + 3.0% | TBADN + 2.5% | BCP(15)/ | NPB + 3.0% | TBADN + 2.5% | BCP | Li₂O(0.1)/ |
| | CFₓ | CN6(100)/ | DBzR | TBP | Li₂O(0.1)/ | DBzR | TBP | (15) | Al(200) |
| | | NPB(20) | (30) | (40) | HAT-CN6(100)/ | (30) | (40) | | |
| | | | | | NPB(20) | | | | |
| Ex. 37 | ITO/ | HAT- | NPB + 3.0% | TBADN + 2.5% | BCP(15)/ | NPB + 3.0% | TBADN + 2.5% | BCP | Li₂O(0.1)/ |
| | CFₓ | CN6(100)/ | DBzR | TBP | Li(0.3)/ | DBzR | TBP | (15) | Al(200) |
| | | NPB(20) | (30) | (40) | HAT-CN6(100)/ | (30) | (40) | | |
| | | | | | NPB(20) | | | | |
| Ex. 38 | ITO/ | HAT- | NPB + 3.0% | TBADN + 2.5% | BCP(15)/ | NPB + 3.0% | TBADN + 2.5% | BCP | Li₂O(0.1)/ |
| | CFₓ | CN6(100)/ | DBzR | TBP | Cs(0.3)/ | DBzR | TBP | (15) | Al(200) |
| | | NPB(20) | (30) | (40) | HAT-CN6(100)/ | (30) | (40) | | |
| | | | | | NPB(20) | | | | |
| Comp. | ITO/ | NPB | NPB + 3.0% | TBADN + 2.5% | BCP(15)/ | NPB + 3.0% | TBADN + 2.5% | BCP | Li₂O(0.1)/ |
| Ex. 8 | CFₓ | (100) | DBzR | TBP | Li₂O(0.1)/ | DBzR | TBP | (15) | Al(200) |
| | | | (30) | (40) | HAT-CN6(100)/ | (30) | (40) | | |
| | | | | | NPB(20) | | | | |
| Comp. | ITO/ | None | NPB + 3.0% | TBADN + 2.5% | BCP(15)/ | NPB + 3.0% | TBADN + 2.5% | BCP | Li₂O(0.1)/ |
| Ex. 9 | CFₓ | | DBzR | TBP | Li₂O(0.1)/ | DBzR | TBP | (15) | Al(200) |
| | | | (30) | (40) | HAT-CN6(100)/ | (30) | (40) | | |
| | | | | | NPB(20) | | | | |

An anode was formed by forming a fluorocarbon (CFₓ) layer on a glass substrate on which an ITO (indium tin oxide) film had been formed. A fluorocarbon layer was formed by plasma polymerization of a CHF₃ gas. A thickness of a fluorocarbon layer was 1 nm.

On the anode manufactured as described above, a hole injecting unit, a second light emitting unit, an intermediate unit, a first light emitting unit, an electron transporting layer, and a cathode were formed by successively depositing them by a deposition method.

In a hole injecting unit of Examples 36 to 38, a “HAT-CN6” layer was formed as a first electron extracting layer, and a NPB layer was formed thereon as a first adjacent layer. In Comparative Example 8, a hole injecting unit was formed using only a NPB layer. In Comparative Example 9, a second light emitting unit was formed directly on an anode without forming a hole injecting unit.

In an intermediate unit, an electron injecting layer is formed using Li₂O, Li or Cs.

A first light emitting unit and a second light emitting unit are formed by laminating a light emitting layer (NPB+3.0% DBzR) and a blue emitting layer (TBADN+2.5% TBP). In any light emitting unit, an orange emitting layer is situated on an anode side, and a blue emitting layer is situated on a cathode side. And, % is % by weight unless otherwise is indicated.

In an orange emitting layer, NPB is used as a host material, and DBzR is used as a dopant material.

In a blue emitting layer, TBADN is used as a host material, and TBP is used as a dopant material.

Respective organic EL elements manufactured were measured for a chromaticity (CIE(x,y)), and a light emitting efficiency, and measurement results together with a driving voltage are shown in Table 26. A light emitting efficiency is a value at 10 nA/cm².

TABLE 26

| | Driving | | | Light Emitting |
|---|---|---|---|---|
| | Voltage | | | Efficiency |
| | (V) | CIEₓ | CIE_{y} | (cd/A) |
| Ex. 36 | 12.4 | 0.35 | 0.42 | 20.2 |
| Ex. 37 | 11.5 | 0.34 | 0.41 | 21.2 |
| Ex. 38 | 11.8 | 0.35 | 0.42 | 20.9 |
| Comp. | 21.0 | 0.36 | 0.42 | 11.7 |
| Ex. 8 | | | | |
| Comp. | 13.0 | 0.32 | 0.41 | 17.3 |
| Ex. 9 | | | | |

As apparent from results shown in Table 26, in organic EL elements of Examples 36 to 38 in which a hole injecting unit consisting of a first electron extracting layer and a first adjacent layer is formed in accordance with a sixth aspect of the present invention, a driving voltage is low, and a light emitting efficiency is high as compared with organic EL elements of Comparative Examples 8 and 9.

Examples in accordance with a seventh aspect of the present invention will be explained below.

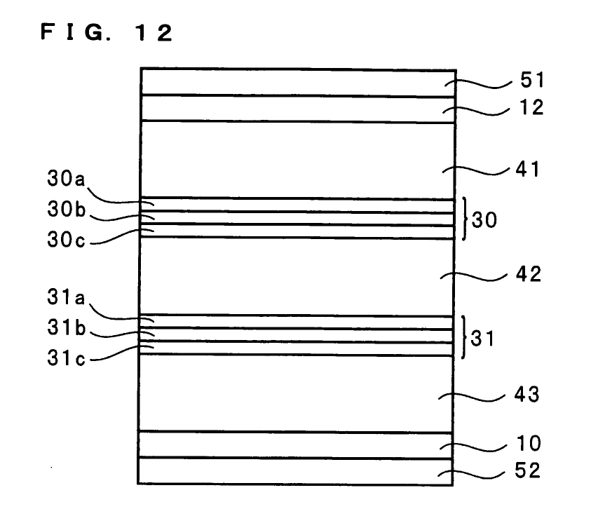

FIG. 12 is a schematic cross-sectional view showing an organic EL element in accordance with a seventh aspect of the present invention. As shown in FIG. 12, between a cathode 51 and an anode 52, a first light emitting unit 41, a second light emitting unit 42, and a third light emitting unit 43 are provided. Between a first light emitting unit 41 and a second light emitting unit 42, an intermediate unit 30 is provided. Between a second light emitting unit 42 and a third light emitting unit 43, an intermediate unit 31 is provided.

An intermediate unit 30 is constructed of an electron extracting layer 30a situated on a cathode 51 side, an electron transporting layer 30c situated on an anode 52 side, and an electron injecting layer 30b provided between an electron extracting layer 30a and an electron transporting layer 30c. Likewise, an intermediate unit 31 is constructed of an electron extracting layer 31a provided on a cathode 51 side, an electron transporting layer 31c provided on a cathode 52 side, and an electron injecting layer 31b provided between an electron extracting layer 31a and an electron transporting layer 31c.

Between a cathode 51 and a first light emitting unit 41, an electron transporting layer 12 is provided. Between an anode 52 and a third light emitting unit 43, a hole injecting layer 10 is provided.

In a seventh aspect of the present invention, film thicknesses of respective electron transporting layers 12, 30c and 31c are set to be greater as they become more distant from a cathode 51. Therefore, a film thickness of an electron transporting layer 30c is set to be greater than a film thickness of an electron transporting layer 12, and a film thickness of an electron transporting layer 31c is set to be greater than a film thickness of an electron transporting layer 30c. Respective film thicknesses of electron transporting layers 12, 30c and 31c are set to be not greater than 40 nm.

By providing film thicknesses of electron transporting layers 12, 30c and 31c as described above, a balance of electron injection into respective light emitting units 41, 42 and 43 can be improved. For this reason, light emitting intensities in respective light emitting units 41, 42 and 43 can be made to approach a uniform intensity and, as a result, a light emitting efficiency as a whole element can be improved.

According to the other embodiment of a seventh aspect of the present invention, film thicknesses of a hole injecting layer 10 and electron extracting layers 30a and 31a are set to be greater as they become more distant from an anode 52. Therefore, a film thickness of an electron extracting layer 31a is set to be greater than a film thickness of a hole injecting layer 10, and a film thickness of an electron extracting layer 30a is set to be greater than a film thickness of an electron extracting layer 31a. In addition, respective film thicknesses of a hole injecting layer and electron extracting layers 30a and 31a are set to be not greater than 100 nm.

By setting film thicknesses of a hole injecting layer 10 and electron extracting layers 30a and 31a as described above, a balance of injection of a hole into respective light emitting units 41, 42 and 43 can be improved. As a result, light emitting intensities in respective light emitting units 41, 42 and 43 can be made to approach a uniform intensity, and a light emitting efficiency as a whole element can be improved.

In Example shown in FIG. 12, three light emitting units are possessed, but the present invention is not limited to this, and it is enough that at least two light emitting units may be provided.

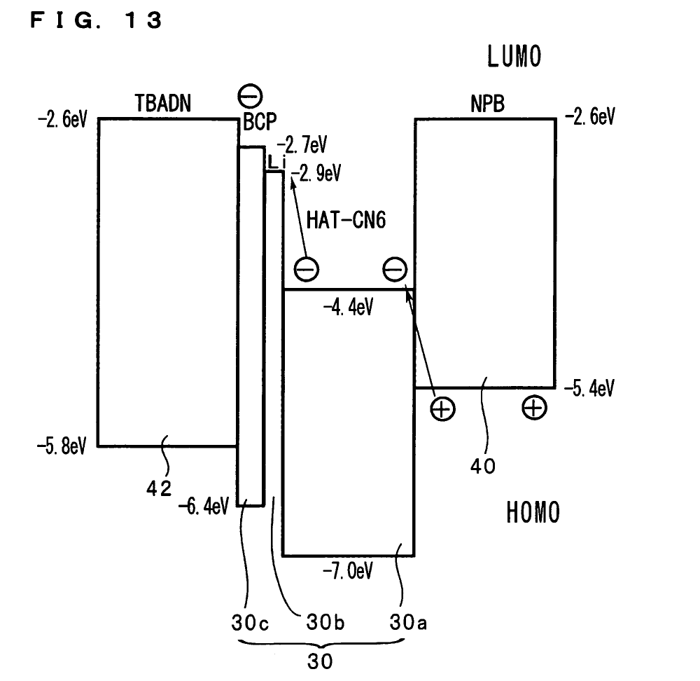

FIG. 13 is a view showing energy diagram around an intermediate unit. An intermediate unit 30 is constructed of an electron extracting layer 30a, an electron injecting layer 30b and an electron transporting layer 30c. On a cathode side of an electron extracting layer 30a, an adjacent layer 40 is provided. In addition, on an anode side of an intermediate unit 30, a second light emitting unit 42 is provided. In FIG. 13, only layers on an intermediate unit 30 side of a second light emitting unit 42 are shown.

In Example shown in FIG. 13, an electron extracting layer 30a is formed of HAT-CN6.

In addition, an electron injecting layer 30b is formed of Li (metal lithium).

In addition, an electron transporting layer 30c is formed of BCP.

In a seventh aspect of the present invention, as described above, a film thickness of an electron transporting layer is not larger than 40 nm, further preferably in a range of 1 to 40 nm. A film thickness of an electron injecting layer is in a range of 0.1 to 10 nm, further preferably in a range of 0.1 to 1 nm. A film thickness of an electron extracting layer 30a is, as described above, preferably not larger than 100 nm, more preferably in a range of 1 to 100 nm, further preferably in a range of 5 to 50 nm.

In Example shown in FIG. 13, an adjacent layer 40 is formed of NPB.

In Example shown in FIG. 13, a layer indicated as a second light emitting unit 42 is formed of TBADN.

As shown in FIG. 13, a difference between an absolute value (4.4 eV) of a LUMO energy level of an electron extracting layer 30a and an absolute value (5.4 eV) of a HOMO energy level of an adjacent layer 40 is within 1.5 eV. In addition, an absolute value of a LUMO energy level (work function) of an electron injecting layer 30b is smaller than an absolute value of a LUMO energy level of an electron extracting layer 30a, and an absolute value of a LUMO energy level of an electron transporting layer 30c is smaller than an absolute value of a LUMO energy level of an electron injecting layer 30b.

Therefore, an electron extracting layer 30a can extract an electron from an adjacent layer 40 upon application of a voltage to an anode and a cathode.

The extracted electron is supplied to a second light emitting unit 42 through an electron injecting layer 30b and an electron transporting layer 30c.

In addition, in an adjacent layer 40, since an electron is extracted, a hole is generated. This hole is supplied to a first light emitting unit, and is recombined with an electron supplied from a cathode or an adjacent intermediate unit. As a result, light is emitted in a first light emitting unit.

An electron supplied to a second light emitting unit is recombined with a hole supplied from an anode or an adjacent intermediate unit, in a second light emitting unit 42. As a result, light is emitted in a second light emitting unit 42 as well as in a third light emitting unit 43.

As described above, according to the present invention, a recombination region can be formed in a first light emitting unit, a second light emitting unit, and a third light emitting unit, respectively, and light can be emitted. As a result, a light emitting efficiency can be enhanced and, at the same time, light can be emitted at an emitting color of a first light emitting unit, a second light emitting unit, and a third light emitting unit.

### EXPERIMENT 13

An organic EL element having an anode, a hole injecting layer, a second light emitting unit, an intermediate unit, a first light emitting unit, an electron transporting layer, and a cathode shown in Table 27 was manufactured. In the following Table, a numerical in ( ) indicates a film thickness (nm) of each layer. In an intermediate unit, a film thickness X of an electron transporting layer formed of BCP was changed between 70 nm and 500 nm as shown in Table 28.

An anode was manufactured by forming a fluorocarbon (CFₓ) layer on a glass substrate on which an ITO (indium tin oxide) film had been formed. A fluorocarbon layer was formed by plasma polymerization of a CHF₃ gas. A thickness of a fluorocarbon layer was 1 nm.

On the anode manufactured as described above, a hole injecting layer, a second light emitting unit, an intermediate unit, a first light emitting unit, an electron transporting layer, and a cathode were formed by successively depositing them by a deposition method.

A hole injecting layer is formed of HAT-CM6.

An intermediate unit is formed as in the intermediate unit 30 shown in FIG. 2 except that an electron injecting layer is formed of Li₂O.

A first light emitting unit and a second light emitting unit are formed by laminating an orange emitting layer (90% NPB+10% tBuDPN+3.0% DBzR) and a blue emitting layer (80% TBADN+20% NPB+2.5% TBP). In any light emitting unit, an orange emitting layer is situated on an anode side, and a blue emitting layer is situated on a cathode side. And, % is % by weight unless otherwise is indicated.

In an orange emitting layer, 90% NPB+10% tBuDPN is used as a host material, and 3.0% by weight of DBzR with respect to 100% by weight of the sum of NPB and tBuDPN is used as a dopant material.

In a blue emitting layer, 80% TBADN+20% NPB are used as a host material, and 2.5% by weight of TBP with respect to 100% by weight of the sum of TBADN and NPB is used as a dopant material.

TABLE 27

| | Hole | | | | | | Electron | |
|---|---|---|---|---|---|---|---|---|
| | Injecting | | | Intermediate | First Light Emitting | | Transporting | |
| Anode | Layer | Second light Emitting Unit | | Unit | Unit | | Layer | Cathode |
| ITO/ | HAT- | 90% NPB + | 80% TBADN + 20% | BCP(X)/ | 90% NPB + 10% | 80% TBADN + 20% | BCP | LiF(1)/ |
| | | 10% | | | | | | |
| CFx | CN6 | tBuDPN + | NPB + | Li₂O(0.2)/ | tBuDPN + 3.0% | NPB + 2.5% | (12) | Al(200) |
| | (50) | 3.0% | | | | | | |
| | | 2.5% DBzR | TBP | HAT-CN6(50) | DBzR | TBP | | |
| | | (50) | (50) | | (50) | (50) | | |

Respective organic EL elements manufactured were measured for a light emitting efficiency, and measurement results together with a driving voltage are shown in Table 28. A light emitting efficiency is a value at 20 mA/cm².

TABLE 28

| | Film Thickness | | | | |
|---|---|---|---|---|---|
| Film Thickness | of Electron | | | | |
| of Electron | Transporting | Ratio of Film Thickness | | Ratio of | |
| Transporting | Layer of | of Electron Transporting | Light | Light | |
| Layer on | Intermediate | Layer | Emitting | Emitting | |
| Cathode Side | Unit | (Intermediate | Efficiency | Efficiency | Driving |
| (nm) | (nm) | Unit/Cathode Side) | (cd/A) | (%) | Voltage |
| 12 | 7 | 0.6 | 22.8 | 93 | 7.9 |
| 12 | 12 | 1.0 | 24.1 | 100 | 7.2 |
| 12 | 17 | 1.4 | 29.5 | 122 | 7.8 |
| 12 | 22 | 1.8 | 30.5 | 127 | 7.7 |
| 12 | 32 | 2.7 | 26.4 | 110 | 7.8 |
| 12 | 40 | 3.3 | 24.4 | 101 | 8.2 |
| 12 | 50 | 4.2 | 19.1 | 79 | 8.5 |

As apparent from results shown in Table 28, it is seen that, when a film thickness of an electron transporting layer of an intermediate unit is 17 nm to 40 nm, and is greater than that of an electron transporting layer on a cathode side, a light emitting efficiency is improved as compared with the case where the film thickness is 120 nm which is the same as that of an electron transporting layer on a cathode side. This is thought as follows: By making a film thickness of an electron transporting layer of an intermediate unit great, injection of an electron in a second light emitting unit which is far from a cathode side is promoted and, as a result, injection of an electron becomes approximately the same extent in a first light emitting unit and a second light emitting unit, light emitting intensities of a first light emitting unit and a second light emitting unit approach a uniform intensity, and a light emitting efficiency as a whole is enhanced.

When a film thickness of an electron transporting layer of an intermediate unit is 50 nm, a light emitting efficiency is lowered. This is thought as follows: Since a film thickness of an electron transporting layer becomes too great, disorder occurs in electron injection, thereby, a light emitting efficiency is reduced.

In addition, it is seen that, when a film thickness of an electron transporting layer of an intermediate unit is 7 nm, and is smaller than a film thickness of an electron transporting layer on a cathode side, a light emitting efficiency is reduced.

From the forgoing, it is seen that, in accordance with a seventh aspect of the present invention, by setting film thicknesses of respective electron transporting layers so that they become greater as they become more distant from a cathode, and setting film thicknesses to be not greater than 40 nm, a better light emitting efficiency is obtained.

### EXPERIMENT 14

An organic EL element having an anode, a hole injecting layer a third light emitting unit, a second intermediate unit, a second light emitting unit, a first intermediate unit, a first light emitting unit, an electron transporting layer, and a cathode shown in Table 29 was manufactured. In the following Table, a thickness in ( ) indicates a thickness (nm) of each layer.

A first intermediate unit and a second intermediate unit are formed as in Experiment 1 except that a film thickness X of an electron transporting layer of a first intermediate unit and a film thickness Y of an electron transporting layer of a second intermediate unit are changed as shown in Table 30.

In addition, first to third light emitting units are formed as in light emitting units in Experiment 13. In addition, an anode, a hole injecting layer, an electron transporting layer, and a cathode are formed as in Experiment 13.

An organic EL device manufactured was measured for a light emitting efficiency, and measurement results are shown in Table 30.

TABLE 29

| | Hole | | | | | |
|---|---|---|---|---|---|---|
| | Injecting | Third light | | Second Intermediate | Second Light | |
| Anode | Layer | Emitting Unit | | Unit | Emitting Unit | |
| ITO/ | HAT- | 90% NPB + 10% | 80% TBADN + 20% | BCP(Y)/ | 90% NPB + 10% | 80% TBADN + 20% |
| CFx | CN6 | tBuDPN + 3.0% | NPB + 2.5% | Li₂O(0.2)/ | tBuDPN + 3.0% | NPB + 2.5% |
| | (50) | DBzR | TBP | HAT-CN6(50) | DBzR | TBP |
| | | (50) | (50) | | (50) | (50) |

| | | | | |
|---|---|---|---|---|
| | | First | Electron | |
| Anode | First Intermediate | Light Emitting | Transporting | |
| | Unit | Unit | Layer | Cathode |

| | | | | | |
|---|---|---|---|---|---|
| ITO/ | BCP(X)/ | 90% NPB + 10% | 80% TBADN + 20% | BCP | LiF(1)/ |
| CFx | Li₂O(0.2)/ | tBuDPN + 3.0% | NPB + 2.5% | (12) | Al(200) |
| | HAT-CN6(50) | (50) | DBzR | TBP | |
| | | | (50) | | |

TABLE 30

| | | Film | | | | |
|---|---|---|---|---|---|---|
| | Film | Thicknesses | | | | |
| Film | Thickness | Y (nm) of | Ratio of Film | Ratio of Film | | |
| Thickness of | X (nm) of | Electron | Thickness of | Thicknesses of | | |
| Electron | Electron | Transporting | Electron | Electron | | |
| Transporting | Transporting | Layer of | Transporting | Transporting | Light | |
| Layer on | Layer of First | Second | Layers (First | Layers (Second | Emitting | Driving |
| Cathode side | Intermediate | Intermediate | Intermediate | Intermediate | Efficiency | Voltage |
| (nm) | Unit | Unit | Unit/Cathode Side) | Unit/Cathode Side) | (cd/A) | (V) |
| 12 | 12 | 12 | 1.00 | 1.00 | 57.1 | 11.2 |
| 12 | 14 | 18 | 1.17 | 1.50 | 65 | 11.3 |

As shown in Table 30, it is seen that, by making a film thickness of an electron transporting layer of a first intermediate unit to be greater than a film thickness of an electron transporting layer on a cathode side, and making a film thickness of an electron transporting layer of a second intermediate unit to be greater than a film thickness of an electron transporting layer of a first intermediate unit, a high light emitting efficiency is obtained.

### EXPERIMENT 15

An organic EL element having an anode, a hole injecting layer, a forth light emitting unit, a third intermediate unit, a third light emitting unit, a second intermediate unit, a second light emitting unit, a first intermediate unit, a first light emitting unit, an electron transporting layer, and a cathode shown in Table 31 was manufactured.

An intermediate unit was formed as in the intermediate unit of Experiment 13 except that a film thickness X of an electron transporting layer of a first intermediate unit, a film thickness Y of an electron transporting layer of a second intermediate unit, and a film thickness Z of an electron transporting layer of a third intermediate unit were set at values shown in Table 32.

First to fourth light emitting units were formed as in the light emitting unit of Experiment 13. In addition, an anode, a hole injecting layer, an electron transporting layer, and a cathode were formed as in Experiment 13.

Respective organic EL elements manufactured were measured for a light emitting efficiency, and a light emitting efficiency together with a driving voltage is shown in Table 32.

TABLE 31

| | | | | |
|---|---|---|---|---|
| | Hole | Fourth | | Third |
| | Injecting | Light Emitting | Third Intermediate | light Emitting |
| Anode | Layer | Unit | Unit | Unit |

| | | | | | | |
|---|---|---|---|---|---|---|
| ITO/ | HAT- | 90% NPB + 10% | 80% TBADN + 20% | BCP(Z)/ | 90% NPB + 10% | 80% TBADN + 20% |
| CFx | CN6 | tBuDPN + 3.0% | NPB + 2.5% | Li₂O(0.2)/ | tBuDPN + 3.0% | NPB + 2.5% |
| | (20) | DBzR | TBP | HAT-CN6(20) | DBzR | TBP |
| | | (50) | (50) | | (50) | (50) |

| | | Second | | First | First | | Electron | |
|---|---|---|---|---|---|---|---|---|
| | Second Intermediate | Light Emitting | | Intermediate | Light Emitting | | Transporting | |
| Anode | Unit | Unit | | Unit | Unit | | Layer | Cathode |
| ITO/ | BCP(Y)/Li₂O(0.2)/ | 90% NPB + 10% | 80% TBADN + 20% | BCP(X)/ | 90% NPB + 10% | 80% TBADN + | BCP | LiF(1)/ |
| CFx | HAT-CN6(20) | tBuDPN + 3.0% | NPB + 2.5% | Li₂O(0.2)/ | tBuDPN + 3.0% | 20% | (12) | Al(200) |
| | | DBzR | TBP | HAT-CN6(20) | DBzR | TBP | NPB + 2.5% | |
| | | (50) | (50) | | (50) | (50) | | |

TABLE 32

| | | Film Thickness | | | |
|---|---|---|---|---|---|
| | Film Thickness | Y (nm) of | Film Thickness | | |
| Film Thickness | X (nm) of | Electron | Z (nm) of | | |
| Electron | Electron | Transporting | Electron | | |
| Transporting | Transporting | Layer of | Transporting | | |
| Layer on | Layer of First | Second | Layer of Third | Light | Driving |
| Cathode Side | Intermediate | Intermediate | Intermediate | Emitting | Voltage |
| (nm) | Unit | Unit | Uni | Efficiency | (V) |
| 12 | 12 | 12 | 12 | 75.3 | 17.6 |
| 12 | 14 | 16 | 18 | 79.2 | 17.5 |

As apparent from results shown in Table 32, by making a film thickness of an electron transporting layer of a first intermediate unit greater than a film thickness of an electron transporting layer on a cathode side, making a film thickness of an electron transporting layer of a second intermediate unit greater than an electron transporting layer of a first intermediate unit, and making a film thickness of an electron transporting layer of an third intermediate unit greater than a film thickness of an electron transporting layer of a second intermediate unit, a high light emitting efficiency is obtained.

### EXPERIMENT 16

In the present Experiment, thicknesses of a hole injecting layer and an electron extracting layer were changed.

An organic EL element having an anode, a hole injecting layer, a second light emitting unit, an intermediate unit, a first light emitting unit, an electron transporting layer and a cathode shown in Table 33 was manufactured.

Respective layers were formed as in Experiment 13 except that a film thickness Y of an electron extracting layer of an intermediate unit was changed in a range of 10 nm to 110 nm as shown in Table 34, and a film thickness of an electron transporting layer of an intermediate unit is 12 nm which is the same as a film thickness of an electron transporting layer on a cathode side.

Respective organic EL elements manufactured were measured for a light emitting efficiency, and a light emitting efficiency and a driving voltage are shown in Table 34.

TABLE 33

| | Hole | Second | | | First | | Electron | |
|---|---|---|---|---|---|---|---|---|
| | Injecting | Light Emitting | | Intermediate | Light Emitting | | Transporting | |
| Anode | Layer | Unit | | Unit | Unit | | Layer | Cathode |
| ITO/ | HAT- | 90% NPB + | 80% TBADN + | BCP(12)/ | 90% NPB + 10% | 80% TBADN + 20% | BCP | LiF(1)/ |
| CFx | CN6 | 10% tBuDPN + | 20% NPB + | Li₂O(0.2)/ | tBuDPN + 3.0% | NPB + 2.5% | (12) | Al(200) |
| | (X) | 3.0% DBzR | 2.5% TBP | HAT-CN6(Y) | DBzR | TBP | | |
| | | (50) | (50) | | (50) | (50) | | |

TABLE 34

| | | | Ratio of | |
|---|---|---|---|---|
| Film Thickness | Film thickness | Light | Light | |
| X (nm) of Hole | Y (nm) of Electron | Emitting | Emitting | Driving |
| Injecting Layer | Extracting Layer of | Efficiency | Efficiency | Voltage |
| on Anode Side | Intermediate Unit | (cd/A) | (%) | (V) |
| 50 | 10 | 18.6 | 77 | 7.7 |
| 50 | 50 | 24.1 | 100 | 7.2 |
| 50 | 70 | 26.5 | 110 | 7.7 |
| 50 | 100 | 24.8 | 103 | 8.1 |
| 50 | 110 | 19.2 | 80 | 8.6 |

As apparent from results shown in Table 34, it is seen that by setting a film thickness of an electron extracting layer of an intermediate unit to be in a range of 70 nm to 100 nm which is greater than a film thickness of a hole injecting layer on a cathode side, higher light emitting efficiency is obtained than a light emitting efficiency obtained when the film thickness is 50 nm, being the same as a film thickness of a hole injecting layer. It is seen that, when a film thickness of an electron extracting layer is 110 nm, a light emitting efficiency is lowered. This is thought that, when a thickness of an electron extracting layer becomes too great, disorder occurs in hole movement. In addition, it is seen that, when a film thickness of an electron extracting layer is smaller than a film thickness of a hole injecting layer, a light emitting efficiency is reduced.

### EXPERIMENT 17

In the present Experiment, the number of light emitting units was 3, and a film thickness of an electron extracting layer in an intermediate unit was changed.

An organic EL element having an anode, a hole injecting layer, a third light emitting unit, a second intermediate unit, a second light emitting unit, a first intermediate unit, a first light emitting unit, an electron transporting layer, and a cathode shown in Table 35 was manufactured.

A film thickness Z of an electron extracting layer of a first light emitting unit, and a film thickness Y of an electron extracting layer of a second intermediate unit were changed as shown in Table 36. According to the same manner as that of Experiment 13 except for the above condition, an anode, a hole injecting layer, each light emitting unit, each intermediate unit, an electron transporting layer, and a cathode were formed.

Respective organic EL elements manufactured were measured for a light emitting efficiency, and measurement results together with a driving voltage are shown in Table 36.

TABLE 35

| | Hole | Third | | Second | Second | | First |
|---|---|---|---|---|---|---|---|
| | Injecting | Light Emitting | | Intermediate | Light Emitting | | Intermediate |
| Anode | Layer | Unit | | Unit | Unit | | Unit |
| ITO/ | HAT- | 90% NPB + 10% | 80% TBADN + | BCP(12)/ | 90% NPB + 10% | 80% TBADN + 20% | BCP(12)/ |
| CFx | CN6 | tBuDPN + 3.0% | 20% NPB + 2.5% | Li₂O(0.2)/ | tBuDPN + 3.0% | NPB + 2.5% | Li₂O(0.2)/ |
| | (X) | DBzR | TBP | HAT-CN6(Y) | DBzR | TBP | HAT-CN6(Z) |
| | | (50) | (50) | | (50) | (50) | |

| Anode | First Light Emitting Unit | | Electron Transporting Layer | Cathode |
|---|---|---|---|---|
| ITO/ | 90% NPB + 10% tBuDPN + 3.0% | 80% TBADN + 20% NPB + 2.5% TBP | BCP (12) | LiF (1)/Al (200) |
| CFx | DBzR (50) | (50) | | |

TABLE 36

| | Film Thickness | | | |
|---|---|---|---|---|
| | Y (nm) of | Film Thickness | | |
| Film | Electron | Z (nm) of | | |
| Thickness | Extracting | Electron | Light | |
| X (nm) of Hole | Layer of First | Extracting | Emitting | Driving |
| Injecting Layer | Intermediate | Layer of Second | Efficiency | Voltage |
| on Anode Side | Unit | Intermediate Unit | (cd/A) | (V) |
| 50 | 50 | 50 | 57.1 | 11.2 |
| 50 | 60 | 70 | 61.2 | 11.7 |

As apparent from results shown in Table 36, by making a film thickness of an electron extracting layer of a first intermediate unit greater than a film thickness of a hole injecting layer on an anode side, and making a film thickness of an electron extracting layer of a second intermediate unit greater than a film thickness of an electron extracting layer of a first intermediate unit, a high light emitting efficiency is obtained.

### EXPERIMENT 18

In the present Experiment, both of an electron extracting layer and an electron transporting layer of an intermediate unit were changed.

An organic EL element having an anode, a hole injecting layer, a second light emitting unit, an intermediate unit, a first light emitting unit, an electron transporting layer and a cathode shown in Table 37 was manufactured.

A film thickness Z of an electron transporting layer of an intermediate unit and a film thickness Y of an electron extracting layer were changed as shown in Table 38. According to the same manner as that of Experiment 13 except for the above condition, an anode, a hole injecting layer, each light emitting unit, an intermediate unit, an electron transporting layer, and a cathode were formed.

Respective organic EL elements manufactured were measured for a light emitting efficiency, and measurement results together with a driving voltage are shown in Table 38.

TABLE 37

| | Hole | Second | | | First | | Electron | |
|---|---|---|---|---|---|---|---|---|
| | Injecting | Light Emitting | | Intermediate | Light Emitting | | Transporting | |
| Anode | Layer | Unit | | Unit | Unit | | Layer | Cathode |
| ITO/ | HAT- | 90% NPB + 10% | 80% TBADN + | BCP(Z)/ | 90% NPB + 10% | 80% TBADN + | BCP | LiF(1)/ |
| CFx | CN6 | tBuDPN + 3.0% | 20% NPB + 2.5% | Li₂O(0.2)/ | tBuDPN + 3.0% | 20% NPB + 2.5% | (W) | Al(200) |
| | (X) | DBzR | TBP | HAT-CN6(Y) | DBzR | TBP | | |
| | | (50) | (50) | | (50) | (50) | | |

TABLE 38

| | | Film Thickness | Film thickness | | | |
|---|---|---|---|---|---|---|
| Film Thickness | | W (nm) of | Z (nm) of | | Ratio of | |
| X (nm) of | Film Thickness | Electron | Electron | Light | Light | |
| Hole Injecting | Y (nm) of Electron | Transporting | Transporting | Emitting | Emitting | Driving |
| Layer on Anode | Extracting Layer of | Layer on | Layer of | Efficiency | Efficiency | Voltage |
| Side | Intermediate Unit | Cathode Side | Intermediate Unit | (cd/A) | (%) | (V) |
| 50 | 10 | 12 | 7 | 18.8 | 78 | 7.8 |
| 50 | 50 | 12 | 12 | 24.1 | 100 | 7.2 |
| 50 | 70 | 12 | 17 | 30.2 | 125 | 7.6 |

As shown in Table 38, by making a film thickness of an electron transporting layer of an intermediate unit greater than a film thickness of an electron transporting layer on a cathode side, and making a film thickness of an electron extracting layer of an intermediate unit greater than a film thickness of a hole injecting layer on an anode side, a high light emitting efficiency is obtained. In addition, it is seen that, by making a film thickness of an electron transporting layer of an intermediate unit smaller than a film thickness of an electron transporting layer on a cathode side, and making a film thickness of an electron extracting layer of an intermediate unit smaller than a film thickness of a hole injecting layer on an anode side, a light emitting efficiency is reduced.

A light emitting efficiency is higher as 30.2 cd/A as compared with the case where a film thickness of an electron transporting layer of an intermediate unit is 17 nm in Table 28 (light emitting efficiency 29.5 cd/A), and the case where a film thickness of a hole injecting layer of an intermediate unit is 70 nm in Table 34 (26.5 cd/A). From the forgoing, it is seen that, by making both film thicknesses of an electron transporting layer and a hole injecting layer greater in an intermediate unit in accordance with a seventh aspect of the present invention, a light emitting efficiency can be further enhanced.

Example in accordance with an eighth aspect of the present invention will be explained below.

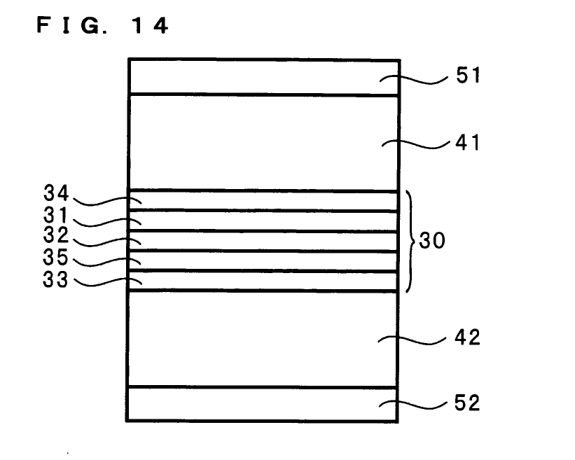

FIG. 14 is a schematic cross-sectional view showing an organic EL element in accordance with an eighth aspect of the present invention. As shown in FIG. 14, between a cathode 51 and an anode 52, a first light emitting unit 41 and a second light emitting unit 42 are provided. Between a first light emitting unit 41 and a second light emitting unit 42, an intermediate unit 30 is provided. A first light emitting unit 41 is provided on a cathode 51 side relative to an intermediate unit 30, and a second light emitting unit 42 is provided on an anode 52 side relative to an intermediate unit 30.

In an intermediate unit 30, an electron extracting layer 31 and an electron transporting layer 33 are provided.

In accordance with an eighth-1 aspect of the present invention, an electron extracting layer 31 is doped with an electron extraction promoting material. A content of an electron extraction promoting material in an electron extracting layer 31 is preferably in a range of 0.1 to 50% by weight, further preferably 1 to 45% by weight.

In accordance with an eighth-2 aspect of the present invention, an electron extraction promoting layer 34 is provided between an electron extracting layer 31 and a first light emitting unit 41. A thickness of an electron extraction promoting layer 34 is preferably in a range of 0.1 to 100 nm, further preferably in a range of 0.5 to 50 nm.

In accordance with an eighth-3 aspect of the present invention, an electron transporting layer 33 and/or an electron extracting layer 31 are doped with an electron injecting organic material. A content of an electron injecting organic material is preferably in a range of 0.1 to 50% by weight, further preferably in a range of 1 to 45% by weight.

In accordance with an eighth-aspect of the present invention, between an electron extracting layer 31 and an electron transporting layer 33, an electron injecting organic material layer 35 comprising an electron injecting organic material is provided. A thickness of an electron injecting organic material layer is preferably in a range of 0.1 to 100 nm, further preferably in a range of 0.5 to 50 nm.

In an eighth-aspect of the invention, when an electron injecting layer 31 is provided, it is provided between an electron extracting layer 31 and an electron transporting layer 33 and, when an electron injecting organic material layer 35 is present, it is provided between an electron extracting layer 31 and an electron injecting organic material layer 35. A thickness of an electron injecting layer 32 is preferably in a range of 0.1 to 100 nm, further preferably in a range of 0.2 to 50 nm. Since a thickness of an electron injecting layer 32 is very small, the layer may be formed in the state where it is diffused on a surface of an adjoining electron injecting organic material layer 35 and electron transporting layer 33 and is doped therein.

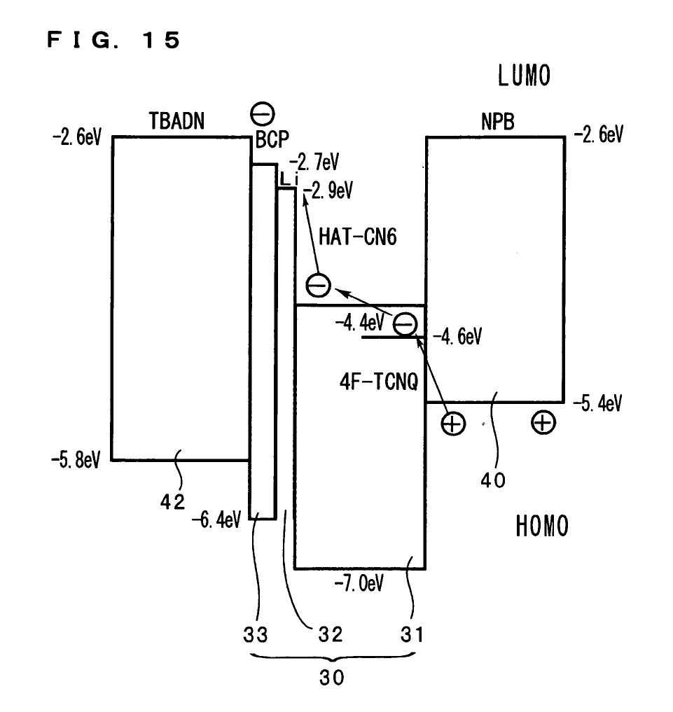

FIG. 15 is a view showing energy diagram around intermediate unit of one embodiment in accordance with an eighth-1 aspect of the present invention. An intermediate unit 30 is constructed of an electron extracting layer 31, an electron injecting layer 32 and an electron transporting layer 33. On a cathode side of an electron extracting layer 31, an adjacent layer 40 which is a light emitting layer on an intermediate unit 30 side of a first light emitting unit 41 is provided. In addition, on an anode side of an intermediate unit 30, a second light emitting unit 42 is provided. In FIG. 2, only a light emitting layer on an intermediate unit 30 of a second light emitting unit 42 is shown.

In Example showing in FIG. 15, an electron extracting layer 31 is formed of HAT-CN6.

An electron injecting layer 32 is formed of Li (metal lithium).

An electron transporting layer 33 is formed of BCP.

An adjacent layer (light emitting layer) 40 contains NBP as a host material.

A light emitting layer indicated as a second light emitting unit 42 contains TBADN as a host material.

In Example shown in FIG. 15, an electron extracting layer 31 is doped with 4F-TCNQ
(2,3,5,6-tetrafluoro-7,7,8,8-tetracyano-quinodimethane). That is, 4F-TCNQ is doped as an electron extraction promoting material. 4F-TCNQ has the following structure.

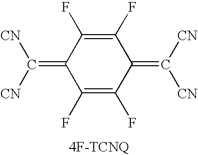

OHBBDT
(4,5,6,7,4′,5′,6′,7′-octahydro-[2,2′]bi[benzo[1,3]dithiolidene]) used as an electron extraction promoting material in Example described later has the following structure.

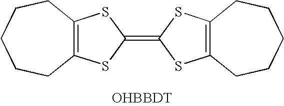

In addition, TPBT
(2,2,2′,2′-tetraphenyl-bi-thiapyran-4,4′-diylidene) used as an electron extraction promoting material in Example described later has the following structure.

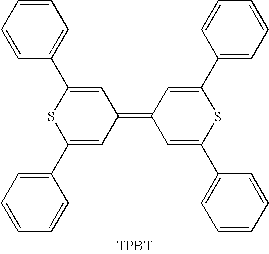

In addition, DTN
(2,3-diphenyl-1,4,6,11-tetraaza-naphthacene) used as an electron injecting organic material in Example described later has the following structure.

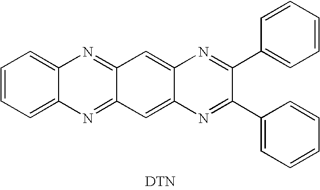

As shown in FIG. 15, a difference between an absolute value (4.4 eV) of a LUMO energy level of an electron extracting layer 31 and an absolute value (5.4 eV) of a HOMO energy level of an adjacent layer 40 is within 2.0 eV and, in the case of FIG. 15, the difference is 1.0 eV. When this value is 2.0 eV, an electron extracting layer 31 can extract an electron from an adjacent layer 40 upon application of a voltage to an anode and a cathode. Further, as this value is smaller, the electron extracting effect is larger. For example, when this value is 1.5 eV, the electron extracting effect is greater than the effect when this value is 2.0 eV and, further, 1.0 eV or smaller as in FIG. 15 is most preferable. An electron extracting layer 31 is doped with 4F-TCNQ, and an absolute value of an energy level of LUMO of this 4F-TCNQ is 4.6 eV. Therefore, by doping a layer with an electron extraction promoting material, extraction of an electron from an adjacent layer 40 becomes easy, and an electron can be extracted effectively. The extracted electron is supplied to a second light emitting unit 42 through an electron injecting layer 32 and an electron transporting layer 33.

In an adjacent layer 40, since an electron is extracted, a hole is generated. This hole is recombined with an electron supplied from a cathode, in a first light emitting unit. As a result, light is emitted in a first light emitting unit.

An electron supplied to a second light emitting unit is recombined with a hole supplied from an anode, in a second light emitting unit 42. As a result, light is emitted in a second light emitting unit 42.

As described above, a recombination region can be formed in a first light emitting unit and a second light emitting unit, respectively, and light can be emitted. Therefore, a light emitting efficiency can be enhanced and, at the same time, light can be emitted at an emitting color of a first light emitting unit and a second light emitting unit.

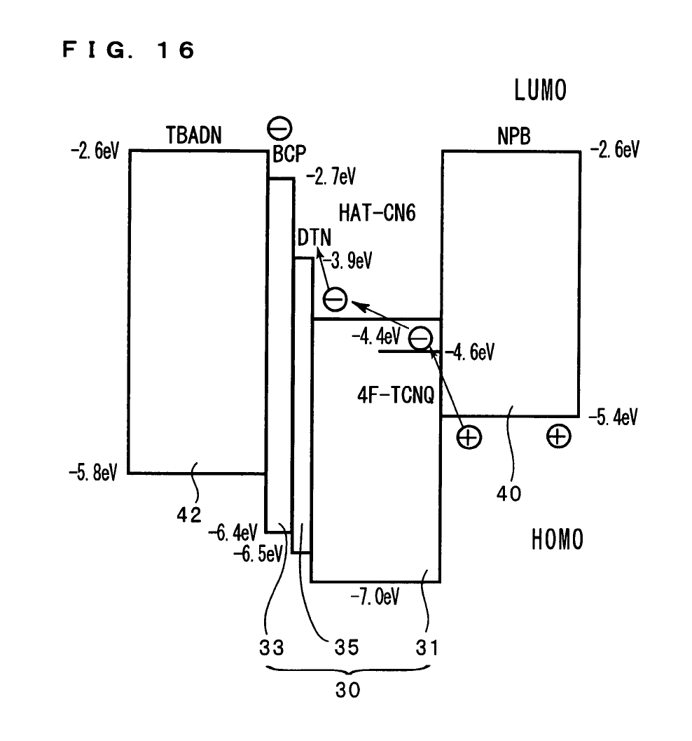

FIG. 16 is a view showing energy diagram around intermediate unit in accordance with an eighth-1 aspect and an eighth-4 aspect of the present invention. In Example shown in FIG. 16, between an electron extracting layer 31 and an electron transporting layer 33, an electron injecting organic material layer 35 comprising DTN is provided.

An electron extracting layer 31 is doped with 4F-TCNQ as an electron extraction promoting material as in Example shown in FIG. 15. Therefore, an electron can be easily extracted from an adjacent layer 40. An electron extracted by an electron extracting layer 31 is supplied to an electron transporting layer 33 and, between an electron extracting layer 31 and an electron transporting layer 33, an electron injecting organic material layer 35 is provided, and since its LUMO energy level is a value between that of an electron extracting layer 31 and that of an electron transporting layer 33, an electron can be effectively injected into an electron transporting layer 33.

In Example shown in FIG. 16, an electron injecting organic material layer 35 comprising an electron injecting organic material is provided between an electron extracting layer 31 and an electron transporting layer 33, but in accordance with an eighth-aspect of the present invention, when an electron injecting organic material comprising DTN is doped into an electron extracting layer 31 and/or an electron transporting layer 33, the similar effect can be also obtained.

In respective Examples shown in FIG. 15 and FIG. 16, 4F-TCNQ which is an electron extraction promoting material is doped into an electron extracting layer 31, but also when an electron extraction promoting layer 34 comprising 4F-TCNQ is provided between an adjacent layer 40 and an electron extracting layer 31, the similar effect can be obtained.

### EXPERIMENT 19

### Examples 39 to 53 and Comparative Examples 10 to 12

Organic EL elements of Examples 39 to 53 and Comparative Examples 10 to 12 having an anode, a hole injective layer, a second light emitting unit, an intermediate unit, a first light emitting unit, an electron transporting layer, and a cathode shown in Table 39 were manufactured.

An anode was manufactured by forming a fluorocarbon (CFₓ) layer on a glass substrate on which an ITO (indium tin oxide) film had been formed. A fluorocarbon layer was formed by plasma polymerization of a CHF₃ gas. A thickness of a fluorocarbon layer was 1 nm.

On the anode manufactured as described above, a hole injecting layer, a second light emitting unit, an intermediate unit, a first light emitting unit, an electron transporting layer, and a cathode were formed by successively depositing them by a deposition method.

A first light emitting unit and a second light emitting unit are formed by laminating an orange emitting layer (NPB+10% tBuDPN+3.0% DBzR) and a blue emitting layer (TBADN+20% NPB+2.5% TBP). In any light emitting unit, an orange emitting layer is situated on an anode side, and a blue emitting layer is situated on a cathode side. And, % is % by weight unless otherwise is indicated.

In an orange emitting layer, NPB and tBuDPN are used as a host material, and DBzR is used as a dopant material.

In a blue emitting layer, TBADN and NPB are used as a host material, and TBP is used as a dopant material.

Respective organic EL elements manufactured were measured for a light emitting efficiency, and measurement results together with a driving voltage are shown in Table 39. A light emitting efficiency is a value at 10 mA/cm².

TABLE 39

| | | | Second Light Emitting Unit | | |
|---|---|---|---|---|---|
| | | Hole | Orange | Blue | |
| | | Injecting | Emitting | Emitting | |
| | Anode | Layer | Layer | Layer | Intermediate Unit |
| Ex. | ITO/ | HAT-CN6 | NPB + 10% tBuDPN + 3.0% | TBADN + 20% NPB + 2.5% | BCP/Li₂O/HAT-CN6 + 25% 4F-TCNQ |
| 39 | CFx | (50) | DBzR(30) | TBP(40) | (10)/(0.2)/(50) |
| Ex. | ITO/ | HAT-CN6 | NPB + 10% tBuDPN + 3.0% | TBADN + 20% NPB + 2.5% | BCP/Li₂O/HAT-CN6 + 20% OHBBDT |
| 40 | CFx | (50) | DBzR(30) | TBP(40) | (10)/(0.2)/(50) |
| Ex. | ITO/ | HAT-CN6 | NPB + 10% tBuDPN + 3.0% | TBADN + 20% NPB + 2.5% | BCP/Li₂O/HAT-CN6 + 25% TPBT |
| 41 | CFx | (50) | DBzR(30) | TBP(40) | (10)/(0.2)/(50) |
| Ex. | ITO/ | HAT-CN6 | NPB + 10% tBuDPN + 3.0% | TBADN + 20% NPB + 2.5% | BCP/Li₂O/HAT-CN6/TPBT |
| 42 | CFx | (50) | DBzR(30) | TBP(40) | (10)/(0.2)/(47)/(3) |
| Ex. | ITO/ | HAT-CN6 | NPB + 10% tBuDPN + 3.0% | TBADN + 20% NPB + 2.5% | BCP/DTN/Li₂O/HAT-CN6 |
| 43 | CFx | (50) | DBzR(30) | TBP(40) | (10)/(3)/(0.2)/(50) |
| Ex. | ITO/ | HAT-CN6 | NPB + 10% tBuDPN + 3.0% | TBADN + 20% NPB + 2.5% | BCP/BCP + 50% DTN/Li₂O/HAT-CN6 |
| 44 | CFx | (50) | DBzR(30) | TBP(40) | (10)/(3)/(0.2)/(50) |
| Ex. | ITO/ | HAT-CN6 | NPB + 10% tBuDPN + 3.0% | TBADN + 20% NPB + 2.5% | BCP/DTN/Li₂O/HAT-CN6 + 25% 4F-TCNQ |
| 45 | CFx | (50) | DBzR(30) | TBP(40) | (10)/(3)/(0.2)/(50) |
| Ex. | ITO/ | HAT-CN6/NPB | NPB + 10% tBuDPN + 3.0% | TBADN + 20% NPB + 2.5% | BCP/DTN/Li₂O/HAT-CN6 + 25% |
| 46 | CFx | (50)/(30) | DBzR(30) | TBP(40) | 4F-TCNQ/NPB (10)/(3)/(0.2)/(50)/(30) |
| Ex. | ITO/ | HAT-CN6 | NPB + 10% tBuDPN + 3.0% | TBADN + 20% NPB + 2.5% | BCP/50% DTN + 50% HAT-CN6/HAT-CN6 |
| 47 | CFx | (50) | DBzR(30) | TBP(40) | (10)/(3)/(50) |
| Ex. | ITO/ | HAT-CN6/NPB | NPB + 10% tBuDPN + 3.0% | TBADN + 20% NPB + 2.5% | BCP/DTN/Li/HAT-CN6 + 25% 4F-TCNQ-NPB |
| 48 | CFx | (50)/(30) | DBzR(30) | TBP(40) | (10)/(3)/(0.2)/(50)/(30) |
| Ex. | ITO/ | HAT-CN6/NPB | NPB + 10% tBuDPN + 3.0% | TBADN + 20% NPB + 2.5% | BCP/DTN/Cs/HAT-CN6 + 25% 4F-TCNQ-NPB |
| 49 | CFx | (50)/(30) | DBzR(30) | TBP(40) | (10)/(3)/(0.2)/(50)/(30) |
| Ex. | ITO/ | HAT-CN6 | NPB + 10% tBuDPN + 3.0% | TBADN + 20% NPB + 2.5% | BCP/Li/HAT-CN6 + 25% 4F-TCNQ |
| 50 | CFx | (50) | DBzR(30) | TBP(40) | (10)/(0.2)/(50) |
| Ex. | ITO/ | HAT-CN6 | NPB + 10% tBuDPN + 3.0% | TBADN + 20% NPB + 2.5% | BCP/50% Mg + 50% HAT-CN6/HAT-CN6 |
| 51 | CFx | (50) | DBzR(30) | TBP(40) | (15)/(3)/(25) |
| Ex. | ITO/ | HAT-CN6 | NPB + 10% tBuDPN + 3.0% | TBADN + 20% NPB + 2.5% | BCP/50% Mg + 50% DTN/HAT-CN6 |
| 52 | CFx | (50) | DBzR(30) | TBP(40) | (15)/(3)/(25) |
| Ex. | ITO/ | HAT-CN6 | NPB + 10% tBuDPN + 3.0% | TBADN + 20% NPB + 2.5% | BCP/50% Mg + 50% DTN/50% Mg + 50% |
| 53 | CFx | (50) | DBzR(30) | TBP(40) | HAT-CN6/HAT-CN6 (15)/(3)/(3)/(25) |
| Comp. | ITO/ | HAT-CN6 | NPB + 10% tBuDPN + 3.0% | TBADN + 20% NPB + 2.5% | BCP/HAT-CN6 |
| Ex. 10 | CFx | (50) | DBzR(30) | TBP(40) | (10)/(50) |
| Comp. | ITO/ | HAT-CN6 | NPB + 10% tBuDPN + 3.0% | TBADN + 20% NPB + 2.5% | BCP/Li₂O/HAT-CN6 |
| Ex. 11 | CFx | (50) | DBzR(30) | TBP(40) | (10)/(0.2)/(50) |
| Comp. | ITO/ | HAT-CN6 | NPB + 10% tBuDPN + 3.0% | TBADN + 20% NPB + 2.5% | None |
| Ex. 12 | CFx | (50) | DBzR(30) | TBP(40) | |

| | First light emitting unit | | | | | |
|---|---|---|---|---|---|---|
| | Orange | Blue Light | | | | |
| | Emitting | Emitting | | | Driving | Light Emit- |
| | Layer | Layer | Electron Transporting Layer | Cathode | Voltage | ting Efficiency (cd/A) |
| Ex. | NPB + 10% tBuDPN + 3.0% | TBADN + 20% NPB + 2.5% | BCP | LiF/Al | 7.2 | 32.0 |
| 39 | DBzR(30) | TBP(40) | (10) | (10)/(2000) | | |
| Ex. | NPB + 10% tBuDPN + 3.0% | TBADN + 20% NPB + 2.5% | BCP | LiF/Al | 7.3 | 28.8 |
| 40 | DBzR(30) | TBP(40) | (10) | (10)/(2000) | | |
| Ex. | NPB + 10% tBuDPN + 3.0% | TBADN + 20% NPB + 2.5% | BCP | LiF/Al | 7.2 | 29.8 |
| 41 | DBzR(30) | TBP(40) | (10) | (10)/(2000) | | |
| Ex. | NPB + 10% tBuDPN + 3.0% | TBADN + 20% NPB + 2.5% | BCP | LiF/Al | 8.5 | 29.7 |
| 42 | DBzR(30) | TBP(40) | (10) | (10)/(2000) | | |
| Ex. | NPB + 10% tBuDPN + 3.0% | TBADN + 20% NPB + 2.5% | BCP | LiF/Al | 7.1 | 33.1 |
| 43 | DBzR(30) | TBP(40) | (10) | (10)/(2000) | | |
| Ex. | NPB + 10% tBuDPN + 3.0% | TBADN + 20% NPB + 2.5% | BCP | LiF/Al | 7.3 | 24.5 |
| 44 | DBzR(30) | TBP(40) | (10) | (10)/(2000) | | |
| Ex. | NPB + 10% tBuDPN + 3.0% | TBADN + 20% NPB + 2.5% | BCP | LiF/Al | 6.8 | 34.5 |
| 45 | DBzR(30) | TBP(40) | (10) | (10)/(2000) | | |
| Ex. | NPB + 10% tBuDPN + 3.0% | TBADN + 20% NPB + 2.5% | BCP | LiF/Al | 7.4 | 33.5 |
| 46 | DBzR(30) | TBP(40) | (10) | (10)/(2000) | | |
| Ex. | NPB + 10% tBuDPN + 3.0% | TBADN + 20% NPB + 2.5% | BCP | LiF/Al | 11.0 | 27.0 |
| 47 | DBzR(30) | TBP(40) | (10) | (10)/(2000) | | |
| Ex. | NPB + 10% tBuDPN + 3.0% | TBADN + 20% NPB + 2.5% | BCP | LiF/Al | 7.3 | 32.5 |
| 48 | DBzR(30) | TBP(40) | (10) | (10)/(2000) | | |
| Ex. | NPB + 10% tBuDPN + 3.0% | TBADN + 20% NPB + 2.5% | BCP | LiF/Al | 7.3 | 32.6 |
| 49 | DBzR(30) | TBP(40) | (10) | (10)/(2000) | | |
| Ex. | NPB + 10% tBuDPN + 3.0% | TBADN + 20% NPB + 2.5% | BCP | LiF/Al | 7.2 | 31.8 |
| 50 | DBzR(30) | TBP(40) | (10) | (10)/(2000) | | |
| Ex. | NPB + 10% tBuDPN + 3.0% | TBADN + 20% NPB + 2.5% | BCP | LiF/Al | 7.3 | 29.7 |
| 51 | DBzR(30) | TBP(40) | (10) | (10)/(2000) | | |
| Ex. | NPB + 10% tBuDPN + 3.0% | TBADN + 20% NPB + 2.5% | BCP | LiF/Al | 7.2 | 31.3 |
| 52 | DBzR(30) | TBP(40) | (10) | (10)/(2000) | | |
| Ex. | NPB + 10% tBuDPN + 3.0% | TBADN + 20% NPB + 2.5% | BCP | LiF/Al | 7.3 | 33.8 |
| 53 | DBzR(30) | TBP(40) | (10) | (10)/(2000) | | |
| Comp. | NPB + 10% tBuDPN + 3.0% | TBADN + 20% NPB + 2.5% | BCP | LiF/Al | 14.2 | 11.5 |
| Ex. 10 | DBzR(30) | TBP(40) | (10) | (10)/(2000) | | |
| Comp. | NPB + 10% tBuDPN + 3.0% | TBADN + 20% NPB + 2.5% | BCP | LiF/Al | 7.4 | 24.0 |
| Ex. 11 | DBzR(30) | TBP(40) | (10) | (10)/(2000) | | |
| Comp. | NPB + 10% tBuDPN + 3.0% | TBADN + 20% NPB + 2.5% | BCP | LiF/Al | 6.0 | 12.1 |
| Ex. 12 | DBzR(30) | TBP(40) | (10) | (10)/(2000) | | |

As shown in Table 39, in Example 39, 4F-TCNQ as an electron extraction promoting material is doped into an electron transporting layer. In Example 40, OHBBDT as an electron extraction promoting material is doped into an electron extracting layer. In Example 41, TPBT as an electron extraction promoting material is doped into an electron extracting layer.

In Example 42, an electron extraction promoting layer comprising TPBT is provided between an electron transporting layer, and an orange emitting layer of a first light emitting unit which is an adjacent layer.

In Example 43, an electron injecting organic material layer comprising DTN which is an electron injecting organic material is provided between an electron transporting layer comprising BCP, and an electron injecting layer comprising Li₂O.

In Example 44, between an electron transporting layer comprising BCP, and an electron injecting layer comprising Li₂O, a layer of BCP doped with 50% DTN is provided. Therefore, a surface of an electron transporting layer is doped with an electron injecting organic material comprising DTN.

In Example 45, between an electron transporting layer comprising BCP, and an electron injecting layer comprising Li₂O, an electron injecting organic material layer comprising DTN is provided. In addition, an electron extracting layer is doped with an electron extraction promoting material comprising 4F-TCNQ.

In Example 46, between an electron transporting layer comprising BCP and an electron injecting layer comprising Li₂O, an electron injecting organic material layer comprising DTN is provided. In addition, an electron extracting layer is doped with 4F-TCNQ and, as an adjacent layer, a layer comprising NPB is provided in an intermediate unit.

In Example 47, between an electron extracting layer and an electron transporting layer comprising BCP, a layer comprising HAT-CN6doped with 50% DTN is provided. Therefore, a surface of an electron extracting layer is doped with an electron injecting organic material comprising DTN.

In Example 48, between an electron transporting layer comprising BCP, and an electron injecting layer comprising Li, an electron injecting organic material layer comprising DTN is provided. An electron extracting layer is doped with 4F-TCNQ and, in an intermediate unit, an adjacent layer comprising NPB is provided.

In Example 49, between an electron transporting layer comprising BCP, and an electron injecting layer comprising Cs, an electron injecting organic material layer comprising DTN is provided. In addition, an electron extracting layer is doped with an electron extraction promoting material comprising 4F-TCNQ. In addition, in an intermediate unit, an adjacent layer comprising NPB is provided.

In Example 50, an electron extracting layer is doped with an electron extraction promoting material comprising 4F-TCNQ.

In Example 51, an electron injecting layer comprising Mg is 50% doped with HAT-CN6 as a material for an electron extracting layer. A work function of Mg is −3.7 eV.

In Example 52, an electron injecting layer comprising Mg is 50% doped with DTN as an electron injecting organic material.

In Example 53, a first electron injecting layer comprising Mg doped with 50% HAT-CN6, and a second electron injecting layer comprising Mg doped with 50% DTN are provided. A first electron injecting layer is arranged on a cathode side, and a second electron injecting layer is arranged on an anode side.

In Comparative Example 10, in an intermediate unit, only an electron extracting layer and an electron transporting layer are provided.

In Comparative Example 11, only an electron extracting layer, an electron injecting layer, and an electron transporting layer are provided.

In Comparative Example 12, an intermediate unit is not provided.

As apparent from results shown in Table 39, Examples 39 to 41 in accordance with an eighth-1 aspect of the present invention exhibit a better light emitting efficiency as compared with Comparative Examples 10 to 12.

Example 42 in accordance with an eighth-2 aspect of the present invention exhibits a better light emitting efficiency as compared with Comparative Examples 10 to 12.

Example 43 in accordance with an eithth-4 aspect of the present invention exhibits a better light emitting efficiency as compared with Comparative Examples 10 to 12.

Example 44 in accordance with an eighth-3 aspect of the present invention exhibits a better light emitting efficiency as compared with Comparative Examples 10 to 12.

Examples 45 and 46 in accordance with an eighth-1 aspect and an eighth-4 aspect of the present invention exhibit a better light emitting efficiency as compared with Comparative Examples 10 to 12.

Example 47 in accordance with an eighth-3 aspect of the present invention exhibits a better light emitting efficiency as compared with Comparative Examples 10 to 12.

Examples 48 and 49 in accordance with an eighth-1 aspect and an eighth-4 aspect of the present invention exhibit a better light emitting efficiency as compared with Comparative Examples 10 to 12.

Example 50 in accordance with an eighth-1 aspect of the present invention exhibits a better light emitting efficiency as compared with Comparative Examples 10 to 12.

Examples 51 to 53 in accordance with an eighth-5 aspect of the present invention exhibit a better light emitting efficiency as compared with Comparative Examples 10 to 12.

Table 40 shows absolute values of HOMO energy levels and absolute values of LUMO energy levels of 4F-TCNQ, OHBBDT, TPBT, DTN, HAT-CN6, NPB, and BCP.

TABLE 40

| | HOMO (eV) | LUMO (eV) |
|---|---|---|
| 4F-TCNQ | — | 4.6 |
| OHBBDT | — | 5.0 |
| TPBT | — | 4.9 |
| DTN | 6.5 | 3.9 |
| HAT-CN6 | 7.0 | 4.4 |
| NPB | 5.4 | 2.6 |
| BCP | 6.4 | 2.7 |

As shown in Table 40, in an eighth aspect of the present invention, absolute values of energy levels of LUMO of 4F-TCNQ, OHBBDT, and TPBT used as an electron extraction promoting material are higher than an absolute value of an energy level of LUMO of HAT-CN6 of an electron extracting layer, and lower than an absolute value of an energy level of HOMO of NBP which is a host material for an adjacent layer.

In addition, in an eighth aspect of the present invention, an energy level of LUMO of DTN used as an electron injecting organic material is smaller than an absolute value of an energy level of LUMO of HAT-CN6 of an electron extracting layer, and is larger than an absolute value of an energy level of LUMO of BCP of an electron transporting layer.

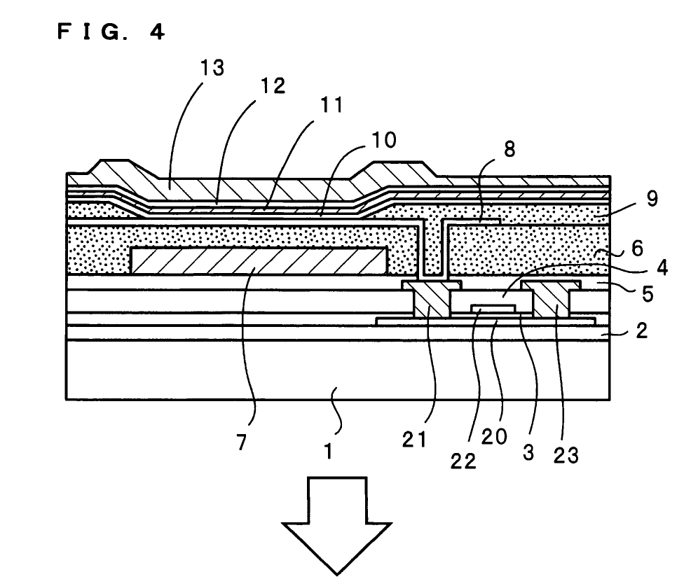

FIG. 4 is a cross-sectional view showing an example of a bottom emission-type of organic EL display device in accordance with the present invention. In this organic EL display device, light emission in each pixel is driven using TFT as an active element. Alternatively, as an active element, a diode may be used. In addition, in this organic EL display device, a color filter is provided. This organic EL display device is a bottom emission-type display device performing display by irradiating light below a substrate 1 as shown by an arrow.

Referring to FIG. 4, a first insulating layer 2 is provided on a substrate 1 comprising a transparent substrate such as a glass. A first insulating layer 2 is formed, for example, of SiO₂ or SiNₓ. On a first insulating layer 2, a channel region 20 comprising a polysilicon layer is formed. On a channel region 20, a drain electrode 21 and a source electrode 23 are formed and, between a drain electrode 21 and a source electrode 23, a gate electrode 22 is provided via a second insulating layer 3. On a gate electrode 22, a fourth insulating layer 4 is provided. A second insulating layer 3 is formed, for example, of SiNₓ and SiO₂, and a third insulating layer 4 is formed of SiO₂ and SiNₓ.

On a third insulating layer 4, a fourth insulating layer 5 is formed. A fourth insulating layer 5 is formed, for example, of SiNₓ. A color filter layer 7 is provided at a part of a pixel region on a fourth insulating layer 5. As a color filter layer 7, color filters of R (red), G (green) and B (blue) are provided. On a color filter layer 7, a first flattening film 6 is provided. A throughhole part is formed in a first flattening film 6 above a drain electrode 21, and a hole injecting electrode 8 comprising ITO (indium-tin oxide) formed on a first flattening film 6 is introduced into a throughhole part. On a hole injecting electrode (anode) 8 in a pixel region, a hole injecting layer 10 is formed. On a part other than a pixel region, a second flattening film 9 is formed.

On a hole injecting layer 10, a light emitting element layer 11 laminated in accordance with the present invention is provided. A light emitting element layer 11 has a structure in accordance with the present invention in which a first light emitting unit is laminated on a second light emitting unit via an intermediate unit. On a light emitting element layer 11, an electron transporting layer 12 is provided and, on an electron transporting layer 12, an electron injecting electrode (cathode) 13 is provided.

As described above, in the organic EL element in the present Example, an organic EL element is constructed by laminating a hole injecting electrode (anode) 8, a hole injecting layer 10, a light emitting element layer 11 having a structure in accordance with the present invention, an electron transporting layer 12, and an electron injecting electrode (cathode) 13 on a pixel region.

In the light emitting element layer 11 in the present Example, since a light emitting unit in which an orange emitting layer and a blue emitting layer are laminated is used, white light is emitted from a light emitting element layer 11. This white emitted light is radiated to the outside through a substrate 1, and since a color filter layer 7 is provided on an emitting side, a color of R, G or B is radiated depending on a color of a color filter layer 7. In the case of a monochromatic light emitting element, no color filter layer may be provided.

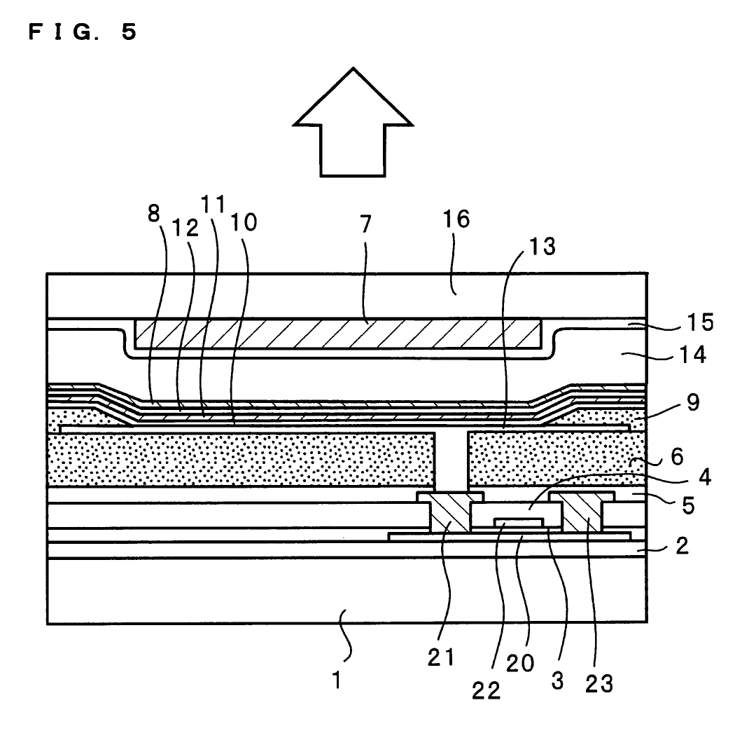

FIG. 5 is a cross-sectional view showing an example of a top emission-type organic EL display device in accordance with the present invention. The organic EL display device of the present Example is an organic EL display device performing display by radiating light above a substrate 1 as shown by an arrow.

A part of from a substrate 1 to an anode 3 is manufactured approximately as in the Example shown in FIG. 4, provided that a color filter layer 7 is provided not on a fourth insulating layer 5, but above an organic EL element. Specifically, the color filter layer 7 is attached by attaching a color filter layer 7 on a transparent sealing substrate 10 comprising a glass, coating an overcoating layer 5 thereon, and applying this on an anode 8 via a transparent adhesive layer 14. In addition, in the present Example, positions of an anode and a cathode are reverse relative to Example shown in FIG. 4.

As an anode 8, a transparent electrode is formed, for example, by laminating ITO having a film thickness of around 100 nm and silver having a film thickness of around 20 nm. As a cathode 13, a reflection electrode is formed and, for example, a thin film of aluminum, chromium or silver having a film thickness of around 100 nm is formed. An overcoating layer 15 is formed of an acryl resin at a thickness of about 1 μm. A color filter layer 7 may be of a pigment type, or of a dye type. A thickness thereof is around 1 μm.

White light emitted from a light emitting element layer 11 is radiated to the outside through a sealing substrate 16, and a color filter layer 7 is provided on a light emitting side, a color of R, G or B is radiated depending on a color of a color filter layer 7. Since the organic EL display device of the present Example is a top emission-type, a region in which a thin film transistor is provided, can be also used as a pixel region, and a color filter layer 7 is provided in a wider range than Example shown in FIG. 4. A light emitting element layer 11 is formed of an organic EL element in accordance with the present invention, and is a light emitting layer having a high light emitting efficiency and, according to the present Example, since a wider region can be used as a pixel region, an advantage of a light emitting element layer having a high light emitting efficiency can be sufficiently utilized. In addition, since formation of a light emitting element layer having a plurality of light emitting units can be performed without considering influence by an active matrix, a freedom degree of design can be enhanced.

In the above Example, a glass plate is used as a sealing substrate, but in the present invention, a sealing substrate is not limited to a glass plate, but a film such as an oxidized film of SiO₂ and a nitrided film such as SiNₓ may be also used as a sealing substrate. In this case, since a film-like sealing substrate can be formed directly on an element, it becomes unnecessary to provide a transparent adhesive layer.

Alternatively, even in the case of a top emission-type display device, as a structure of an element, a hole injecting electrode may be formed on a first flattening film 6, and a hole injecting layer 10, a second light emitting unit, an intermediate unit, a first light emitting unit, an electron transporting layer 12, and an electron injecting electrode 13 may be formed on the hole injecting electrode in this order as in a bottom emission-type. In this case, a hole injecting electrode (anode) takes a structure of a metal film having light reflecting property, or a laminated structure of ITO and a metal film, and an electron injecting electrode (cathode) takes a structure of a metal film which is very thin and has light permeability, or a laminated structure of such the metal film and an ITO-based permeable electrically conductive layer. Thereby, light can be taken out on a cathode side.

In the aforementioned respective Examples, an organic EL element in which two light emitting units (first light emitting unit and second light emitting unit) are arranged between an anode and a cathode is exemplified, but the number of light emitting units in the present invention is not limited to 2, but 3 or more light emitting units may be provided, and an intermediate unit may be provided between respective light emitting units.

1. An organic electroluminescent element comprising a cathode, an anode, an intermediate unit arranged between said cathode and said anode, a first light emitting unit arranged between said cathode and said intermediate unit, and a second light emitting unit arranged between said anode and said intermediate unit,
wherein an electron extracting layer for extracting an electron from an adjacent layer adjoining a cathode side is provided in said intermediate unit, an absolute value of an energy level of a lowest unoccupied molecular orbital (LUMO) of said electron extracting layer |LUMO(A)|, and an absolute value of an energy level of a highest occupied molecular orbital (HOMO) of said adjacent layer |HOMO(B)| are in the relationship of |HOMO(B)|−|LUMO(A)|≦1.5 eV,
and said intermediate unit supplies a hole generated by extraction of an electron from said adjacent layer by said electron extracting layer to said first light emitting unit and, at the same time, supplies the extracted electron to said second light emitting unit.

2. The organic electroluminescent device according to claim 1, wherein said second light emitting unit is a light emitting unit which emits substantially the same color as that of said first light emitting unit.

3. The organic electroluminescent device according to claim 1, wherein said first light emitting unit and said second light emitting unit have a structure in which two light emitting layers are laminated so that they are directly contacted.

4. The organic electroluminescent device according to claim 1, wherein said adjacent layer is provided in said first light emitting unit.

5. The organic electroluminescent element according to claim 1, wherein said adjacent layer is provided in said intermediate unit.

6. The organic electroluminescent element according to claim 1, wherein the adjacent layer is formed of a hole transporting material.

7. The organic electroluminescent element according to claim 1, wherein said adjacent layer is formed of an arylamine-based hole transporting material.

8. The organic electroluminescent device according to claim 1, wherein said electron extracting layer is formed of a pyrazine derivative represented by the following structural formula: 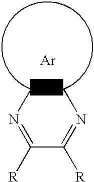
(wherein Ar represents an aryl group, and R represents hydrogen, an alkyl group having a carbon number of 1 to 10, an alkyloxy group having a carbon number of 1 to 10, a dialkylamine group having a carbon number of 1 to 10, F, Cl, Br, I or CN).

9. The organic electroluminescent device according to claim 1, wherein said electron extracting layer is formed of a hexaazatriphenylene derivative represented by the following structural formula: 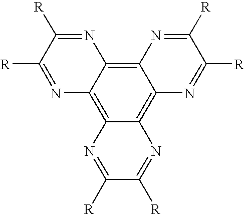
(wherein R represents hydrogen, an alkyl group having a carbon number of 1 to 10, an alkyloxy group having a carbon number of 1 to 10, a dialkylamine group having a carbon number of 1 to 10, F, Cl, Br, I or CN).

10. The organic electroluminescent element according to claim 1, wherein an electron injecting layer is provided between said electron extracting layer and said second light emitting unit.

11. The organic electroluminescent element according to claim 10, wherein said electron injecting layer is formed of a metal lithium, and a thickness thereof is in a range of 0.3 to 0.9 nm.

12. The organic electroluminescent element according to claim 10, wherein an electron transporting layer is provided between said electron injecting layer and said second light emitting unit.

13. A bottom emission-type organic electroluminescent display device comprising; an organic electroluminescent element having an element structure sandwiched between an anode and a cathode; and an active matrix driving substrate having each active element for supplying a display signal for each display pixel to said organic electroluminescent element; wherein said organic electroluminescent element is provided on said active matrix driving substrate and, among said cathode and said anode, an electrode provided on said substrate side is a transparent electrode,
said organic electroluminescent display device characterized in that:
said organic electroluminescent element comprises said cathode, said anode, an intermediate unit arranged between said cathode and said anode, a first light emitting unit arranged between said cathode and said intermediate unit, and a second light emitting unit arranged between said anode and said intermediate unit,
an electron extracting layer for extracting an electron from an adjacent layer adjoining a cathode side is provided in said intermediate unit, an absolute value of an energy level of a lowest unoccupied molecular orbital (LUMO) of said electron extracting layer |LUMO(A)|, and an absolute value of an energy level of a highest occupied molecular orbital (HOMO) of said adjacent layer |HOMO(B)| are in the relationship of |HOMO(B)|−|LUMO(A)|≦1.5 eV, and
said intermediate unit supplies a hole generated by extraction of an electron from said adjacent layer by said electron extracting layer and, at the same time, supplies the extracted electron to said second light emitting unit.

14. The organic electroluminescent display device according to claim 13, wherein said organic electroluminescent element is a white emitting element, and a color filter is arranged between said organic electroluminescent element and said substrate.

15. A top emission-type organic electroluminescent display device comprising; an organic electroluminescent element having an element structure sandwiched between an anode and a cathode; an active matrix driving substrate having each active element for supplying a display signal for each display pixel to said organic electroluminescent element; and a transparent sealing substrate provided opposite to said active matrix driving substrate; wherein said organic electroluminescent element is arranged between said active matrix driving substrate and said sealing substrate and, among said cathode and said anode, an electrode provided on said sealing substrate side is a transparent electrode,
said organic electroluminescent display device characterized in that:
said organic electroluminescent element comprises said cathode, said anode, an intermediate unit arranged between said cathode and said anode, a first light emitting unit arranged between said cathode and said intermediate unit, and a second light emitting unit arranged between said anode and said intermediate unit,
an electron extracting layer for extracting an electron from an adjacent layer adjoining a cathode side is provided in said intermediate unit, an absolute value of an energy level of a lowest unoccupied molecular orbital (LUMO) of said electron extracting layer |LUMO(A)|, and an absolute value of an energy level of a highest occupied molecular orbital (HOMO) of said adjacent layer |HOMO(B)| are in the relationship of |HOMO(B)|−|LUMO(A)|≦1.5 eV, and
said intermediate unit supplies a hole generated by extraction of an electron from said adjacent layer by said electron extracting layer and, at the same time, supplies the extracted electron to said second light emitting unit.

16. The organic electroluminescent display device according to claim 15, wherein said organic electroluminescent element is a white emitting element, and a color filter is arranged between said organic electroluminescent element and said sealing substrate.

17. An organic electroluminescent element comprising a cathode, an anode, an intermediate unit arranged between said cathode and said anode, a first light emitting unit arranged between said cathode and said intermediate unit, and a second light emitting unit which is arranged between said anode and said intermediate unit, and emits a color substantially different from that of said first light emitting unit,
wherein an electron extracting layer for extracting an electron from an adjacent layer adjoining a cathode side is provided in said intermediate unit, an absolute value of an energy level of a lowest unoccupied molecular orbital (LUMO) of said electron extracting layer |LUMO(A)|, and an absolute value of an energy level of a highest occupied molecular orbital (HOMO) of said adjacent layer |HOMO(B)| are in the relationship of |HOMO(B)|−|LUMO(A)|≦1.5 eV, and said intermediate unit supplies a hole generated by extraction of an electron from said adjacent layer by said electron extracting layer to said first light emitting unit and, at the same time, supplies the extracted electron to said second light emitting unit.

18. The organic electroluminescent element according to claim 17, wherein an electron injecting layer is provided adjoining an anode side of said electron extracting layer, an absolute value of an energy level of a lowest unoccupied molecular orbital (LUMO) of said electron injecting layer |LUMO(C)| or an absolute value of a work function |WF (C)| is smaller than |LUMO(A)|, and
said intermediate unit supplies an electron extracted by said electron extracting layer to said second light emitting unit via said electron injecting layer.

19. The organic electroluminescent element according to claim 16, wherein an electron transporting layer is provided in said intermediate unit between said electron injecting layer and said second light emitting unit, an absolute value of an energy level of a lowest unoccupied molecular orbital of said electron transporting layer |LUMO(D)| is smaller than |LUMO(C)| or |WF (C)|, and
said intermediate unit supplies an electron extracted by said electron extracting layer to said second light emitting unit via said electron injecting layer and said electron transporting layer.

20. The organic electroluminescent element according to claim 17, wherein at least one of said first light emitting unit and said second light emitting unit has a structure in which two light emitting layers are laminated so that they are directly contacted.

21. A bottom emission-type organic electroluminescent display device comprising; an organic electroluminescent element having an element structure sandwiched between an anode and a cathode; and an active matrix driving substrate having each active element for supplying a display signal for each display pixel to said organic electroluminescent element; wherein said organic electroluminescent element is provided on said active matrix driving substrate and, among said cathode and said anode, an electrode provided on said substrate side is a transparent electrode,
characterized in that:
said organic electroluminescent element comprises said cathode, said anode, an intermediate unit arranged between said cathode and said anode, a first light emitting unit arranged between said cathode and said intermediate unit, and a second light emitting unit which is arranged between said anode and said intermediate unit, and emits a color substantially different from that of said first light emitting unit,
an electron extracting layer for extracting an electron from an adjacent layer adjoining a cathode side is provided in said intermediate unit, an absolute value of an energy level of a lowest unoccupied molecular orbital (LUMO) of said electron extracting layer |LUMO(A)|, and an absolute value of an energy level of a highest occupied molecular orbital (HOMO) of said adjacent layer |HOMO(B)| are in the relationship of |HOMO(B)|−|LUMO(A)|≦1.5 eV, and said intermediate unit supplies a hole generated by extraction of an electron from said adjacent layer by said electron extracting layer to said first light emitting unit and, at the same time, supplies the extracted electron to said second light emitting unit.

22. A top emission-type organic electroluminescent display device comprising; an organic electroluminescent element having an element structure sandwiched between an anode and a cathode; an active matrix driving substrate having each active element for supplying a display signal for each display pixel to said organic electroluminescent element; and a transparent sealing substrate provided opposite to said active matrix driving substrate; wherein said organic electroluminescent element is arranged between said active matrix driving substrate and said sealing substrate and, among said cathode and said anode, an electrode provided on said sealing substrate side is a transparent electrode,
characterized in that:
said organic electroluminescent element comprises said cathode, said anode, an intermediate unit arranged between said cathode and said anode, a first light emitting unit arranged between said cathode and said intermediate unit, and a second light emitting unit which is arranged between said anode and said intermediate unit, and emits a color substantially different from that of said first light emitting unit,
an electron extracting layer for extracting an electron from an adjacent layer adjoining a cathode side is provided in said intermediate unit, an absolute value of an energy level of a lowest unoccupied molecular orbital (LUMO) of said electron extracting layer |LUMO(A)|, and an absolute value of an energy level of a highest occupied molecular orbital (HOMO) of said adjacent layer |HOMO(B)| are in the relationship of |HOMO(B)|−|LUMO(A)|≦1.5 eV, and said intermediate unit supplies a hole generated by extraction of an electron from said adjacent layer by said electron extracting layer to said first light emitting unit and, at the same time, supplies the extracted electron to said second light emitting unit.

23. An organic electroluminescent element comprising a cathode, an anode, an intermediate unit arranged between said cathode and said anode, a first light emitting unit arranged between said cathode and said intermediate unit, and a second light emitting unit arranged between said anode and said intermediate unit,
wherein an electron extracting layer for extracting an electron from an adjacent layer adjoining a cathode side is provided in said intermediate unit, an absolute value of an energy level of a lowest unoccupied molecular orbital (LUMO) of said electron extracting layer |LUMO(A)|, and an absolute value of an energy level of a highest occupied molecular orbital (HOMO) of said adjacent layer |HOMO(B)| are in the relationship of |HOMO(B)|−|LUMO(A)|≦1.5 eV,
a light emitting layer situated on an intermediate unit side of said first light emitting unit contains an arylamine-based hole transporting material, said light emitting layer is provided adjoining said electron extracting layer so as to function as said adjacent layer, and
said intermediate unit supplies a hole generated by extraction of an electron from said light emitting layer by said electron extracting layer to said first light emitting unit and, at the same time, supplies the extracted electron to said second light emitting unit.

24. The organic electroluminescent element according to claim 23, wherein said electron extracting layer is formed of a pyrazine derivative represented by the following structural formula: 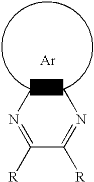
(wherein Ar represents an aryl group, and R represents hydrogen, an alkyl group having a carbon number of 1 to 10, an alkyloxy group having a carbon number of 1 to 10, a dialkylamine group having a carbon number of 1 to 10, F, Cl, Br, I or CN).

25. The organic electroluminescent element according to claim 23, wherein said electron extracting layer is formed of a hexaazatriphenylene derivative represented by the following structural formula: 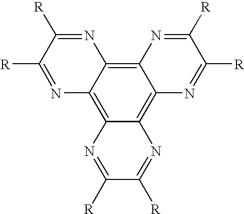
(wherein R represents hydrogen, an alkyl group having a carbon number of 1 to 10, an alkyloxy group having a carbon number of 1 to 10 having a carbon number of 1 to 10, a dialkylamine group having a carbon number of 1 to 10, F, Cl, Br, I or CN).

26. A bottom emission-type organic electroluminescent display device comprising; an organic electroluminescent element having an element structure sandwiched between an anode and a cathode; and an active matrix driving substrate having each active element for supplying a display signal for each display pixel to said organic electroluminescent element; wherein said organic electroluminescent element is provided on said active matrix driving substrate and, among said cathode and said anode, an electrode provided on said substrate side is a transparent electrode,
characterized in that:
said organic electroluminescent element comprises said cathode, said anode, an intermediate unit arranged between said cathode and said anode, a first light emitting unit arranged between said cathode and said intermediate unit, and a second light emitting unit arranged between said anode and said intermediate unit,
an electron extracting layer for extracting an electron from an adjacent layer adjoining a cathode side is provided in said intermediate unit, an absolute value of an energy level of a lowest unoccupied molecular orbital (LUMO) of said electron extracting layer |LUMO(A)|, and an absolute value of an energy level of a highest occupied molecular orbital (HOMO) of said adjacent layer |HOMO(B)| are in the relationship of |HOMO(B)|−|LUMO(A)|≦1.5 eV,
a light emitting layer situated on an intermediate unit side of said first light emitting unit contains an arylamine-based hole transporting material, said light emitting layer is provided adjoining said electron extracting layer so as to function as said adjacent layer, and
said intermediate unit supplies a hole generated by extraction of an electron from said light emitting layer by said electron extracting layer to said first light emitting unit and, at the same time, supplies the extracted electron to said second light emitting unit.

27. A top emission-type organic electroluminescent display device comprising; an organic electroluminescent element having an element structure sandwiched between an anode and a cathode; an active matrix driving substrate having each active element for supplying a display signal for each display pixel to said organic electroluminescent element; and a transparent sealing substrate provided opposite to said active matrix driving substrate; wherein said organic electroluminescent element is arranged between said active matrix driving substrate and said sealing substrate and, among said cathode and said anode, an electrode provided on said sealing substrate side is a transparent electrode,
characterized in that:
said organic electroluminescent element comprises said cathode, said anode, an intermediate unit arranged between said cathode and said anode, a first light emitting unit arranged between said cathode and said intermediate unit, and a second light emitting unit arranged between said anode and said intermediate unit,
an electron extracting layer for extracting an electron from an adjacent layer adjoining a cathode side is provided in said intermediate unit, an absolute value of an energy level of a lowest unoccupied molecular orbital (LUMO) of said electron extracting layer |LUMO(A)|, and an absolute value of an energy level of a highest occupied molecular orbital (HOMO) of said adjacent layer |HOMO(B)| are in the relationship of |HOMO(B)|−|LUMO(A)|≦1.5 eV, a light emitting layer situated on an intermediate unit side of said first light emitting unit contains an arylamine-based hole transporting material, said light emitting layer is provided adjoining said electron extracting layer so as to function as said adjacent layer, and
said intermediate unit supplies a hole generated by extraction of an electron from said light emitting layer by said electron extracting layer to said first light emitting unit and, at the same time, supplies the extracted electron to said second light emitting unit.

28. An organic electroluminescent element comprising a cathode, an anode, an intermediate unit arranged between said cathode and said anode, a first light emitting unit arranged between said cathode and said intermediate unit, and a second light emitting unit arranged between said cathode and said intermediate unit,
an electron extracting layer for extracting an electron from an adjacent layer adjoining a cathode side, and an electron injecting layer adjoining an anode side of said electron extracting layer are provided in said intermediate unit, an absolute level of an energy level of a lowest unoccupied orbital (LUMO) of said electron extracting layer |LUMO(A)|, and an absolute value of an energy level of a highest occupied molecular orbital (HOMO) of said adjacent layer |HOMO(B)| are in the relationship of |HOMO(B)|−|LUMO(A)|≦1.5 eV, an absolute value of an energy level of a lowest unoccupied molecular orbital (LUMO) of said electron injecting layer |LUMO(C)| or an absolute value of a work function |WF(C)| is smaller than |LUMO(A)|, and said intermediate unit supplies a hole generated by extraction of an electron from said adjacent layer by said electron extracting layer to said first light emitting unit and, at the same time, supplies the extracted electron to said second light emitting unit via said electron injecting layer.

29. The organic electroluminescent element according to claim 28, wherein an electron transporting layer is provided in said intermediate unit between said electron injecting layer in said intermediate unit, and said second light emitting unit, an absolute value of an energy level of a lowest unoccupied molecular orbital of said electron transporting layer |LUMO(D)| is smaller than |LUMO(C)| or an absolute value of a work function |WF(C)|, and said intermediate unit supplies an electron extracted by said electron extracting layer to said second light emitting unit via said electron injecting layer and said electron transporting layer.

30. The organic electroluminescent element according to claim 28, wherein a thickness of said electron extracting layer is in a range of 8 to 100 nm.

31. The organic electroluminescent element, wherein said electron extracting layer is formed of a pyrazine derivative represented by the following structural formula: 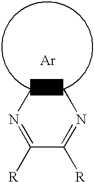
(wherein Ar represents an aryl group, and R represents hydrogen, an alkyl group having a carbon number of 1 to 10, an alkyloxy group having a carbon number of 1 to 10 having a carbon number of 1 to 10, a dialkylamine group having a carbon number of 1 to 10, F, Cl, Br, I or CN).

32. The organic electroluminescent element according to claim 28, wherein said electron extracting layer is formed of a hexaazatriphenylene derivative represented by the following structural formula: 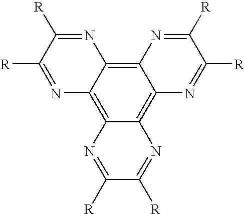
(wherein R represents hydrogen, an alkyl group having a carbon number of 1 to 10, an alkyloxy group having a carbon number of 1 to 10 having a carbon number of 1 to 10, a dialkylamine group having a carbon number of 1 to 10, F, Cl, Br, I or CN).

33. An organic electroluminescent element comprising a cathode, an anode, an intermediate unit arranged between said cathode and said anode, a first light emitting unit arranged between said cathode and said intermediate unit, a second light emitting unit arranged between said anode and said intermediate unit, and a hole injecting unit arranged between said anode and said second light emitting unit,
wherein an electron extracting layer for extracting an electron from an adjacent layer adjoining a cathode side is provided in said intermediate unit, an absolute value of an energy level of a lowest unoccupied molecular orbital (LUMO) of said electron extracting layer |LUMO(A)|, and an absolute value of an energy level of a highest occupied molecular orbital (HOMO) of said adjacent layer |HOMO(B)| are in the relationship of |HOMO(B)|−|LUMO(A)|≦1.5 eV, and said intermediate unit supplies a hole generated by extraction of an electron from said adjacent layer by said electron extracting layer to said first light emitting unit and, at the same time, supplies the extracted electron to said second light emitting unit,
characterized in that:
said hole injecting unit is constructed of a hole injecting layer comprising an arylamine-based hole transporting material, and a hole injection promoting layer arranged between said hole injecting layer and said anode, and an absolute value of an energy level of a highest occupied molecular orbital (HOMO) of said hole injection promoting layer |HOMO(X)| has a relationship of |WF (Y)|<|HOMO(X)|<|HOMO(Z)| relative to an absolute value of a work function of said anode |WF (Y)| and an absolute value of an energy level of a highest occupied molecular orbital (HOMO) of said hole injecting layer |HOMO(Z)|.

34. The organic electroluminescent element according to claim 33, wherein an electron injecting layer is provided adjoining an anode side of said electron extracting layer, an absolute value of an energy level of a lowest unoccupied molecular orbital (LUMO) of said electron injecting layer |LUMO(C)| or an absolute value of a work function |WF(C)| is smaller than |LUMO(A)|, and
said intermediate unit supplies an electron extracted by said electron extracting layer to said second light emitting unit via said electron injecting layer.

35. The organic electroluminescent element according to claim 34, wherein an electron transporting layer is provided in said intermediate unit between said electron injecting layer and said second light emitting unit, an absolute value of an energy level of a lowest unoccupied molecular orbital of said electron transporting layer |LUMO(D)| is smaller than |LUMO(C)| or |WF (C)|, and said intermediate unit supplies an electron extracted by said electron extracting layer to said second light emitting unit via said electron injecting layer and said electron transporting layer.

36. A bottom emission-type organic electroluminescent display device comprising; an organic electroluminescent element having an element structure sandwiched between an anode and a cathode; and an active matrix driving substrate having each active element for supplying a display signal for each display pixel to said organic electroluminescent element; wherein said organic electroluminescent element is provided on said active matrix driving substrate and, among said cathode and said anode, an electrode provided on said substrate side is a transparent electrode,
characterized in that:
said organic electroluminescent element comprises said cathode, said anode, an intermediate unit arranged between said cathode and said anode, a first light emitting unit arranged between said cathode and said intermediate unit, a second light emitting unit arranged between said anode and said intermediate unit, and a hole injecting unit arranged between said anode and said second light emitting unit, an electron extracting layer for extracting an electron from an adjacent layer adjoining a cathode side is provided in said intermediate unit, an absolute value of an energy level of a lowest unoccupied molecular orbital (LUMO) of said electron extracting layer |LUMO(A)|, and an absolute value of an energy level of a highest occupied molecular orbital (HOMO) of said adjacent layer |HOMO(B)| are in the relationship of |HOMO(B)|−|LUMO(A)|≦1.5 eV, and said intermediate unit supplies a hole generated by extraction of an electron from said adjacent layer by an electron extracting layer to said first light emitting unit and, at the same time, supplies the extracted electron to said second light emitting unit,
wherein said hole injecting unit is constructed of a hole injecting layer comprising an arylamine-based hole transporting material, and a hole injection promoting layer arranged between said hole injecting layer and said anode, and an absolute value of an energy level of a highest occupied molecular orbital (HOMO) of said hole injection promoting layer |HOMO(X)| has a relationship of |WF(Y)|<|HO MO(X)|<|HOMO(Z)| relative to an absolute value of a work function of said anode |WF (Y)| and an absolute value of an energy level of a highest occupied molecular orbital (HOMO) of said hole injecting layer |HOMO(Z)|.

37. A top emission-type organic electroluminescent display device comprising; an organic electroluminescent element having an element structure sandwiched between an anode and a cathode; an active matrix driving substrate having each active element for supplying a display signal for each display pixel to said organic electroluminescent element; and a transparent sealing substrate provided opposite to said active matrix driving substrate; wherein said organic electroluminescent element is arranged between said active matrix driving substrate and said sealing substrate and, among said cathode and said anode, an electrode provided on said sealing substrate side is a transparent electrode,
characterized in that:
said organic electroluminescent element comprises said cathode, said anode, an intermediate unit arranged between said cathode and said anode, a first light emitting unit arranged between said cathode and said intermediate unit, a second light emitting unit arranged between said anode and said intermediate unit, and a hole injecting unit arranged between said anode and said second light emitting unit, an electron extracting layer for extracting an electron from an adjacent layer adjoining a cathode side is provided in said intermediate unit, an absolute value of an energy level of a lowest unoccupied molecular orbital (LUMO) of said electron extracting layer |LUMO(A)|, and an absolute value of an energy level of a highest occupied molecular orbital (HOMO) of said adjacent layer |HOMO(B)| are in the relationship of |HOMO(B)|−|LUMO(A)|≦1.5 eV, and said intermediate unit supplies a hole generated by extraction of an electron from said adjacent layer by an electron extracting layer to said first light emitting unit and, at the same time, supplies the extracted electron to said second light emitting unit,
wherein said hole injecting unit is constructed of a hole injecting layer comprising an arylamine-based hole transporting material, and a hole injection promoting layer arranged between said hole injecting layer and said anode, and an absolute value of an energy level of a highest occupied molecular orbital (HOMO) of said hole injection promoting layer |HOMO(X)| has a relationship of |WF(Y)|<|HO MO(X)|<|HOMO(Z)| relative to an absolute value of a work function of said anode |WF (Y)| and an absolute value of an energy level of a highest occupied molecular orbital (HOMO) of said hole injecting layer |HOMO(Z)|.

38. An organic electroluminescent element comprising a cathode, an anode, a light emitting unit arranged between said cathode and said anode, and a hole injecting unit arranged between said anode and said light emitting unit, characterized in that said hole injecting unit has a first electron extracting layer provided on said anode side, and a first adjacent layer comprising a hole transporting material provided adjoining said first electron extracting layer on said cathode side.

39. The organic electroluminescent element according to claim 38, wherein an absolute value of an energy level of a lowest unoccupied molecular orbital (LUMO) of said first electron extracting layer |LUMO(A₁)|, and an absolute value of an energy level of a highest unoccupied molecular orbital (HOMO) of said first adjacent layer |HOMO(B₁)| are in the relationship of |HOMO(B₁)|−|LUMO(A₁)|≦1.5 eV.

40. The organic electroluminescent element according to claim 38, wherein said light emitting unit has a first light emitting unit provided on a cathode side holding an intermediate unit, and a second light emitting unit provided on an anode side,
a second electron extracting layer for extracting an electron from a second adjacent layer adjoining a cathode side is provided in said intermediate unit, an absolute value of an energy level of a lowest unoccupied molecular orbital (LUMO) of said second electron extracting layer |LUMO(A₂)|, and an absolute value of an energy level of a highest occupied molecular orbital (HOMO) of said second adjacent layer |HOMO(B₂)| are in the relationship of |HOMO(B₂)|−|LUMO(A₂)|≦1.5 eV, and
said intermediate unit supplies a hole generated by extraction of an electron from said second adjacent layer by said second electron extracting layer to said first light emitting unit and, at the same time, supplies the extracted electron to said second light emitting unit.

41. The organic electroluminescent element according to claim 40, wherein an electron injecting layer is provided adjoining an anode side of said second electron extracting layer, an absolute value of an energy level of a lowest unoccupied molecular orbital (LUMO) of said second electron injecting layer |LUMO(C)| or an absolute value of a work function |WF (C)| is smaller than |LUMO(A₂)|, and
said intermediate unit supplies an electron extracted by said second electron extracting layer to said second light emitting unit via said electron injecting layer.

42. The organic electroluminescent value according to claim 41, wherein an electron transporting layer is provided in said intermediate unit between said electron injecting layer and said second light emitting unit, an absolute value of an energy level of a lowest unoccupied molecular orbital of said electron transporting layer |LUMO (D)| is smaller than |LUMO(C)| or |WF (C)|, and
said intermediate unit supplies an electron extracted by said second electron extracting layer to said second light emitting unit via said electron injecting layer and said electron transporting layer.

43. The organic electroluminescent element according to claim 38, wherein said first electron extracting layer and/or said second electron extracting layer is formed of a pyrazine derivative represented by the following structural formula: 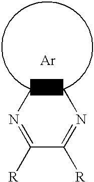
(wherein Ar represents an aryl group, and R represents hydrogen, an alkyl group having a carbon number of 1 to 10, an alkyloxy group having a carbon number of 1 to 10 having a carbon number of 1 to 10, a dialkylamine group having a carbon number of 1 to 10, F, Cl, Br, I or CN).

44. The organic electroluminescent element according to claim 38, wherein said first electron extracting layer and/or said second electron extracting layer is formed of a hexaazatriphenylene derivative represented by the following structural formula: 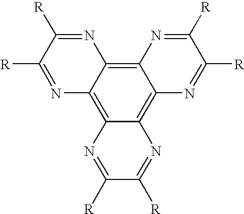
(wherein R represents hydrogen, an alkyl group having a carbon number of 1 to 10, an alkyloxy group having a carbon number of 1 to 10 having a carbon number of 1 to 10, a dialkylamine group having a carbon number of 1 to 10, F, Cl, Br, I or CN).

45. An organic electroluminescent element comprising a cathode, an anode, a plurality of light emitting units arranged between said cathode and said anode, and an intermediate unit arranged between said light emitting units,
wherein said intermediate unit has an electron transporting layer provided on an anode side, and an electron extracting layer provided on a cathode side, said electron extracting layer is a layer for extracting an electron from an adjacent layer adjoining a cathode side of said electron extracting layer, an absolute value of an energy level of a lowest unoccupied molecular orbital (LUMO) of said electron extracting layer |LUMO(A)|, and an absolute value of an energy level of a highest unoccupied molecular orbital (HOMO) of said adjacent layer |HOMO(B)| are in the relationship of |HOMO(B)|−|LUMO(A)|≦1.5 eV, and said intermediate unit supplies a hole generated by extraction of an electron from said adjacent layer by said electron extracting layer and, at the same time, supplies the extracted electron to a light emitting unit on an anode side via said electron transporting layer,
characterized in that:
an electron transporting layer is provided also between said cathode, and said light emitting unit closest to said cathode, and film thicknesses of respective electron transporting layers are set to be greater as they become more distant from said cathode, and are set to be not greater than 40 nm.

46. The organic electroluminescent element according to claim 45, wherein a hole injecting layer is provided between said anode, and said light emitting unit closest to said anode, and film thicknesses of said hole injecting layer and respective electron extracting layers are set to be greater as they become more distant from said anode, and are set to be not greater than 100 nm.

47. An organic electroluminescent element comprising a cathode, an anode, a plurality of light emitting units arranged between said cathode and said anode, and an intermediate unit arranged between said light emitting units,
wherein said intermediate unit has an electron transporting layer provided on an anode side, and an electron extracting layer provided on a cathode side, said electron extracting layer is a layer for extracting an electron from an adjacent layer adjoining a cathode side of said electron extracting layer, an absolute value of an energy level of a lowest unoccupied molecular orbital (LUMO) of said electron extracting layer |LUMO(A)|, and an absolute value of an energy level of a highest occupied molecular orbital (HOMO) of said adjacent layer |HOMO(B)| are in the relationship of |HOMO(B)|−|LUMO(A)|≦1.5 eV, and said intermediate unit supplies a hole generated by extraction of an electron from said adjacent layer by said electron extracting layer and, at the same time, supplies the extracted electron to a light emitting unit on an anode side via an electron transporting layer,
characterized in that:
a hole injecting layer is provided between said anode, and said light emitting unit closest to said anode, and film thicknesses of said hole injecting layer and respective electron extracting layers are set to be greater as they become more distant from said anode, and are set to be not greater than 100 nm.

48. The organic electroluminescent element according to claim 45, wherein an electron injecting layer is provided adjoining an anode side of said electron extracting layer, an absolute value of an energy level of a lowest unoccupied molecular orbital (LUMO) of said electron injecting layer |LUMO(C)| or an absolute value of a work function |WF (C)| is smaller than |LUMO(A)|, and an absolute value of an energy level of a lowest unoccupied molecular orbital of said electron transporting layer |LUMO(D)| is smaller than |LUMO(C)| or |WF(C)|, and
said intermediate unit supplies an electron extracted by said electron extracting layer to said light emitting unit via said electron injecting layer and said electron transporting layer.

49. A bottom emission-type organic electroluminescent display device comprising; an organic electroluminescent element having an element structure sandwiched between an anode and a cathode; and an active matrix driving substrate having each active element for supplying a display signal for each display pixel to said organic electroluminescent element; wherein said organic electroluminescent element is provided on said active matrix driving substrate and, among said cathode and said anode, an electrode provided on said substrate side is a transparent electrode,
characterized in that:
said organic electroluminescent element comprises said cathode, said anode, a plurality of light emitting units arranged between said cathode and said anode, and an intermediate unit arranged between said light emitting units,
wherein said intermediate unit has an electron transporting layer provided on an anode side, and an electron extracting layer provided on a cathode side, said electron extracting layer is a layer for extracting an electron from an adjacent layer adjoining a cathode side of said electron extracting layer, an absolute value of an energy level of a lowest unoccupied molecular orbital (LUMO) of said electron extracting layer |LUMO(A)|, and an absolute value of an energy level of a highest occupied molecular orbital (HOMO) of said adjacent layer |HOMO(B)| are in the relationship of |HOMO(B)|−|LUMO(A)|≦1.5 eV, said intermediate unit supplies a hole generated by extraction of an electron from said adjacent layer by said electron extracting layer to a light emitting unit on a cathode side and, at the same time, supplies the extracted electron to a light emitting unit on an anode side via said electron transporting layer, a hole injecting layer is provided between said anode, and said light emitting unit closest to said anode, and film thicknesses of said hole injecting layer and respective electron extracting layers are set to be greater as they become more distant from said anode, and are set to be not greater than 100 nm.

50. A top emission-type organic electroluminescent display device comprising; an organic electroluminescent element having an element structure sandwiched between an anode and a cathode; an active matrix driving substrate having each active element for supplying a display signal for each display pixel to said organic electroluminescent element; and a transparent sealing substrate provided opposite to said active matrix driving substrate; wherein said organic electroluminescent element is arranged between said active matrix driving substrate and said sealing substrate and, among said cathode and said anode, an electrode provided on said sealing substrate side is a transparent electrode,
characterized in that:
said organic electroluminescent element comprises said cathode, said anode, a plurality of light emitting units arranged between said cathode and said anode, and an intermediate unit arranged between said light emitting units,
wherein said intermediate unit has an electron transporting layer provided on an anode side, and an electron extracting layer provided on a cathode side, said electron extracting layer is a layer for extracting an electron from an adjacent layer adjoining a cathode side of said electron extracting layer, an absolute value of an energy level of a lowest unoccupied molecular orbital (LUMO) of said electron extracting layer |LUMO(A)|, and an absolute value of an energy level of a highest occupied molecular orbital (HOMO) of said adjacent layer |HOMO(B)| are in the relationship of |HOMO (B)|−|LUMO (A)|≦1.5 eV, said intermediate unit supplies a hole generated by extraction of an electron from said adjacent layer by said electron extracting layer to a light emitting unit on a cathode side and, at the same time, supplies the extracted electron to a light emitting unit on an anode side via said electron transporting layer, a hole injecting layer is provided between said anode, and said light emitting unit closest to said anode, and film thicknesses of said hole injecting layer and respective electron extracting layers are set to be greater as they become more distant from said anode, and are set to be not greater than 100 nm.

51. An organic electroluminescent element comprising a cathode, an anode, a plurality of light emitting units arranged between said anode and said cathode, and an intermediate unit arranged between said light emitting units,
wherein said intermediate unit has an electron transporting layer provided on an anode side, and an electron extracting layer provided on a cathode side, said electron extracting layer is a layer for extracting an electron from an adjacent layer adjoining a cathode side of said electron extracting layer, an absolute value of an energy level of a lowest unoccupied molecular orbital (LUMO) of said electron extracting layer |LUMO(A)|, and an absolute value of an energy level of a highest occupied molecular orbital (HOMO) of said adjacent layer |HOMO(B)| are in the relationship of |HOMO(B)|−|LUMO(A)|≦2.0 eV, and said intermediate unit supplies a hole generated by extraction of an electron from said adjacent layer by said electron extracting layer to a light emitting unit on a cathode side and, at the same time, supplies the extracted electron to a light emitting unit on an anode side via said electron transporting layer,
characterized in that:
an electron extraction promoting material having an absolute value of an energy level of a lowest unoccupied molecular orbital (LUMO) |LUMO(C)| in a relationship of |HOMO(B)|>|LUMO(C)|>|LUMO(A)| is doped into said electron extracting layer.

52. An organic electroluminescent element comprising a cathode, an anode, a plurality of light emitting units arranged between said cathode and said anode, and an intermediate unit arranged between said light emitting units,
wherein said intermediate unit has an electron transporting layer provided on an anode side, and an electron extracting layer provided on a cathode side, said electron extracting layer is a layer for extracting an electron from an adjacent layer adjoining a cathode side of said electron extracting layer, an absolute value of an energy level of a lowest unoccupied molecular orbital (LUMO) of said electron extracting layer |LUMO(A)|, and an absolute value of an energy level of a highest occupied molecular orbital (HOMO) of said adjacent layer |HOMO(B)| are in the relationship of |HOMO(B)|−|LUMO(A)|≦2.0 eV, and said intermediate unit supplies a hole generated by extraction of an electron from said adjacent layer by said electron extracting layer to a light emitting unit on a cathode side and, at the same time, supplies the extracted electron to a light emitting unit on an anode side via said electron transporting layer,
characterized in that an electron extraction promoting layer comprising an electron extraction promoting material having an absolute value of an energy level of a lowest unoccupied molecular orbital (LUMO) |LUMO(C)| in the relationship of |HOMO(B)|>|LUMO(C)|>|LUMO(A)| is provided between said electron extracting layer and said adjacent layer.

53. An organic electroluminescent element comprising a cathode, an anode, a plurality of light emitting units arranged between said cathode and said anode, and an intermediate unit arranged between said light emitting units,
wherein said intermediate unit has an electron transporting layer provided on an anode side, and an electron extracting layer provided on a cathode side, said electron extracting layer is a layer for extracting an electron from an adjacent layer adjoining a cathode side of said electron extracting layer, an absolute value of an energy level of a lowest unoccupied molecular orbital (LUMO) of said electron extracting layer |LUMO(A)|, and an absolute value of an energy level of a highest occupied molecular orbital (HOMO) of said adjacent layer |HOMO(B)| are in the relationship of |HOMO(B)|−|LUMO(A)|≦2.0 eV, and said intermediate unit supplies a hole generated by extraction of an electron from said adjacent layer by said electron extracting layer to a light emitting unit on a cathode side and, at the same time, supplies the extracted electron to a light emitting unit on an anode side via said electron transporting layer,
characterized in that:
an electron injecting organic material having an absolute value of an energy level of a lowest unoccupied molecular orbital (LUMO) |LUMO(D)| in a relation of |LUMO(A)|>|LUMO (D)|>|LUMO(E)| relative to an absolute value of an energy level of a lowest unoccupied molecular orbital (LUMO) of said electron transporting layer |LUMO(E)| and |LUMO(A)| is doped into said electron transporting layer and/or said electron extracting layer.

54. An organic electroluminescent element comprising a cathode, an anode, a plurality of light emitting units arranged between said cathode and said anode, and an intermediate unit arranged between said light emitting units,
wherein said intermediate unit has an electron transporting layer provided on an anode side, and an electron extracting layer provided on a cathode side, said electron extracting layer is a layer for extracting an electron from an adjacent layer adjoining a cathode side of said electron extracting layer, an absolute value of an energy level of a lowest unoccupied molecular orbital (LUMO) of said electron extracting layer |LUMO(A)|, and an absolute value of an energy level of a highest occupied molecular orbital (HOMO) of said adjacent layer |HOMO(B)| are in the relationship of |HOMO(B)|−|LUMO(A)|≦2.0 eV, and said intermediate unit supplies a hole generated by extraction of an electron from said adjacent layer by said electron extracting layer to a light emitting unit on a cathode side and, at the same time, supplies the extracted electron to a light emitting unit on an anode side via said electron transporting layer,
characterized in that:
an electron injecting organic material layer comprising an electron injecting organic material having an absolute value of an energy level of a lowest unoccupied molecular orbital (LUMO) |LUMO(D)| in relation of |LUMO(A)|>|LUMO(D)|>|LUMO(E)| relative to an absolute value of an energy level of a lowest unoccupied molecular orbital (LUMO) of said electron transporting layer |LUMO(E)| and |LUMO(A)| is provided between said electron extracting layer and said electron transporting layer.

55. The organic electroluminescent element according to claim 89, wherein an electron injecting layer comprising at least one kind selected from an alkali metal, an alkaline earth metal, and an oxide thereof is provided between said electron extracting layer and said electron transporting layer.

56. The organic electroluminescent element according to claim 54, wherein an electron injecting layer comprising at least one kind selected from an alkali metal, an alkaline earth metal, and an oxide thereof is provided between said electron extracting layer and said electron injecting organic material layer.

57. An organic electroluminescent element comprising a cathode, an anode, a plurality of light emitting units arranged between said cathode and said anode, and an intermediate unit arranged between said light emitting units,
wherein said intermediate unit has an electron transporting layer provided on an anode side, and an electron extracting layer provided on a cathode side, said electron extracting layer is a layer for extracting an electron from an adjacent layer adjoining a cathode side of said electron extracting layer, an absolute value of an energy level of a lowest unoccupied molecular orbital (LUMO) of said electron extracting layer |LUMO(A)|, and an absolute value of an energy level of a highest occupied molecular orbital (HOMO) of said adjacent layer |HOMO(B)| are in the relationship of |HOMO(B)|−|LUMO(A)|≦2.0 eV, and said intermediate unit supplies a hole generated by extraction of an electron from said adjacent layer by said electron extracting layer to a light emitting unit on a cathode side and, at the same time, supplies the extracted electron to a light emitting unit on an anode side via said electron transporting layer,
characterized in that:
an electron injecting layer comprising at least one kind selected from an alkali metal, an alkaline earth metal, and an oxide thereof is provided between said electron extracting layer and said electron transporting layer, and
an electron injecting organic material having an absolute value of an energy level of a lowest unoccupied molecular orbital (LUMO) |LUMO(D)| in a relationship of |LUMO (A)|>|LUMO(D)|>|LUMO (E)| relative to an absolute value of an energy level of a lowest unoccupied molecular orbital (LUMO) of said electron transporting layer |LUMO(E)| and |LUMO(A)|, or a material for said electron extracting layer is doped into said electron injecting layer.

58. The organic electroluminescent element according to claim 51, wherein said electron extracting layer is formed of a pyrazine derivative represented by the following structural formula: 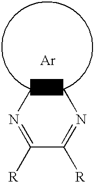
(wherein Ar represents an aryl group, and R represents hydrogen, an alkyl group having a carbon number of 1 to 10, an alkyloxy group having a carbon number of 1 to 10 having a carbon number of 1 to 10, a dialkylamine group having a carbon number of 1 to 10, F, Cl, Br, I or CN).

59. The organic electroluminescent element according to claim 51, wherein said electron extracting layer is formed of a hexaazatriphenylene derivative represented by the following structural formula: 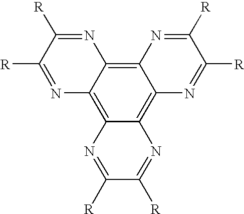
(wherein R represents hydrogen, an alkyl group having a carbon number of 1 to 10, an alkyloxy group having a carbon number of 1 to 10 having a carbon number of 1 to 10, a dialkylamine group having a carbon number of 1 to 10, F, Cl, Br, I or CN).

60. A bottom emission-type organic electroluminescent display device comprising; an organic electroluminescent element having an element structure sandwiched between an anode and a cathode; and an active matrix driving substrate having each active element for supplying a display signal for each display pixel to said organic electroluminescent element; wherein said organic electroluminescent element is provided on said active matrix driving substrate and, among said cathode and said anode, an electrode provided on said substrate side is a transparent electrode,
characterized in that said organic electroluminescent element is the organic electroluminescent element as defined in claim 51.

61. A top emission-type organic electroluminescent display device comprising; an organic electroluminescent element having an element structure sandwiched between an anode and a cathode; an active matrix driving substrate having each active element for supplying a display signal for each display pixel to said organic electroluminescent element; and a transparent sealing substrate provided opposite to said active matrix driving substrate; wherein said organic electroluminescent element is arranged between said active matrix driving substrate and said sealing substrate and, among said cathode and said anode, an electrode provided on said sealing substrate side is a transparent electrode,
characterized in that said organic electroluminescent element is the organic electroluminescent element as defined in claim 51.
